(19) United States
(12) Patent Application Publication
(10) Pub. No.: US 2024/0290679 A1
(43) Pub. Date: Aug. 29, 2024

(54) SEMICONDUCTOR DEVICE

(71) Applicant: ROHM CO., LTD., Kyoto-shi (JP)

(72) Inventor: Yuki NAKANO, Kyoto-shi (JP)

(73) Assignee: ROHM CO., LTD., Kyoto-shi (JP)

(21) Appl. No.: 18/654,417

(22) Filed: May 3, 2024

Related U.S. Application Data
(63) Continuation of application No. PCT/JP2022/040494, filed on Oct. 28, 2022.

(30) Foreign Application Priority Data
Nov. 5, 2021 (JP) 2021-181313

(51) Int. Cl. H01L 23/31; H01L 29/16; H01L 29/423

(52) U.S. Cl. CPC H01L 23/3192; H01L 29/1608; H01L 29/42356

(57) ABSTRACT

A semiconductor device includes a chip having a main surface, a main surface electrode arranged on the main surface, a terminal electrode that has a terminal surface and a terminal side wall, and that has a recessed portion recessed toward the main surface electrode side in the terminal surface, and a sealing insulator that covers a periphery of the terminal electrode on the main surface such as to expose the terminal surface and cover the terminal side wall.

### CROSS-REFERENCE TO RELATED APPLICATIONS

The present application is a bypass continuation of International Patent Application No. PCT/JP2022/040494 filed on Oct. 28, 2022, which claims the benefit of priority to Japanese Patent Application No. 2021-181313 filed on Nov. 5, 2021, the entire contents of each application are hereby incorporated herein by reference.

### BACKGROUND

### 1. Field of the Disclosure

The present disclosure relates to a semiconductor device.

### 2. Description of the Related Art

US20190080976A1 discloses a semiconductor device that includes a semiconductor substrate, an electrode and a protective film. The electrode is formed on the semiconductor substrate. The protective film has a laminated structure that includes an inorganic protective film and an organic protective film and covers the electrode.

### BRIEF DESCRIPTION OF THE DRAWINGS

FIG. 1 is a plan view of a semiconductor device according to a first embodiment.

FIG. 2 is a cross sectional view taken along II-II line shown in FIG. 1.

FIG. 3 is a cross sectional view taken along III-III line shown in FIG. 1.

FIG. 4 is an enlarged plan view showing a principal part of an inner portion of a chip.

FIG. 5 is a cross sectional view taken along V-V line shown in FIG. 4.

FIG. 6 is an enlarged cross sectional view showing a peripheral edge portion of the chip.

FIG. 7 is a plan view showing layout examples of a gate electrode and a source electrode.

FIG. 8 is a plan view showing a layout example of an upper insulating film.

FIG. 9 is an enlarged cross sectional view showing a principal part of a gate terminal electrode.

FIG. 10 is an enlarged cross sectional view showing a principal part of a source terminal electrode.

FIG. 11 is a plan view showing a wafer structure that is to be used at a time of manufacturing.

FIG. 12 is a cross sectional view showing a device region shown in FIG. 11.

FIGS. 13A to 13N are cross sectional views showing a manufacturing method example for the semiconductor device shown in FIG. 1.

FIG. 14 is a plan view showing a semiconductor device according to a second embodiment.

FIG. 15 is a cross sectional view taken along XV-XV line shown in FIG. 14.

FIG. 16 is a plan view showing a semiconductor device according to a third embodiment.

FIG. 17 is a cross sectional view taken along XVII-XVII line shown in FIG. 16.

FIG. 18 is a plan view showing a semiconductor device according to a fourth embodiment.

FIGS. 19A to 19F are cross sectional views showing a manufacturing method example for the semiconductor device shown in FIG. 18.

FIG. 20 is a plan view showing a semiconductor device according to a fifth embodiment.

FIG. 21 is a plan view showing a semiconductor device according to a sixth embodiment.

FIG. 22 is a cross sectional view taken along XXII-XXII line shown in FIG. 21.

FIG. 23 is a circuit diagram showing an electrical configuration of the semiconductor device shown in FIG. 21.

FIG. 24 is a plan view showing a semiconductor device according to a seventh embodiment.

FIG. 25 is a cross sectional view taken along XXV-XXV line shown in FIG. 24.

FIG. 26 is a plan view showing a semiconductor device according to an eighth embodiment.

FIG. 27 is a plan view showing a semiconductor device according to a ninth embodiment.

FIG. 28 is a plan view showing a semiconductor device according to a tenth embodiment.

FIG. 29 is a plan view showing a semiconductor device according to an eleventh embodiment.

FIG. 30 is a cross sectional view taken along XXX-XXX line shown in FIG. 29.

FIG. 31 is a plan view showing a semiconductor device according to a twelfth embodiment.

FIG. 32 is a plan view showing a semiconductor device according to a thirteenth embodiment.

FIG. 33 is a plan view showing a semiconductor device according to a fourteenth embodiment.

FIG. 34 is a cross sectional view showing a modified example of the chip to be applied to each of the embodiments.

FIG. 35 is a cross sectional view showing a modified example of a sealing insulator to be applied to each of the embodiments.

FIG. 36 is a plan view showing a package to which any one of the semiconductor devices according to the first to eleventh embodiments is to be incorporated.

FIG. 37 is a plan view showing a package to which any one of the semiconductor devices according to the twelfth to fourteenth embodiments is to be incorporated.

FIG. 38 is a perspective view showing a package to which any one of the semiconductor devices according to the first to eleventh embodiments and any one of the semiconductor devices according to the twelfth to fourteenth embodiments are to be incorporated.

FIG. 39 is an exploded perspective view of the package shown in FIG. 38.

FIG. 40 is a cross sectional view taken along LX-LX line shown in FIG. 38.

### DETAILED DESCRIPTION OF THE PREFERRED EMBODIMENTS

Hereinafter, embodiments shall be described in detail with reference to attached drawings. The attached drawings are schematic views and are not strictly illustrated, and scales and the like thereof do not always match. Also, identical reference symbols are given to corresponding structures among the attached drawings, and duplicate descriptions thereof shall be omitted or simplified. For the structures whose description have been omitted or simplified, the description given before the omission or simplification shall be applies.

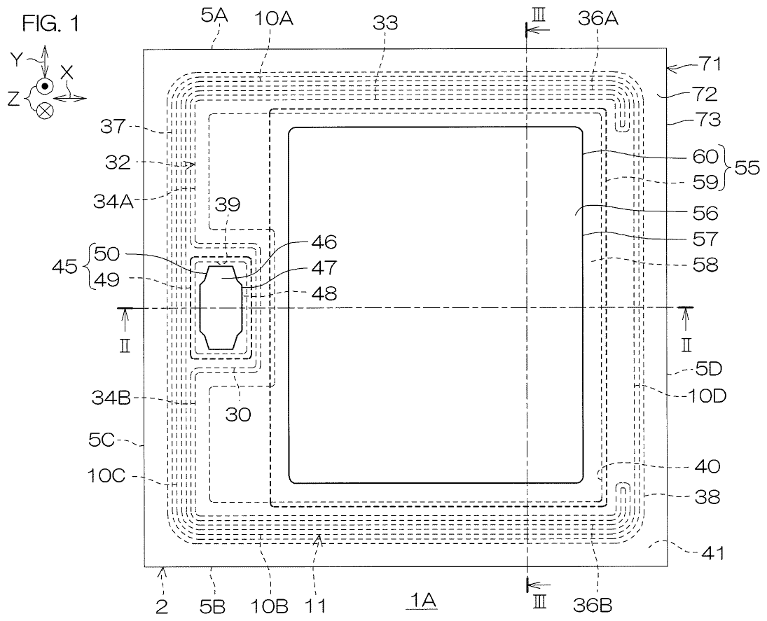

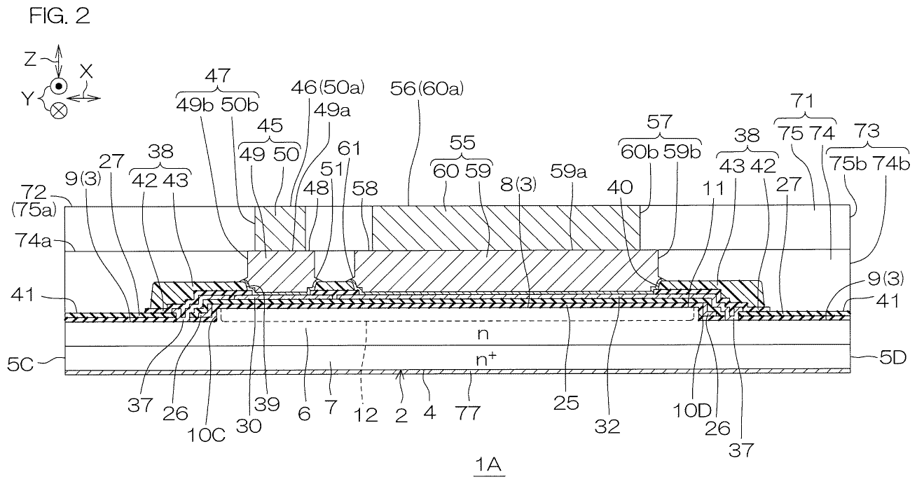

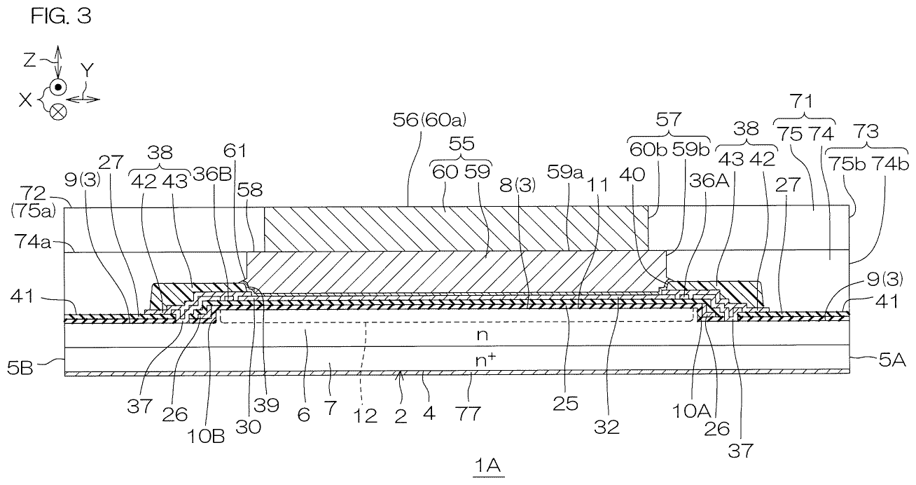

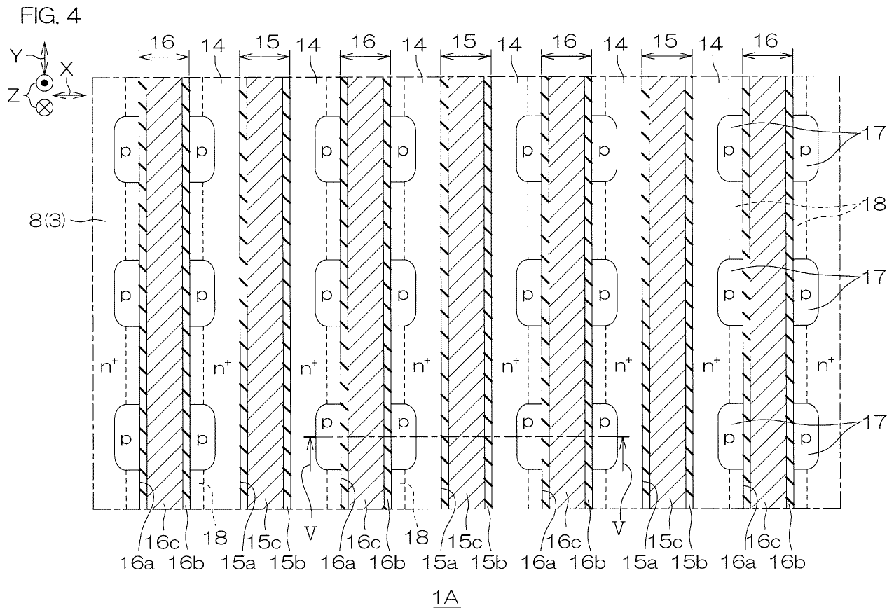

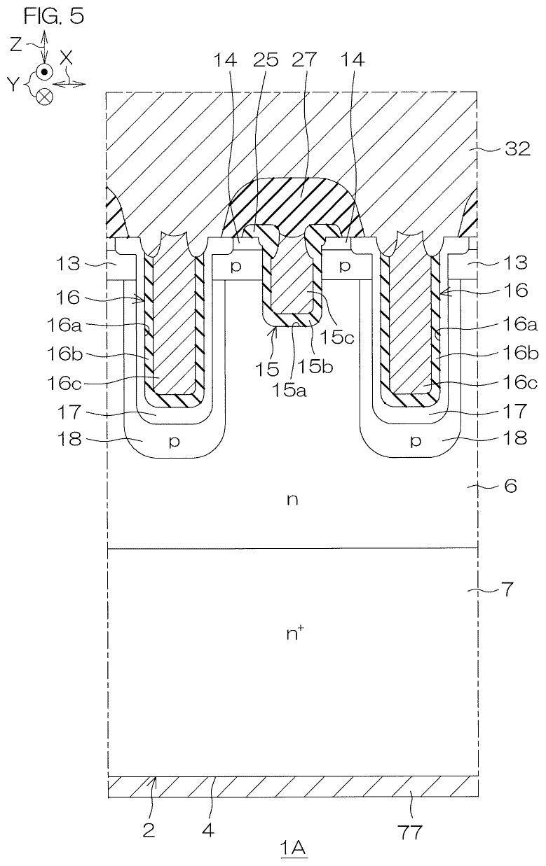

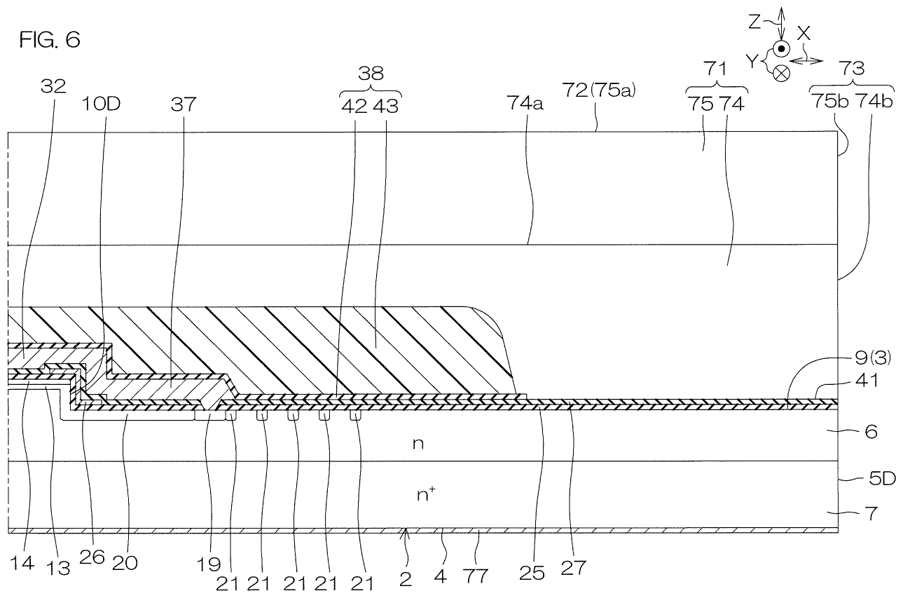

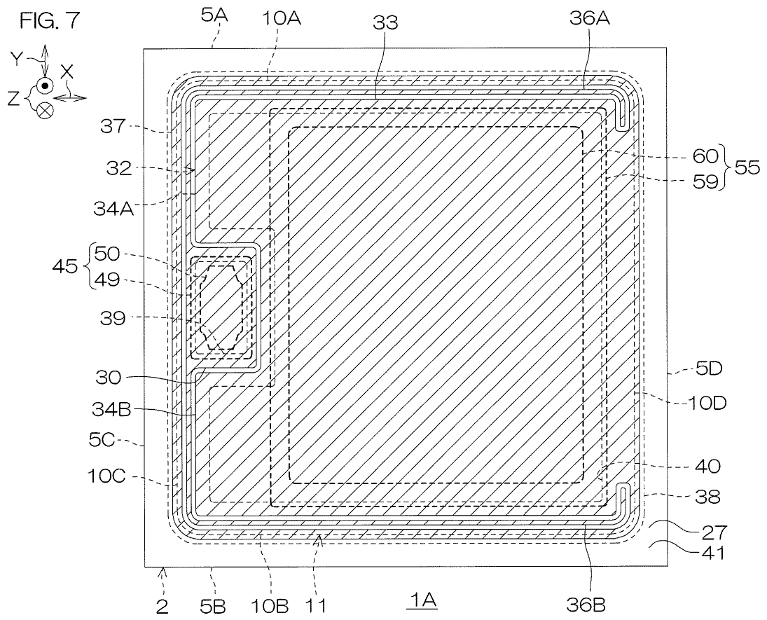

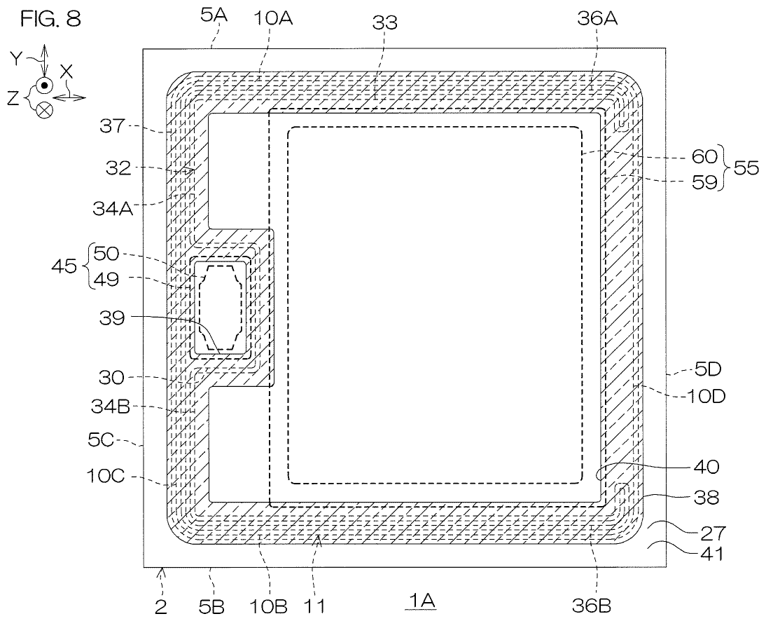

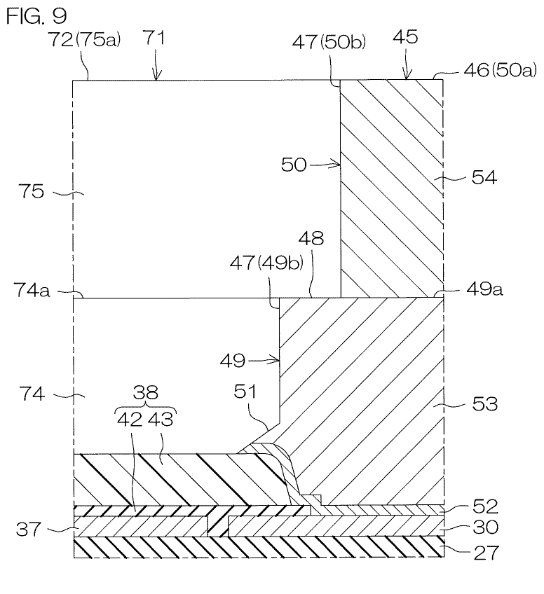

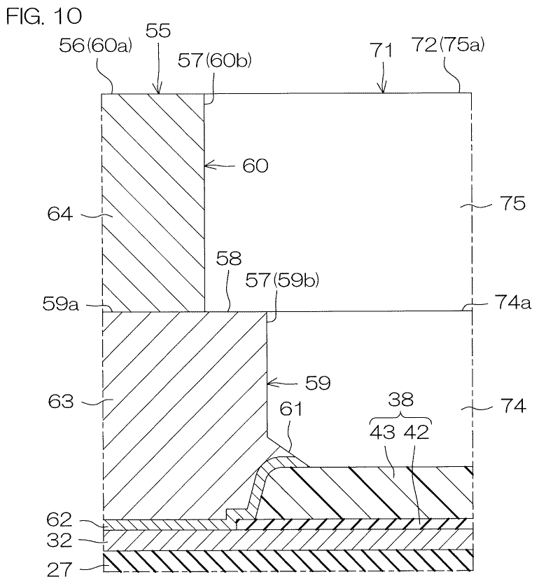

FIG. 1 is a plan view of a semiconductor device 1A according to a first embodiment. FIG. 2 is a cross sectional view taken along II-II line shown in FIG. 1. FIG. 3 is a cross sectional view taken along III-III line shown in FIG. 1. FIG. 4 is an enlarged plan view showing a principal part of an inner portion of a chip 2. FIG. 5 is a cross sectional view taken along V-V line shown in FIG. 4. FIG. 6 is an enlarged cross sectional view showing a peripheral edge portion of the chip 2. FIG. 7 is a plan view showing layout examples of a gate electrode 30 and a source electrode 32. FIG. 8 is a plan view showing a layout example of an upper insulating film 38. FIG. 9 is an enlarged cross sectional view showing a principal part of a gate terminal electrode 45. FIG. 10 is an enlarged cross sectional view showing a principal part of a source terminal electrode 55.

With reference to FIG. 1 to FIG. 10, the semiconductor device 1A includes a chip 2 that includes a monocrystal of a wide bandgap semiconductor and that is formed in a hexahedral shape (specifically, rectangular parallelepiped shape), in this embodiment. That is, the semiconductor device 1A is a “wide bandgap semiconductor device”. The chip 2 may be referred to as a “semiconductor chip” or a “wide bandgap semiconductor chip”. The wide bandgap semiconductor is a semiconductor having a bandgap exceeding a bandgap of an Si (Silicon). GaN (gallium nitride), SiC (silicon carbide) and C (diamond) are exemplified as the wide bandgap semiconductors.

The chip 2 is an “SiC chip” including an SiC monocrystal of a hexagonal crystal as an example of the wide bandgap semiconductor. That is, the semiconductor device 1A is an “SiC semiconductor device”. The SiC monocrystal of the hexagonal crystal has multiple polytypes including 2H (Hexagonal)-SiC monocrystal, 4H-SiC monocrystal, 6H-SiC monocrystal and the like. In this embodiment, an example in which the chip 2 includes the 4H-SiC monocrystal is to be given, but this does not preclude a choice of other polytypes.

The chip 2 has a first main surface 3 on one side, a second main surface 4 on the other side, and first to fourth side surfaces 5A to 5D connecting the first main surface 3 and the second main surface 4. The first main surface 3 and the second main surface 4 are each formed in a quadrangle shape in plan view as viewed from their normal direction Z (hereinafter, simply referred to as “in plan view”). The normal direction Z is also a thickness direction of the chip 2. The first main surface 3 and the second main surface 4 are preferably formed by a c-plane of the SiC monocrystal, respectively.

In this case, the first main surface 3 is preferably formed by a silicon surface of the SiC monocrystal, and the second main surface 4 is preferably formed by a carbon surface of the SiC monocrystal. The first main surface 3 and the second main surface 4 may each have an off angle inclined with a predetermined angle with respect to the c-plane toward a predetermined off direction. The off direction is preferably an a-axis direction ([11-20] direction) of the SiC monocrystal. The off angle may be more than 0° and not more than 10°. The off angle is preferably not more than 5°. The second main surface 4 may consist of a ground surface with grinding marks, or may consist of a smooth surface without a grinding mark.

The first side surface 5A and the second side surface 5B extend in a first direction X along the first main surface 3 and oppose in a second direction Y intersecting to (specifically, orthogonal to) the first direction X. The third side surface 5C and the fourth side surface 5D extend in the second direction Y and oppose in the first direction X. The first direction X may be an m-axis direction ([1-100] direction) of the SiC monocrystal, and the second direction Y may be the a-axis direction of the SiC monocrystal. As a matter of course, the first direction X may be the a-axis direction of the SiC monocrystal, and the second direction Y may be the m-axis direction of the SiC monocrystal. The first to fourth side surfaces 5A to 5D may each consist of a ground surface with grinding marks, or may each consist of a smooth surface without a grinding mark.

The chip 2 has a thickness of not less than 5 μm and not more than 250 μm in regard to the normal direction Z. The thickness of the chip 2 may be not more than 100 μm. The thickness of the chip 2 is preferably not more than 50 μm. The thickness of the chip 2 is particularly preferably not more than 40 μm. The first to fourth side surfaces 5A to 5D may each have a length of not less than 0.5 mm and not more than 10 mm in plan view.

The lengths of the first to fourth side surfaces 5A to 5D are preferably not less than 1 mm. The lengths of the first to fourth side surfaces 5A to 5D are particularly preferably not less than 2 mm. That is, the chip 2 preferably has a planar area of not less than 1 mm square (preferably, not less than 2 mm square) and preferably has a thickness of not more than 100 μm (preferably, not more than 50 μm). The lengths of the first to fourth side surfaces 5A to 5D are set in a range of not less than 4 mm and not more than 6 mm, in this embodiment.

The semiconductor device 1A includes a first semiconductor region 6 of an n-type (first conductivity type) that is formed in a region (surface layer portion) on the first main surface 3 side inside the chip 2. The first semiconductor region 6 is formed in a layered shape extending along the first main surface 3 and is exposed from the first main surface 3 and the first to fourth side surfaces 5A to 5D. The first semiconductor region 6 consists of an epitaxial layer (specifically, an SiC epitaxial layer), in this embodiment. The first semiconductor region 6 may have a thickness of not less than 1 μm and not more than 50 μm in regard to the normal direction Z. The thickness of the first semiconductor region 6 is preferably not less than 3 μm and not more than 30 μm. The thickness of the first semiconductor region 6 is particularly preferably not less than 5 μm and not more than 25 μm.

The semiconductor device 1A includes a second semiconductor region 7 of the n-type that is formed in a region (surface layer portion) on the second main surface 4 side inside the chip 2. The second semiconductor region 7 is formed in a layered shape extending along the second main surface 4 and exposes from the second main surface 4 and the first to fourth side surfaces 5A to 5D. The second semiconductor region 7 has an n-type impurity concentration higher than that of the first semiconductor region 6 and is electrically connected to the first semiconductor region 6. The second semiconductor region 7 consists of a semiconductor substrate (specifically, an SiC semiconductor substrate), in this embodiment. That is, the chip 2 has a laminated structure including the semiconductor substrate and the epitaxial layer.

The second semiconductor region 7 may have a thickness of not less than 1 μm and not more than 200 μm in regard to the normal direction Z. The thickness of the second semiconductor region 7 is preferably not less than 5 μm and not more than 50 μm. The thickness of the second semiconductor region 7 is particularly preferably not less than 5 μm and not more than 20 μm. Considering an error to be occurred to the first semiconductor region 6, the thickness of the second semiconductor region 7 is preferably not less than 10 μm. The thickness of the second semiconductor region 7 is most preferably less than the thickness of the first semiconductor region 6. According to the second semiconductor region 7 having the relatively small thickness, a resistance value (for example, an on-resistance) due to the second semiconductor region 7 can be reduced. As a matter of course, the thickness of the second semiconductor region 7 may exceed the thickness of first semiconductor region 6.

The semiconductor device 1A includes an active surface 8 (active surface), an outer surface 9 (outer surface) and first to fourth connecting surfaces 10A to 10D (connecting surface) that are formed in the first main surface 3. The active surface 8, the outer surface 9 and the first to fourth connecting surfaces 10A to 10D define a mesa portion 11 (plateau) in the first main surface 3. The active surface 8 may be referred to as a “first surface portion”, the outer surface 9 may be referred to as a “second surface portion”, the first to fourth connecting surfaces 10A to 10D may be referred to as “connecting surface portions”. The active surface 8, the outer surface 9 and the first to fourth connecting surfaces 10A to 10D (that is, the mesa portion 11) may be considered as components of the chip 2 (the first main surface 3).

The active surface 8 is formed at an interval inward from a peripheral edge of the first main surface 3 (the first to fourth side surfaces 5A to 5D). The active surface 8 has a flat surface extending in the first direction X and the second direction Y. The active surface 8 is formed in a quadrangle shape having four sides parallel to the first to fourth side surfaces 5A to 5D in plan view, in this embodiment.

The outer surface 9 is positioned outside the active surface 8 and is recessed toward the thickness direction of the chip 2 (the second main surface 4 side) from the active surface 8. Specifically, the outer surface 9 is recessed with a depth less than the thickness of the first semiconductor region 6 such as to expose the first semiconductor region 6. The outer surface 9 extends along the active surface 8 in a band shape and is formed in an annular shape (specifically, a quadrangle annular shape) surrounding the active surface 8 in plan view. The outer surface 9 has a flat surface extending in the first direction X and the second direction Y and is formed substantially parallel to the active surface 8. The outer surface 9 is continuous to the first to fourth side surfaces 5A to 5D.

The first to fourth connecting surfaces 10A to 10D extend in the normal direction Z and connect the active surface 8 and the outer surface 9. The first connecting surface 10A is positioned on the first side surface 5A side, the second connecting surface 10B is positioned on the second side surface 5B side, the third connecting surface 10C is positioned on the third side surface 5C side, and the fourth connecting surface 10D is positioned on the fourth side surface 5D side. The first connecting surface 10A and the second connecting surface 10B extend in the first direction X and oppose in the second direction Y. The third connecting surface 10C and the fourth connecting surface 10D extend in the second direction Y and oppose in the first direction X.

The first to fourth connecting surfaces 10A to 10D may substantially vertically extend between the active surface 8 and the outer surface 9 such that the mesa portion 11 of a quadrangle columnar is defined. The first to fourth connecting surfaces 10A to 10D may be downwardly inclined from the active surface 8 to the outer surface 9 such that the mesa portion 11 of a quadrangle pyramid shape is defined. Thus, the semiconductor device 1A includes the mesa portion 11 that is formed in the first semiconductor region 6 at the first main surface 3. The mesa portion 11 is formed only in the first semiconductor region 6 and is not formed in the second semiconductor region 7.

The semiconductor device 1A includes a MISFET (Metal Insulator Semiconductor Field Effect Transistor) structure 12 that is formed in the active surface 8 (the first main surface 3). In FIG. 2 and FIG. 3, the MISFET structure 12 is shown simplified by a dashed line. Hereinafter, with reference to FIG. 4 and FIG. 5, a specific structure of the MISFET structure 12 shall be described.

The MISFET structure 12 includes a body region 13 of a p-type (second conductivity type) that is formed in a surface layer portion of the active surface 8. The body region 13 is formed at an interval to the active surface 8 side from a bottom portion of the first semiconductor region 6. The body region 13 is formed in a layered shape extending along the active surface 8. The body region 13 may be exposed from parts of the first to fourth connecting surfaces 10A to 10D.

The MISFET structure 12 includes a source region 14 of the n-type that is formed in a surface layer portion of the body region 13. The source region 14 has an n-type impurity concentration higher than that of the first semiconductor region 6. The source region 14 is formed at an interval to the active surface 8 side from a bottom portion of the body region 13. The source region 14 is formed in a layered shape extending along the active surface 8. The source region 14 may be exposed from a whole region of the active surface 8. The source region 14 may be exposed from parts of the first to fourth connecting surfaces 10A to 10D. The source region 14 forms a channel inside the body region 13 between the first semiconductor region 6 and the source region 14.

The MISFET structure 12 includes a plurality of gate structures 15 that are formed in the active surface 8. The plurality of gate structures 15 arrayed at intervals in the first direction X and each formed in a band shape extending in the second direction Y in plan view. The plurality of gate structures 15 penetrate the body region 13 and the source region 14 such as to reach the first semiconductor region 6. The plurality of gate structures 15 control a reversal and a non-reversal of the channel in the body region 13.

Each of the gate structures 15 includes a gate trench 15a, a gate insulating film 15b and a gate embedded electrode 15c, in this embodiment. The gate trench 15a is formed in the active surface 8 and defines a wall surface of the gate structure 15. The gate insulating film 15b covers the wall surface of the gate trench 15a. The gate embedded electrode 15c is embedded in the gate trench 15a with the gate insulating film 15b interposed therebetween and faces the channel across the gate insulating film 15b.

The MISFET structure 12 includes a plurality of source structures 16 that are formed in the active surface 8. The plurality of source structures 16 are each arranged at a region between a pair of adjacent gate structures 15 in the active surface 8. The plurality of source structures 16 are each formed in a band shape extending in the second direction Y in plan view. The plurality of source structures 16 penetrate the body region 13 and the source region 14 such as to reach the first semiconductor region 6. The plurality of source structures 16 have depths exceeding depths of the gate structures 15. Specifically, the plurality of source structures 16 has the depths substantially equal to the depth of the outer surface 9.

Each of the source structures 16 includes a source trench 16a, a source insulating film 16b and a source embedded electrode 16c. The source trench 16a is formed in the active surface 8 and defines a wall surface of the source structure 16. The source insulating film 16b covers the wall surface of the source trench 16a. The source embedded electrode 16c is embedded in the source trench 16a with the source insulating film 16b interposed therebetween.

The MISFET structure 12 includes a plurality of contact regions 17 of the p-type that are each formed in a region along the source structure 16 inside the chip 2. The plurality of contact regions 17 have a p-type impurity concentration higher than that of the body region 13. Each of the contact regions 17 covers the side wall and the bottom wall of each of the source structures, and is electrically connected to the body region 13.

The MISFET structure 12 includes a plurality of well regions 18 of the p-type that are each formed in a region along the source structure 16 inside the chip 2. Each of the well regions 18 may have a p-type impurity concentration higher than that of the body region 13 and less than that of the contact regions 17. Each of the well regions 18 covers the corresponding source structure 16 with the corresponding contact region 17 interposed therebetween. Each of the well regions 18 covers the side wall and the bottom wall of the corresponding source structure 16, and is electrically connected to the body region 13 and the contact regions 17.

With reference to FIG. 6, the semiconductor device 1A includes an outer contact region 19 of the p-type that is formed in a surface layer portion of the outer surface 9. The outer contact region 19 has a p-type impurity concentration higher than that of the body region 13. The outer contact region 19 is formed at intervals from a peripheral edge of the active surface 8 and a peripheral edge of the outer surface 9, and is formed in a band shape extending along the active surface 8 in plan view.

The outer contact region 19 is formed in an annular shape (specifically, a quadrangle annular shape) surrounding the active surface 8 in plan view, in this embodiment. The outer contact region 19 is formed at an interval to the outer surface 9 side from the bottom portion of the first semiconductor region 6. The outer contact region 19 is positioned on the bottom portion side of the first semiconductor region 6 with respect to the bottom walls of the plurality of gate structures 15 (the plurality of source structures 16).

The semiconductor device 1A includes an outer well region 20 of the p-type that is formed in the surface layer portion of the outer surface 9. The outer well region 20 has a p-type impurity concentration less than that of the outer contact region 19. The p-type impurity concentration of the outer well region 20 is preferably substantially equal to the p-type impurity concentration of the well regions 18. The outer well region 20 is formed in a region between the peripheral edge of the active surface 8 and the outer contact region 19, and is formed in a band shape extending along the active surface 8 in plan view.

The outer well region 20 is formed in an annular shape (specifically, a quadrangle annular shape) surrounding the active surface 8 in plan view, in this embodiment. The outer well region 20 is formed at an interval to the outer surface 9 side from the bottom portion of the first semiconductor region 6. The outer well region 20 may be formed deeper than the outer contact region 19. The outer well region 20 is positioned on the bottom portion side of the first semiconductor region 6 with respect to the plurality of gate structures 15 (the plurality of source structures 16).

The outer well region 20 is electrically connected to the outer contact region 19. The outer well region 20 extends toward the first to fourth connecting surfaces 10A to 10D side from the outer contact region 19 side, and covers the first to fourth connecting surfaces 10A to 10D, in this embodiment. The outer well region 20 is electrically connected to the body region 13 in the surface layer portion of the active surface 8.

The semiconductor device 1A includes at least one (preferably, not less than 2 and not more than 20) field region 21 of the p-type that is formed in a region between the peripheral edge of the outer surface 9 and the outer contact region 19 in the surface layer portion of the outer surface 9. The semiconductor device 1A includes five field regions 21, in this embodiment. The plurality of field regions 21 relaxes an electric field inside the chip 2 at the outer surface 9. A number, a width, a depth, a p-type impurity concentration, etc., of the field region 21 are arbitrary, and various values can be taken depending on the electric field to be relaxed.

The plurality of field regions 21 are arrayed at intervals from the outer contact region 19 side to the peripheral edge side of the outer surface 9. The plurality of field regions 21 are each formed in a band shape extending along the active surface 8 in plan view. The plurality of field regions 21 are each formed in an annular shape (specifically, a quadrangle annular shape) surrounding the active surface 8 in plan view, in this embodiment. Thus, the plurality of field regions 21 are each formed as an FLR (Field Limiting Ring) region.

The plurality of field regions 21 are formed at intervals to the outer surface 9 side from the bottom portion of the first semiconductor region 6. The plurality of field regions 21 are positioned on the bottom portion side of the first semiconductor region 6 with respect to the bottom walls of the plurality of gate structures 15 (the plurality of source structures 16). The plurality of field regions 21 may be formed deeper than the outer contact region 19. The innermost field region 21 may be connected to the outer contact region 19.

The semiconductor device 1A includes a main surface insulating film 25 that covers the first main surface 3. The main surface insulating film 25 may include at least one of a silicon oxide film, a silicon nitride film and a silicon oxynitride film. The main surface insulating film 25 has a single layered structure consisting of the silicon oxide film, in this embodiment. The main surface insulating film 25 particularly preferably includes the silicon oxide film that consists of an oxide of the chip 2.

The main surface insulating film 25 covers the active surface 8, the outer surface 9 and the first to fourth connecting surfaces 10A to 10D. The main surface insulating film 25 covers the active surface 8 such as to be continuous to the gate insulating film 15b and the source insulating film 16b and to expose the gate embedded electrode 15c and the source embedded electrode 16c. The main surface insulating film 25 covers the outer surface 9 and the first to fourth connecting surfaces 10A to 10D such as to cover the outer contact region 19, the outer well region 20 and the plurality of field regions 21.

The main surface insulating film 25 may be continuous to the first to fourth side surfaces 5A to 5D. In this case, an outer wall of the main surface insulating film 25 may consist of a ground surface with grinding marks. The outer wall of the main surface insulating film 25 may form a single ground surface with the first to fourth side surfaces 5A to 5D. As a matter of course, the outer wall of the main surface insulating film 25 may be formed at an interval inward from the peripheral edge of the outer surface 9 and may expose the first semiconductor region 6 from a peripheral edge portion of the outer surface 9.

The semiconductor device 1A includes a side wall structure 26 that is formed on the main surface insulating film 25 such as to cover at least one of the first to fourth connecting surfaces 10A to 10D at the outer surface 9. The side wall structure 26 is formed in an annular shape (a quadrangle annular shape) surrounding the active surface 8 in plan view, in this embodiment. The side wall structure 26 may have a portion that overlaps onto the active surface 8. The side wall structure 26 may include an inorganic insulator or a polysilicon. The side wall structure 26 may be a side wall wiring that is electrically connected to the plurality of source structures 16.

The semiconductor device 1A includes an interlayer insulating film 27 that is formed on the main surface insulating film 25. The interlayer insulating film 27 may include at least one of a silicon oxide film, a silicon nitride film and a silicon oxynitride film. The interlayer insulating film 27 has a single layered structure consisting of the silicon oxide film, in this embodiment.

The interlayer insulating film 27 covers the active surface 8, the outer surface 9 and the first to fourth connecting surfaces 10A to 10D with the main surface insulating film 25 interposed therebetween. Specifically, the interlayer insulating film 27 covers the active surface 8, the outer surface 9 and the first to fourth connecting surfaces 10A to 10D across the side wall structure 26. The interlayer insulating film 27 covers the MISFET structure 12 on the active surface 8 side and covers the outer contact region 19, the outer well region 20 and the plurality of field regions 21 on the outer surface 9 side.

The interlayer insulating film 27 is continuous to the first to fourth side surfaces 5A to 5D, in this embodiment. An outer wall of the interlayer insulating film 27 may consist of a ground surface with grinding marks. The outer wall of the interlayer insulating film 27 may form a single ground surface with the first to fourth side surfaces 5A to 5D. As a matter of course, the outer wall of the interlayer insulating film 27 may be formed at an interval inward from the peripheral edge of the outer surface 9 and may expose the first semiconductor region 6 from the peripheral edge portion of the outer surface 9.

The semiconductor device 1A includes a gate electrode 30 that is arranged on the first main surface 3 (the interlayer insulating film 27). The gate electrode 30 may be referred to as a “gate main surface electrode”. The gate electrode 30 is arranged at an inner portion of the first main surface 3 at an interval from the peripheral edge of the first main surface 3. The gate electrode 30 is arranged on the active surface 8, in this embodiment. Specifically, the gate electrode 30 is arranged on a region adjacent a central portion of the third connecting surface 10C (the third side surface 5C) at the peripheral edge portion of the active surface 8. The gate electrode 30 is formed in a quadrangle shape in plan view, in this embodiment. As a matter of course, the gate electrode 30 may be formed in a polygonal shape other than the quadrangle shape, a circular shape, or an elliptical shape in plan view.

The gate electrode 30 preferably has a planar area of not more than 25% of the first main surface 3. The planar area of the gate electrode 30 may be not more than 10% of the first main surface 3. The gate electrode 30 may have a thickness of not less than 0.5 μm and not more than 15 μm. The gate electrode 30 may include at least one of a Ti film, a TiN film, a W film, an Al film, a Cu film, an Al alloy film, a Cu alloy film and a conductive polysilicon film.

The gate electrode 30 may include at least one of a pure Cu film (Cu film with a purity of not less than 99%), a pure Al film (Al film with a purity of not less than 99%), an AlCu alloy film, an AlSi alloy film and an AlSiCu alloy film. The gate electrode 30 has a laminated structure that includes the Ti film and the Al alloy film (in this embodiment, AlSiCu alloy film) laminated in that order from the chip 2 side, in this embodiment.

The semiconductor device 1A includes a source electrode 32 that is arranged on the first main surface 3 (the interlayer insulating film 27) at an interval from the gate electrode 30. The source electrode 32 may be referred to as a “source main surface electrode”. The source electrode 32 is arranged at an inner portion of the first main surface 3 at an interval from the peripheral edge of the first main surface 3. The source electrode 32 is arranged on the active surface 8, in this embodiment. The source electrode 32 has a body electrode portion 33 and at least one (in this embodiment, a plurality of) drawer electrode portions 34A, 34B, in this embodiment.

The body electrode portion 33 is arrange at a region on the fourth side surface 5D (the fourth connecting surface 10D) side at an interval from the gate electrode 30 and faces the gate electrode 30 in the first direction X, in plan view. The body electrode portion 33 is formed in a polygonal shape (specifically, quadrangle shape) that has four sides parallel to the first to fourth side surfaces 5A to 5D in plan view, in this embodiment.

The plurality of drawer electrode portions 34A, 34B include a first drawer electrode portion 34A on one side (the first side surface 5A side) and a second drawer electrode portion 34B on the other side (the second side surface 5B side). The first drawer electrode portion 34A is drawn out from the body electrode portion 33 onto a region located on one side (the first side surface 5A side) of the second direction Y with respect to the gate electrode 30, and faces the gate electrode 30 in the second direction Y, in plan view.

The second drawer electrode portion 34B is drawn out from the body electrode portion 33 onto a region located on the other side (the second side surface 5B side) of the second direction Y with respect to the gate electrode 30, and faces the gate electrode 30 in the second direction Y, in plan view. That is, the plurality of drawer electrode portions 34A, 34B sandwich the gate electrode 30 from both sides of the second direction Y, in plan view.

The source electrode 32 (the body electrode portion 33 and the drawer electrode portions 34A, 34B) penetrates the interlayer insulating film 27 and the main surface insulating film 25, and is electrically connected to the plurality of source structures 16, the source region 14 and the plurality of well regions 18. As a matter of course, the source electrode 32 does not may have the drawer electrode portions 34A, 34B and may consist only of the body electrode portion 33.

The source electrode 32 has a planar area exceeding the planar are of the gate electrode 30. The planar area of the source electrode 32 is preferably not less than 50% of the first main surface 3. The planar are of the source electrode 32 is particularly preferably not less than 75% of the first main surface 3. The source electrode 32 may have a thickness of not less than 0.5 μm and not more than 15 μm. The source electrode 32 may include at least one of a Ti film, a TiN film, a W film, an Al film, a Cu film, an Al alloy film, a Cu alloy film and a conductive polysilicon film.

The source electrode 32 preferably includes at least one of a pure Cu film (Cu film with a purity of not less than 99%), a pure Al film (Al film with a purity of not less than 99%), an AlCu alloy film, an AlSi alloy film and an AlSiCu alloy film. The source electrode 32 has a laminated structure that includes the Ti film and the Al alloy film (in this embodiment, AlSiCu alloy film) laminated in that order from the chip 2 side, in this embodiment. The source electrode 32 preferably has the same conductive material as that of the gate electrode 30.

The semiconductor device 1A includes at least one (in this embodiment, a plurality of) gate wirings 36A, 36B that are drawn out from the gate electrode 30 onto the first main surface 3 (the interlayer insulating film 27). The plurality of gate wirings 36A, 36B preferably has the same conductive material as that of the gate electrode 30. The plurality of gate wirings 36A, 36B cover the active surface 8 and do not cover the outer surface 9, in this embodiment. The plurality of gate wirings 36A, 36B are drawn out into a region between the peripheral edge of the active surface 8 and the source electrode 32 and each extends in a band shape along the source electrode 32 in plan view.

Specifically, the plurality of gate wirings 36A, 36B include a first gate wiring 36A and a second gate wiring 36B. The first gate wiring 36A is drawn out from the gate electrode 30 into a region on the first side surface 5A side in plan view. The first gate wiring 36A includes a portion extending as a band shape in the second direction Y along the third side surface 5C and a portion extending as a band shape in the first direction X along the first side surface 5A. The second gate wiring 36B is drawn out from the gate electrode 30 into a region on the second side surface 5B side in plan view. The second gate wiring 36B includes a portion extending as a band shape in the second direction Y along the third side surface 5C and a portion extending as a band shape in the first direction X along the second side surface 5B.

The plurality of gate wirings 36A, 36B intersect (specifically, perpendicularly intersect) both end portions of the plurality of gate structures 15 at the peripheral edge portion of the active surface 8 (the first main surface 3). The plurality of gate wirings 36A, 36B penetrate the interlayer insulating film 27 and are electrically connected to the plurality of gate structures 15. The plurality of gate wirings 36A, 36B may be directly connected to the plurality of gate structures 15, or may be electrically connected to the plurality of gate structures 15 via a conductor film.

The semiconductor device 1A includes a source wiring 37 that is drawn out from the source electrode 32 onto the first main surface 3 (the interlayer insulating film 27). The source wiring 37 preferably has the same conductive material as that of the source electrode 32. The source wiring 37 is formed in a band shape extending along the peripheral edge of the active surface 8 at a region located on the outer surface 9 side than the plurality of gate wirings 36A, 36B. The source wiring 37 is formed in an annular shape (specifically, a quadrangle annular shape) surrounding the gate electrode 30, the source electrode 32 and the plurality of gate wirings 36A, 36B in plan view, in this embodiment.

The source wiring 37 covers the side wall structure 26 with the interlayer insulating film 27 interposed therebetween and is drawn out from the active surface 8 side to the outer surface 9 side. The source wiring 37 preferably covers a whole region of the side wall structure 26 over an entire circumference. The source wiring 37 penetrates the interlayer insulating film 27 and the main surface insulating film 25 at the outer surface 9 side, and has a portion connected to the outer surface 9 (specifically, the outer contact region 19). The source wiring 37 may penetrate the interlayer insulating film 27 and may be electrically connected to the side wall structure 26.

The semiconductor device 1A includes an upper insulating film 38 that selectively covers the gate electrode 30, the source electrode 32, the plurality of gate wirings 36A, 36B and the source wiring 37. The upper insulating film 38 has a gate opening 39 exposing an inner portion of the gate electrode 30 and covers a peripheral edge portion of the gate electrode 30 over an entire circumference. The gate opening 39 is formed in a quadrangle shape in plan view, in this embodiment.

The upper insulating film 38 has a source opening 40 exposing an inner portion of the source electrode 32 and covers a peripheral edge portion of the source electrode 32 over an entire circumference. The source opening 40 is formed in a polygonal shape along the source electrode 32 in plan view, in this embodiment. The upper insulating film 38 covers whole regions of the plurality of gate wirings 36A, 36B and a whole region of the source wiring 37.

The upper insulating film 38 covers the side wall structure 26 with the interlayer insulating film 27 interposed therebetween, and is drawn out from the active surface 8 side to the outer surface 9 side. The upper insulating film 38 is formed at an interval inward from the peripheral edge of the outer surface 9 (the first to fourth side surfaces 5A to 5D) and covers the outer contact region 19, the outer well region 20 and the plurality of field regions 21. The upper insulating film 38 defines a dicing street 41 with the peripheral edge of the outer surface 9.

The dicing street 41 is formed in a band shape extending along the peripheral edge of the outer surface 9 (the first to fourth side surfaces 5A to 5D) in plan view. The dicing street 41 is formed in an annular shape (specifically, a quadrangle annular shape) surrounding the inner portion of the first main surface 3 (the active surface 8) in plan view, in this embodiment. The dicing street 41 exposes the interlayer insulating film 27, in this embodiment.

As a matter of course, in a case in which the main surface insulating film 25 and the interlayer insulating film 27 expose the outer surface 9, the dicing street 41 may expose the outer surface 9. The dicing street 41 may have a width of not less than 1 μm and not more than 200 μm. The width of the dicing street 41 is a width in a direction orthogonal to an extending direction of the dicing street 41. The width of the dicing street 41 is preferably not less than 5 μm and not more than 50 μm.

The upper insulating film 38 preferably has a thickness exceeding the thickness of the gate electrode 30 and the thickness of the source electrode 32. The thickness of the upper insulating film 38 is preferably less than the thickness of the chip 2. The thickness of the upper insulating film 38 may be not less than 3 μm and not more than 35 μm. The thickness of the upper insulating film 38 is preferably not more than 25 μm.

The upper insulating film 38 has a laminated structure that includes an inorganic insulating film 42 and an organic insulating film 43 laminated in that order form the chip 2 side, in this embodiment. The upper insulating film 38 may include at least one of the inorganic insulating film 42 and the organic insulating film 43, and does not necessarily have to include the inorganic insulating film 42 and the organic insulating film 43 at the same time. The inorganic insulating film 42 selectively covers the gate electrode 30, the source electrode 32, the plurality of gate wirings 36A, 36B and the source wiring 37, and defines a part of the gate opening 39, a part of the source opening 40 and a part of the dicing street 41.

The inorganic insulating film 42 may include at least one of a silicon oxide film, a silicon nitride film and a silicon oxynitride film. The inorganic insulating film 42 preferably includes an insulating material different from that of the interlayer insulating film 27. The inorganic insulating film 42 preferably includes the silicon nitride film. The inorganic insulating film 42 preferably has a thickness less than the thickness of the interlayer insulating film 27. The thickness of the inorganic insulating film 42 may be not less than 0.1 μm and not more than 5 μm.

The organic insulating film 43 selectively covers the inorganic insulating film 42, and defines a part of the gate opening 39, a part of the source opening 40 and a part of the dicing street 41. Specifically, the organic insulating film 43 partially exposes the inorganic insulating film 42 in a wall surface of the gate opening 39. Also, the organic insulating film 43 partially exposes the inorganic insulating film 42 in a wall surface of the source opening 40. Also, the organic insulating film 43 partially exposes the inorganic insulating film 42 in a wall surface of the dicing street 41.

As a matter of course, the organic insulating film 43 may cover the inorganic insulating film 42 such that the inorganic insulating film 42 does not expose from the wall surface of the gate opening 39. The organic insulating film 43 may cover the inorganic insulating film 42 such that the inorganic insulating film 42 does not expose from the wall surface of the source opening 40. The organic insulating film 43 may cover the inorganic insulating film 42 such that the inorganic insulating film 42 does not expose from the wall surface of the dicing street 41. In those cases, the organic insulating film 43 may cover a whole region of the inorganic insulating film 42.

The organic insulating film 43 preferably consists of a resin film other than a thermosetting resin. The organic insulating film 43 may consist of a translucent resin or a transparent resin. The organic insulating film 43 may consist of a negative type photosensitive resin film or a positive type photosensitive resin film. The organic insulating film 43 preferably consists of a polyimide film, a polyamide film or a polybenzoxazole film. The organic insulating film 43 includes the polybenzoxazole film, in this embodiment.

The organic insulating film 43 preferably has a thickness exceeding the thickness of the inorganic insulating film 42. The thickness of the organic insulating film 43 preferably exceeds the thickness of the interlayer insulating film 27. The thickness of the organic insulating film 43 particularly preferably exceeds the thickness of the gate electrode 30 and the thickness of the source electrode 32. The thickness of the organic insulating film 43 may be not less than 3 μm and not more than 30 μm. The thickness of the organic insulating film 43 is preferably not more than 20 μm.

With mainly reference to FIG. 1, FIG. 2 and FIG. 9, the semiconductor device 1A includes a gate terminal electrode 45 that is arranged on the gate electrode 30. The gate terminal electrode 45 is erected in a columnar shape on a portion that is exposed from the gate opening 39 in the gate electrode 30. The gate terminal electrode 45 has a ruggedness structure. Specifically, the gate terminal electrode 45 has a gate terminal surface 46 and a gate terminal side wall 47, and has a gate recessed portion 48 that is recessed toward the gate electrode 30 in the gate terminal surface 46.

A site at which the gate recessed portion 48 is formed is arbitrary. In this embodiment, the gate recessed portion 48 is formed in a notched shape at a corner portion of the gate terminal surface 46 such as to be continuous to the gate terminal side wall 47 and defines a step portion in the gate terminal side wall 47. In this embodiment, the gate recessed portion 48 is formed in an annular shape that extends along a peripheral edge of the gate terminal surface 46 such as to surround an inner portion of the gate terminal surface 46 in plan view.

The gate terminal electrode 45 preferably has a thickness exceeding the thickness of the gate electrode 30. The thickness of the gate terminal electrode 45 particularly preferably exceeds the thickness of the upper insulating film 38. The thickness of the gate terminal electrode 45 exceeds the thickness of the chip 2, in this embodiment. As a matter of course, the thickness of the gate terminal electrode 45 may be less than the thickness of the chip 2. The thickness of the gate terminal electrode 45 may be not less than 10 μm and not more than 300 μm. The thickness of the gate terminal electrode 45 is preferably not less than 30 μm. The thickness of the gate terminal electrode 45 is particularly preferably not less than 80 μm and not more than 200 μm.

In this embodiment, the gate terminal electrode 45 has a laminated structure that includes a first gate terminal layer 49 (first layer portion) and a second gate terminal layer 50 (second layer portion). The first gate terminal layer 49 is arranged on an inner portion of the gate electrode 30 at an interval from a peripheral edge of the gate electrode 30. The first gate terminal layer 49 has a portion that is drawn out onto the upper insulating film 38 from on the gate electrode 30, and positioned on the upper insulating film 38. That is, the first gate terminal layer 49 includes a portion that is in contact with the inorganic insulating film 42 and the organic insulating film 43. The first gate terminal layer 49 includes a portion that opposes the gate electrode 30 across the upper insulating film 38.

The first gate terminal layer 49 has a first gate main surface 49a (first layer main surface) and a first gate side wall 49b (first layer side wall). The first gate main surface 49a flatly extends along the first main surface 3. In this embodiment, the first gate main surface 49a consists of a ground surface with grinding marks. The first gate side wall 49b forms a part of the gate terminal side wall 47. In this embodiment, the first gate side wall 49b is positioned on the upper insulating film 38 (specifically, organic insulating film 43). The first gate side wall 49b substantially perpendicularly extends in the normal direction Z. “Substantially perpendicularly” includes a mode that extends in a laminated direction while being curved (meandering). The first gate side wall 49b preferably consists of a flat surface without grinding marks.

The first gate terminal layer 49 has a first protrusion portion 51 that outwardly protrudes at a lower end portion of the first gate side wall 49b, in this embodiment. The first protrusion portion 49 is formed at a region on the upper insulating film 38 (the organic insulating film 43) side than an intermediate portion of the first gate side wall 49b. The first protrusion portion 51 extends along an outer surface of the upper insulating film 38, and is formed in a tapered shape in which a thickness gradually decreases toward a tip portion from the first gate side wall 49b in cross sectional view. The first protrusion portion 51 therefore has a sharp-shaped tip portion with an acute angle. As a matter of course, the first gate terminal layer 49 without the first protrusion portion 51 may be formed.

The first gate terminal layer 49 has a first gate planar area and a first gate thickness. The first gate planar area is defined by a planar area of the first gate main surface 49a. The first gate thickness is defined by a distance between the gate electrode 30 and the first gate main surface 49a. The first gate planar area is adjusted according to a planar area of the first main surface 3. The first gate planar area is preferably less than the planar area of the gate electrode 30. The first gate planar area is preferably not more than 25% of the first main surface 3. The first gate planar area is particularly preferably not more than 10% of the first main surface 3.

When the first main surface 3 has the planar area of not less than 1 mm square, the first gate planar area may be not less than 0.4 mm square. The first gate terminal layer 49 may be formed in a polygonal shape (for example, rectangular shape) having a planar area of not less than 0.4 mm×0.7 mm. The first gate terminal layer 49 is formed in a quadrangle shape parallel to the first to fourth side surfaces 5A to 5D in plan view, in this embodiment. As a matter of course, the first gate terminal layer 49 may be formed in a polygonal shape other than the quadrangle shape, a circular shape, or an elliptical shape in plan view.

The first gate thickness preferably exceeds a thickness of the gate electrode 30. The first gate thickness particularly preferably exceeds the thickness of the upper insulating film 38. The first gate thickness may be not more than a thickness of the chip 2 or may exceed the thickness of the chip 2. The first gate thickness may be not less than ½ of a total thickness of the gate terminal electrode 45 or may be not more than ½ of the total thickness of the gate terminal electrode 45.

In this embodiment, the first gate terminal layer 49 has a laminated structure that includes a first gate conductor film 52 and a second gate conductor film 53 laminated in that order from the gate electrode 30 side. The first gate conductor film 52 may include a Ti-based metal film. The first gate conductor film 52 may have a single layered structure consisting of a Ti film or a TiN film. The first gate conductor film 52 may have a laminated structure that includes a Ti film and a TiN film laminated in an arbitrary order.

The first gate conductor film 52 has a thickness of less than the thickness of the gate electrode 30. The first gate conductor film 52 covers the gate electrode 30 in a film shape inside the gate opening 39 and is drawn out onto the upper insulating film 38 in a film shape. The first gate conductor film 52 forms a part of the first protrusion portion 51. The first gate conductor film 52 is not necessarily formed but may be removed.

The second gate conductor film 53 forms a main body of the first gate terminal layer 49. The second gate conductor film 53 may include a Cu-based metal film. The Cu-based metal film may be a pure Cu film (Cu film with a purity of not less than 99%) or a Cu alloy film. In this embodiment, the second gate conductor film 53 includes a pure Cu plating film. The second gate conductor film 53 preferably has a thickness exceeding the thickness of the gate electrode 30. The thickness of the second gate conductor film 53 particularly preferably exceeds the thickness of the upper insulating film 38. In this embodiment, the thickness of the second gate conductor film 53 exceeds the thickness of the chip 2.

The second gate conductor film 53 covers the gate electrode 30 across the first gate conductor film 52 inside the gate opening 39 and is drawn out onto the upper insulating film 38 in a film shape across the first gate conductor film 52. The second gate conductor film 53 forms a part of the first protrusion portion 51. That is, the first protrusion portion 51 has a laminated structure that includes the first gate conductor film 52 and the second gate conductor film 53. The second gate conductor film 53 preferably has a thickness exceeding the thickness of the first gate conductor film 52 inside the first protrusion portion 51.

The second gate terminal layer 50 protrudes toward the opposite side with respect to the chip 2 from the first gate terminal layer 49 such as to define the gate recessed portion 48 with the first gate terminal layer 49. That is, the second gate terminal layer 50 is arranged on the first gate main surface 49a such as to expose a part of the first gate main surface 49a. In this embodiment, the second gate terminal layer 50 includes a portion that is formed at an interval inward from a peripheral edge of the first gate terminal layer 49 such as to define the gate recessed portion 48 in a notched shape with the peripheral edge (first gate side wall 49b) of the first gate terminal layer 49.

In this embodiment, the second gate terminal layer 50 defines the gate recessed portion 48 that is arranged at an interval inward from an entire peripheral edge of the first gate terminal layer 49 and exposes a peripheral edge portion of the first gate main surface 49a over an entire circumference. That is, in this embodiment, the gate recessed portion 48 is formed in an annular shape that surrounds the second gate terminal layer 50 in plan view.

The second gate terminal layer 50 has a second gate main surface 50a (second layer main surface) and a second gate side wall 50b (second layer side wall). The second gate main surface 50a is formed as the gate terminal surface 46. The second gate main surface 50a flatly extends along the first gate main surface 49a. In this embodiment, the second gate main surface 50a consists of a ground surface with grinding marks.

The second gate side wall 50b is positioned on the first gate main surface 49a and forms a part of the gate terminal side wall 47. In this embodiment, the second gate side wall 50b defines the gate recessed portion 48 that exposes the first gate main surface 49a with the first gate side wall 49b. That is, in this embodiment, the gate terminal side wall 47 is defined by the first gate main surface 49a, the first gate side wall 49b and the second gate side wall 50b. The second gate side wall 50b substantially perpendicularly extends in the normal direction Z. “Substantially perpendicularly” includes a mode that extends in a laminated direction while being curved (meandering). The second gate side wall 50b preferably consists of a flat surface without grinding marks.

The second gate side wall 50b is preferably formed in a portion that opposes the gate electrode 30 across the first gate terminal layer 49. That is, the second gate terminal layer 50 preferably opposes only the gate electrode 30 across the first gate terminal layer 49. As a matter of course, the second gate side wall 50b may be formed in a portion that opposes the upper insulating film 38 across the first gate terminal layer 49. That is, the second gate terminal layer 50 may have a portion that opposes the upper insulating film 38 across the first gate terminal layer 49.

The second gate terminal layer 50 has a second gate planar area and a second gate thickness. The second gate planar area is defined by a planar area of the second gate main surface 50a (gate terminal surface 46). The second gate thickness is defined by a distance between the first gate main surface 49a and the second gate main surface 50a. The second gate planar area is less than the first gate planar area of the first gate terminal layer 49 and adjusted according to the first gate planar area. The second gate planar area is preferably not more than 25% of the first main surface 3. The second gate planar area is particularly preferably not more than 10% of the first main surface 3.

When the first main surface 3 has the planar area of not less than 1 mm square, the second gate planar area may be not less than 0.4 mm square. The second gate terminal layer 50 may be formed in a polygonal shape (for example, rectangular shape) having a planar area of not less than 0.4 mm×0.7 mm. The second gate terminal layer 50 is formed in a polygonal shape (quadrangle shape with four corners cut out in a rectangular shape) having four sides parallel to the first to fourth side surfaces 5A to 5D in plan view, in this embodiment.

That is, the second gate terminal layer 50 has a planar shape that is not similar to a planar shape of the first gate terminal layer 49. As a matter of course, the second gate terminal layer 50 may have a planar shape similar to the planar shape of the first gate terminal layer 49. Further, the second gate terminal layer 50 may be formed in a polygonal shape other than a quadrangle shape, a circular shape or an elliptical shape in plan view.

The second gate thickness preferably exceeds the thickness of the gate electrode 30. The second gate thickness particularly preferably exceeds the thickness of the upper insulating film 38. The second gate thickness may be not more than the thickness of the chip 2 or may exceed the thickness of the chip 2. The second gate thickness may be not less than ½ of a total thickness of the gate terminal electrode 45 or may be not more than ½ of the total thickness of the gate terminal electrode 45.

The second gate thickness may be substantially equal to the first gate thickness of the first gate terminal layer 49, may be not less than the first gate thickness or may be less than the first gate thickness. The second gate thickness particularly preferably exceeds the first gate thickness. In this case, the gate recessed portion 48 that has a depth exceeding the first gate thickness is defined.

In this embodiment, the second gate terminal layer 50 has a single layered structure consisting of a third gate conductor film 54 arranged on the first gate terminal layer 49. The third gate conductor film 54 (second gate terminal layer 50) may form a plurality of fine void spaces in a boundary portion with the second gate conductor film 53 (first gate terminal layer 49).

The third gate conductor film 54 may include a Cu-based metal film. The Cu-based metal film may be a pure Cu film (Cu film with a purity of not less than 99%) or a Cu alloy film. In this embodiment, the third gate conductor film 54 includes a pure Cu plating film. As a matter of course, the second gate terminal layer 50 may have a laminated structure that includes the first gate conductor film 52 and the second gate conductor film 53 laminated in that order from the first gate terminal layer 49 side, as with the case of the first gate terminal layer 49.

As described so far, the gate terminal electrode 45 has a ruggedness structure that includes the gate recessed portion 48. A volume of the gate terminal electrode 45 is reduced only by an extent of the gate recessed portion 48. A planar shape, an area, a depth, etc., of the gate recessed portion 48 are adjusted by adjusting a planar shape, an area and a thickness of the second gate terminal layer 50. The second gate terminal layer 50 is to be a connecting portion to which conducting wires (for example, a bonding wire and a conductor plate) or conductive adhesives (for example, a solder and a conductive paste), etc., are connected. Therefore, a mode of the second gate terminal layer 50 is adjusted, as long as a connection area with conducting wires, conductive adhesives, etc., is secured.

With mainly reference to FIGS. 1 to 3 and FIG. 10, the semiconductor device 1A includes a source terminal electrode 55 that is arranged on the source electrode 32. The source terminal electrode 55 is erected in a columnar shape on a portion of the source electrode 32 that is exposed from the source opening 40. The source terminal electrode 55 is arranged on the body electrode portion 33 of the source electrode 32, and is not arranged on the drawer electrode portions 34A, 34B of the source electrode 32, in this embodiment.

A facing area between the gate terminal electrode 45 and the source terminal electrode 55 is thereby reduced. Such a structure is effective in reducing a risk of short-circuit between the gate terminal electrode 45 and the source terminal electrode 55, in a case in which conductive adhesives such as solders and metal pastes are to be adhered to the gate terminal electrode 45 and the source terminal electrode 55. As a matter of course, conductive bonding members such as conductor plates and conducting wires (for example, bonding wires) may be connected to the gate terminal electrode 45 and the source terminal electrode 55. In this case, a risk of short-circuit between the conductive bonding member on the gate terminal electrode 45 side and the conductive bonding member on the source terminal electrode 55 side can be reduced.

The source terminal electrode 55 has a ruggedness structure. Specifically, the source terminal electrode 55 has a source terminal surface 56 and a source terminal side wall 57, and has a source recessed portion 58 that is recessed from the source terminal surface 56 toward the source electrode 32. A site at which the source recessed portion 58 is formed is arbitrary. In this embodiment, the source recessed portion 58 is formed in a notched shape at a corner portion of the source terminal surface 56f such as to be continuous to the source terminal side wall 57, and defines a step portion in the source terminal side wall 57. In this embodiment, the source recessed portion 58 is formed in an annular shape extending along a peripheral edge of the source terminal surface 56 such as to surround an inner portion of the source terminal surface 56 in plan view.

The source terminal electrode 55 preferably has a thickness exceeding the thickness of the source electrode 32. The thickness of the source terminal electrode 55 particularly preferably exceeds the thickness of the upper insulating film 38. The thickness of the source terminal electrode 55 exceeds the thickness of the chip 2, in this embodiment. As a matter of course, the thickness of the source terminal electrode 55 may be less than the thickness of the chip 2. The thickness of the source terminal electrode 55 may be not less than 10 μm and not more than 300 μm. The thickness of the source terminal electrode 55 is preferably not less than 30 μm. The thickness of the source terminal electrode 55 is particularly preferably not less than 80 μm and not more than 200 μm. The thickness of the source terminal electrode 55 is substantially equal to the thickness of the gate terminal electrode 45.

Specifically, the source terminal electrode 55 has a laminated structure that includes a first source terminal layer 59 (first layer portion) and a second source terminal layer 60 (second layer portion). The first source terminal layer 59 is arranged on an inner portion of the source electrode 32 at an interval from a peripheral edge of the source electrode 32. The first source terminal layer 59 has a portion that is drawn out onto the upper insulating film 38 from on the source electrode 32 and positioned on the upper insulating film 38. That is, the first source terminal layer 59 includes a portion in contact with the inorganic insulating film 42 and the organic insulating film 43. The first source terminal layer 59 includes a portion that opposes the source electrode 32 across the upper insulating film 38.

The first source terminal layer 59 has a first source main surface 59a (first layer main surface) and a first source side wall 59b (first layer side wall). The first source main surface 59a flatly extends along the first main surface 3. In this embodiment, the first source main surface 59a consists of a ground surface with grinding marks. The first source side wall 59b forms a part of the source terminal side wall 57. In this embodiment, the first source side wall 59b is positioned on the upper insulating film 38 (specifically, organic insulating film 43). The first source side wall 59b substantially perpendicularly extends in the normal direction Z. “Substantially perpendicularly” includes a mode that extends in a laminated direction while being curved (meandering). The first source side wall 59b preferably consists of a flat surface without grinding marks.

In this embodiment, the first source terminal layer 59 has a second protrusion portion 61 that outwardly protrudes at a lower end portion of the first source side wall 59b. The second protrusion portion 61 is formed in a region on the upper insulating film 38 (organic insulating film 43) side further than an intermediate portion of the first source side wall 59b. The second protrusion portion 61 extends along an outer surface of the upper insulating film 38 and is formed in a tapered shape in which a thickness gradually decreases toward a tip portion from the first source side wall 59b in cross sectional view. Thereby, the second protrusion portion 61 has a sharp-shaped tip portion with an acute angle. As a matter of course, the first source terminal layer 59 without the second protrusion portion 61 may be formed.

The first source terminal layer 59 has a first source planar area and a first source thickness. The first source planar area is defined by a planar area of the first source main surface 59a. The first source thickness is defined by a distance between the gate electrode 30 and the first source main surface 59a. The first source planar area is adjusted according to the planar area of the first main surface 3.

The first source planar area preferably exceeds a first gate planar area of the first gate terminal layer 49. The first source planar area is preferably less than a planar area of the source electrode 32. The first source planar area is preferably not less than 50% of the first main surface 3. The first source planar area is particularly preferably not less than 75% of the first main surface 3.

When the first main surface 3 has the planar area of not less than 1 mm square, the first source planar area is preferably not less than 0.8 mm square. In this case, the first source planar area is particularly preferably not less than 1 mm square. The first source terminal layer 59 may be formed in a polygonal shape having a planar area of not less than 1 mm×1.4 mm. The first source terminal layer 59 is formed in a quadrangle shape parallel to the first to fourth side surfaces 5A to 5D in plan view, in this embodiment. As a matter of course, the first source terminal layer 59 may be formed in a polygonal shape other than the quadrangle shape, a circular shape, or an elliptical shape in plan view.

The first source thickness preferably exceeds the thickness of the source electrode 32. The first source thickness particularly preferably exceeds the thickness of the upper insulating film 38. The first source thickness may be not more than the thickness of the chip 2 or may exceed the thickness of the chip 2. The first source thickness may be not less than ½ of a total thickness of the source terminal electrode 55 or may be not more than ½ of the total thickness of the source terminal electrode 55. In this embodiment, the first source thickness is substantially equal to the first gate thickness of the first gate terminal layer 49.

In this embodiment, the first source terminal layer 59 has a laminated structure that includes a first source conductor film 62 and a second source conductor film 63 laminated in that order from the source electrode 32 side. The first source conductor film 62 may include a Ti-based metal film. The first source conductor film 62 may have a single layered structure consisting of a Ti film or a TiN film. The first source conductor film 62 may have a laminated structure that includes a Ti film and a TiN film laminated in an arbitrary order. The first source conductor film 62 preferably consists of the same conductive material as that of the first gate conductor film 52.

The first source conductor film 62 has a thickness of less than the thickness of the source electrode 32. The first source conductor film 62 covers the source electrode 32 in a film shape inside the source opening 40 and is drawn out onto the upper insulating film 38 in a film shape. The first source conductor film 62 forms a part of the second protrusion portion 61. The thickness of the first source conductor film 62 is substantially equal to the thickness of the first gate conductor film 52. The first source conductor film 62 is not necessarily formed but may be removed.

The second source conductor film 63 forms a main body of the first source terminal layer 59. The second source conductor film 63 may include a Cu-based metal film. The Cu-based metal film may be a pure Cu film (Cu film with a purity of not less than 99%) or a Cu alloy film. In this embodiment, the second source conductor film 63 includes a pure Cu plating film. The second source conductor film 63 preferably has a thickness exceeding the thickness of the source electrode 32. The second source conductor film 63 preferably consists of the same conductive material as that of the second gate conductor film 53.

The second source conductor film 63 preferably has a thickness exceeding the thickness of the source electrode 32. The thickness of the second source conductor film 63 particularly preferably exceeds the thickness of the upper insulating film 38. In this embodiment, the thickness of the second source conductor film 63 exceeds the thickness of the chip 2. The thickness of the second source conductor film 63 is substantially equal to the thickness of the second gate conductor film 53.

The second source conductor film 63 covers the source electrode 32 across the first source conductor film 62 inside the source opening 40 and is drawn out onto the upper insulating film 38 in a film shape across the first source conductor film 62. The second source conductor film 63 forms a part of the second protrusion portion 61. That is, the second protrusion portion 61 has a laminated structure that includes the first source conductor film 62 and the second source conductor film 63. The second source conductor film 63 preferably has a thickness exceeding the thickness of the first source conductor film 62 inside the second protrusion portion 61.

The second source terminal layer 60 protrudes toward the opposite side with respect to the chip 2 from the first source terminal layer 59 such as to define the source recessed portion 58 with the first source terminal layer 59. That is, the second source terminal layer 60 is arranged on the first source main surface 59a such as to expose a part of the first source main surface 59a. In this embodiment, the second source terminal layer 60 includes a portion that is formed at an interval inward from a peripheral edge of the first source terminal layer 59 such as to define the source recessed portion 58 in a notched shape with the peripheral edge (first source side wall 59b) of the first source terminal layer 59.

In this embodiment, the second source terminal layer 60 defines the source recessed portion 58 that is arranged at an interval inward from an entire peripheral edge of the first source terminal layer 59 and exposes a peripheral edge portion of the first source main surface 59a over an entire circumference. That is, in this embodiment, the source recessed portion 58 is formed in an annular shape that surrounds the second source terminal layer 60 in plan view. In this embodiment, the source recessed portion 58 has a depth that is substantially equal to a depth of the gate recessed portion 48.

The second source terminal layer 60 has a second source main surface 60a (second layer main surface) and a second source side wall 60b (second layer side wall). The second source main surface 60a is formed as the source terminal surface 56. The second source main surface 60a flatly extends along the first source main surface 59a. In this embodiment, the second source main surface 60a consists of a ground surface with grinding marks.

The second source side wall 60b is positioned on the first source main surface 59a and forms a part of the source terminal side wall 57. In this embodiment, the second source side wall 60b defines the source recessed portion 58 that exposes the first source main surface 59a with the first source side wall 59b. That is, in this embodiment, the source terminal side wall 57 is defined by the first source main surface 59a, the first source side wall 59b and the second source side wall 60b. The second source side wall 60b substantially perpendicularly extends in the normal direction Z. “Substantially perpendicularly” includes a mode that extends in a laminated direction while being curved (meandering). The second source side wall 60b preferably consists of a flat surface without grinding marks.

The second source side wall 60b is preferably formed at a portion that opposes the source electrode 32 across the first source terminal layer 59. That is, the second source terminal layer 60 preferably opposes only the source electrode 32 across the first source terminal layer 59. As a matter of course, the second source side wall 60b may be formed at a portion that opposes the upper insulating film 38 across the first source terminal layer 59. That is, the second source terminal layer 60 may have a portion that opposes the upper insulating film 38 across the first source terminal layer 59.

The second source terminal layer 60 has a second source planar area and a second source thickness. The second source planar area is defined by a planar area of the second source main surface 60a (source terminal surface 56). The second source thickness is defined by a distance between the first source main surface 59a and the second source main surface 60a. The second source planar area is less than the first source planar area of the first source terminal layer 59 and adjusted according to the first source planar area. The second source planar area is preferably not less than 50% of the first main surface 3. The second source planar area is particularly preferably not less than 75% of the first main surface 3.

When the first main surface 3 has the planar area of not less than 1 mm square, the second source planar area is preferably not less than 0.8 mm square. In this case, the second source planar area is particularly preferably not less than 1 mm square. The second source terminal layer 60 may be formed in a polygonal shape having a planar area of not less than 1 mm×1.4 mm. The second source terminal layer 60 is formed in a quadrangle shape parallel to the first to fourth side surfaces 5A to 5D in plan view, in this embodiment.

That is, the second source terminal layer 60 has a planar shape similar to a planar shape of the first source terminal layer 59. As a matter of course, the second source terminal layer 60 may have the planar shape that is not similar to the planar shape of the first source terminal layer 59. Further, the second source terminal layer 60 may be formed in a polygonal shape other than a quadrangle shape, a circular shape or an elliptical shape in plan view.

The second source thickness preferably exceeds the thickness of the source electrode 32. The second source thickness particularly preferably exceeds the thickness of the upper insulating film 38. The second source thickness may be not more than the thickness of the chip 2 or may exceed the thickness of the chip 2. The second source thickness may be not less than ½ of the total thickness of the source terminal electrode 55 or may be not more than ½ of the total thickness of the source terminal electrode 55.

The second source thickness may be substantially equal to the first source thickness of the first source terminal layer 59, may be not less than the first source thickness or may be less than the first source thickness. The second source thickness particularly preferably exceeds the first source thickness. According to the second source terminal layer 60 having the second source thickness exceeding the first source thickness, the source recessed portion 58 having a depth exceeding the first source thickness is defined. In this embodiment, the second source thickness is substantially equal to the second gate thickness of the second gate terminal layer 50.

In this embodiment, the second source terminal layer 60 has a single layered structure consisting of the third source conductor film 64 arranged on the first source terminal layer 59. The third source conductor film 64 (second source terminal layer 60) may form a plurality of fine void spaces at a boundary portion with the second source conductor film 63 (first source terminal layer 59).

The third source conductor film 64 may include a Cu-based metal film. The Cu-based metal film may be a pure Cu film (Cu film with a purity of not less than 99%) or a Cu alloy film. In this embodiment, the third source conductor film 64 includes a pure Cu plating film. The third source conductor film 64 preferably consists of the same conductive material as that of the third gate conductor film 54. As a matter of course, the second source terminal layer 60 may have a laminated structure that includes the first source conductor film 62 and the second source conductor film 63 laminated in that order from the first source terminal layer 59 side, as with the case of the first source terminal layer 59.

As described so far, the source terminal electrode 55 has a ruggedness structure that includes the source recessed portion 58. A volume of the source terminal electrode 55 is reduced only by an extent of the source recessed portion 58. A planar shape, an area, a depth, etc., of the source recessed portion 58 are adjusted by adjusting a planar shape, an area and a thickness of the second source terminal layer 60. The second source terminal layer 60 is to be a connecting portion to which conducting wires (for example, a bonding wire and a conductor plate) or conductive adhesives (for example, a solder and a conductive paste), etc., are connected.

Therefore, a mode of the second source terminal layer 60 is adjusted, as long as a connection area for conducting wires, conductive adhesives, etc., is secured. A planar area of the source recessed portion 58 preferably exceeds a planar area of the gate recessed portion 48. The planar area of the source recessed portion 58 preferably exceeds a planar area of the gate terminal electrode 45.

The semiconductor device 1A includes a sealing insulator 71 that covers the first main surface 3. The sealing insulator 71 covers a periphery of the gate terminal electrode 45 and a periphery of the source terminal electrode 55 such as to expose a part of the gate terminal electrode 45 and a part of the source terminal electrode 55 on the first main surface 3. Specifically, the sealing insulator 71 covers the active surface 8, the outer surface 9 and the first to fourth connecting surfaces 10A to 10D such as to expose the gate terminal electrode 45 and the source terminal electrode 55.

With reference to FIG. 9, the sealing insulator 71 covers the gate terminal side wall 47 such as to expose the gate terminal surface 46 on the gate terminal electrode 45 side. Specifically, the sealing insulator 71 covers the first gate terminal layer 49 and the second gate terminal layer 50 such as to expose a part of the second gate terminal layer 50. More specifically, the sealing insulator 71 covers the first gate main surface 49a, the first gate side wall 49b and the second gate side wall 50b such as to expose the second gate main surface 50a.

The sealing insulator 71 includes a portion that is positioned inside the gate recessed portion 48. In this embodiment, the sealing insulator 71 includes a portion that surrounds the second gate terminal layer 50 on the first gate terminal layer 49 in plan view. The sealing insulator 71 covers the first gate terminal layer 49 and the second gate terminal layer 50 inside the gate recessed portion 48. The sealing insulator 71 covers the first gate main surface 49a and the second gate side wall 50b inside the gate recessed portion 48.

In this embodiment, the sealing insulator 71 has a portion that covers the first protrusion portion 51 of the first gate terminal layer 49 and opposes the upper insulating film 38 across the first protrusion portion 51. The sealing insulator 71 has a portion that directly covers the upper insulating film 38 in a region outside the gate terminal electrode 45.

With reference to FIG. 10, the sealing insulator 71 covers the source terminal side wall 57 such as to expose the source terminal surface 56 on the source terminal electrode 55 side. Specifically, the sealing insulator 71 covers the first source terminal layer 59 and the second source terminal layer 60 such as to expose a part of the second source terminal layer 60. More specifically, the sealing insulator 71 covers the first source main surface 59a, the first source side wall 59b and the second source side wall 60b such as to expose the second source main surface 60a.

The sealing insulator 71 includes a portion that is positioned inside the source recessed portion 58. In this embodiment, the sealing insulator 71 includes a portion that surrounds the second source terminal layer 60 on the first source terminal layer 59 in plan view. The sealing insulator 71 covers the first source terminal layer 59 and the second source terminal layer 60 inside the source recessed portion 58. The sealing insulator 71 covers the first source main surface 59a and the second source side wall 60b inside the source recessed portion 58.

In this embodiment, the sealing insulator 71 has a portion that covers the second protrusion portion 61 of the first source terminal layer 59 and opposes the upper insulating film 38 across the second protrusion portion 61. The sealing insulator 71 has a portion that directly covers the upper insulating film 38 in a region outside the source terminal electrode 55.

The sealing insulator 71 covers the dicing street 41 at the peripheral edge portion of the outer surface 9. The sealing insulator 71 directly covers the interlayer insulating film 27 at the dicing street 41, in this embodiment. As a matter of course, when the chip 2 (the outer surface 9) or the main surface insulating film 25 is exposed from the dicing street 41, the sealing insulator 71 may directly cover the chip 2 or the main surface insulating film 25 at the dicing street 41.

The sealing insulator 71 has an insulating main surface 72 and an insulating side wall 73. The insulating main surface 72 flatly extends along the first main surface 3. The insulating main surface 72 forms a single flat surface with the gate terminal surface 46 (the second gate main surface 50a) and the source terminal surface 56 (the second source main surface 60a). The insulating main surface 72 may consist of a ground surface with grinding marks. In this case, the insulating main surface 72 preferably forms a single ground surface with the second gate main surface 50a and the second source main surface 60a.

The insulating side wall 73 extends toward the chip 2 from a peripheral edge of the insulating main surface 72 and forms a single flat surface with the first to fourth side surfaces 5A to 5D. The insulating side wall 73 is formed substantially perpendicular to the insulating main surface 72. The angle formed by the insulating side wall 73 with the insulating main surface 72 may be not less than 88° and not more than 92°. The insulating side wall 73 may consist of a ground surface with grinding marks. The insulating side wall 73 may form a single ground surface with the first to fourth side surfaces 5A to 5D.

The sealing insulator 71 preferably has a thickness exceeding the thickness of the gate electrode 30 and the thickness of the source electrode 32. The thickness of the sealing insulator 71 particularly preferably exceeds the thickness of the upper insulating film 38. The thickness of the sealing insulator 71 exceeds the thickness of the chip 2, in this embodiment. As a matter of course, the thickness of the sealing insulator 71 may be less than the thickness of the chip 2. The thickness of the sealing insulator 71 may be not less than 10 μm and not more than 300 μm. The thickness of the sealing insulator 71 is preferably not less than 30 μm. The thickness of the sealing insulator 71 is particularly preferably not less than 80 μm and not more than 200 μm. The thickness of the sealing insulator 71 is substantially equal to the thickness of the gate terminal electrode 45 and the thickness of the source terminal electrode 55.

In this embodiment, the sealing insulator 71 has a laminated structure that includes a first sealing insulator 74 and a second sealing insulator 75. The first sealing insulator 74 covers a periphery of the first gate terminal layer 49 on the first main surface 3 such as to expose a part of the first gate terminal layer 49. Specifically, the first sealing insulator 74 covers the first gate side wall 49b such as to expose the first gate main surface 49a. The first sealing insulator 74 has a portion that covers the first protrusion portion 51 of the first gate terminal layer 49.

The first sealing insulator 74 covers a periphery of the first source terminal layer 59 on the first main surface 3 such as to expose a part of the first source terminal layer 59. Specifically, the first sealing insulator 74 covers the first source side wall 59b such as to expose the first source main surface 59a. The first sealing insulator 74 has a portion that covers the second protrusion portion 61 of the first source terminal layer 59.

The first sealing insulator 74 has a portion that directly covers the upper insulating film 38 in a region outside the gate terminal electrode 45 and a region outside the source terminal electrode 55. Further, the first sealing insulator 74 covers the dicing street 41 at a peripheral edge portion of the outer surface 9. In this embodiment, the first sealing insulator 74 directly covers the interlayer insulating film 27 in the dicing street 41.

The first sealing insulator 74 has a first insulating main surface 74a and a first insulating side wall 74b. The first insulating main surface 74a flatly extends along the first main surface 3 and forms a single flat surface with the first gate main surface 49a and the first source main surface 59a. The first insulating main surface 74a may consist of a ground surface with grinding marks. In this case, the first insulating main surface 74a preferably forms one ground surface with the first gate main surface 49a and the first source main surface 59a. The first insulating side wall 74b forms a part of the insulating side wall 73. The first insulating side wall 74b extends from a peripheral edge of the first insulating main surface 74a toward the chip 2 and forms a single flat surface (a ground surface in this embodiment) with the first to fourth side surfaces 5A to 5D.

The first sealing insulator 74 preferably has a thickness exceeding the thickness of the gate electrode 30 and the thickness of the source electrode 32. The thickness of the first sealing insulator 74 particularly preferably exceeds the thickness of the upper insulating film 38. The thickness of the first sealing insulator 74 may be not more than the thickness of the chip 2 or may exceed the thickness of the chip 2. The thickness of the first sealing insulator 74 may be not less than ½ of a total thickness of the sealing insulator 71 or may be not more than ½ of the total thickness of the sealing insulator 71. The thickness of the first sealing insulator 74 is substantially equal to the first gate thickness of the first gate terminal layer 49 and the first source thickness of the first source terminal layer 59.

The second sealing insulator 75 covers a periphery of the second gate terminal layer 50 on the first sealing insulator 74 such as to expose a part of the second gate terminal layer 50. Specifically, the second sealing insulator 75 covers the second gate side wall 50b such as to expose the second gate main surface 50a. The second sealing insulator 75 includes a portion that enters into the gate recessed portion 48 from on the first sealing insulator 74 and is positioned inside the gate recessed portion 48. The second sealing insulator 75 covers the first gate main surface 49a and the second gate side wall 50b inside the gate recessed portion 48. That is, in this embodiment, the second sealing insulator 75 includes a portion that surrounds the second gate terminal layer 50 on the first gate terminal layer 49 in plan view.

The second sealing insulator 75 covers a periphery of the second source terminal layer 60 on the first sealing insulator 74 such as to expose a part of the second source terminal layer 60. Specifically, the second sealing insulator 75 covers the second source side wall 60b such as to expose the second source main surface 60a. The second sealing insulator 75 includes a portion that enters into the source recessed portion 58 from on the first sealing insulator 74 and is positioned inside the source recessed portion 58. The second sealing insulator 75 covers the first source main surface 59a and the second source side wall 60b inside the source recessed portion 58. That is, in this embodiment, the sealing insulator 71 includes a portion that surrounds the second source terminal layer 60 on the first source terminal layer 59 in plan view.

The second sealing insulator 75 has a second insulating main surface 75a and a second insulating side wall 75b. The second insulating main surface 75a forms the insulating main surface 72. The second insulating main surface 75a flatly extends along the first insulating main surface 74a and forms a single flat surface (ground surface in this embodiment) with the second gate main surface 50a and the second source main surface 60a. The second insulating side wall 75b forms a part of the insulating side wall 73. The second insulating side wall 75b extends toward the chip 2 from a peripheral edge of the second insulating main surface 75a and forms a single flat surface (ground surface, in this embodiment) with the first insulating side wall 74b of the first sealing insulator 74.

The second sealing insulator 75 preferably has a thickness exceeding the thickness of the gate electrode 30 and the thickness of the source electrode 32. The thickness of the second sealing insulator 75 particularly preferably exceeds the thickness of the upper insulating film 38. The thickness of the second sealing insulator 75 may be not more than the thickness of the chip 2 or may exceed the thickness of the chip 2. The thickness of the second sealing insulator 75 may be not less than ½ of the total thickness of the sealing insulator 71 or may be not more than ½ of the total thickness of the sealing insulator 71. The thickness of the second sealing insulator 75 is substantially equal to the second gate thickness of the second gate terminal layer 50 and the second source thickness of the second source terminal layer 60.

The sealing insulator 71 includes a matrix resin, a plurality of fillers and a plurality of flexible particles (flexible agent). The sealing insulator 71 is configured such that a mechanical strength is adjusted by the matrix resin, the plurality of fillers and the plurality of flexible particles. The sealing insulator 71 may include at least the matrix resin, and the presence or the absence of the fillers and the flexible particles is optional.

The sealing insulator 71 may include a coloring material such as carbon black that colors the matrix resin. The matrix resin preferably consists of a thermosetting resin. The matrix resin may include at least one of an epoxy resin, a phenol resin and a polyimide resin as an example of the thermosetting resin. The matrix resin includes the epoxy resin, in this embodiment.

The plurality of fillers are added into the matrix resin and are composed of one of or both of spherical objects each consisting of an insulator and indeterminate objects each consisting of an insulator. The indeterminate object has a random shape other than a sphere shape such as a grain shape, a piece shape and a fragment shape. The indeterminate object may have an edge. The plurality of fillers are each composed of the spherical object from a viewpoint of suppressing a damage to be caused by a filler attack, in this embodiment.

The plurality of fillers may include at least one of ceramics, oxides and nitrides. The plurality of fillers each consist of silicon oxide particles (silicon particles), in this embodiment. The plurality of fillers may each have a particle size of not less than 1 nm and not more than 100 μm. The particle sizes of the plurality of fillers are preferably not more than 50 μm.

The sealing insulator 71 preferably include a plurality of fillers differing in the particle sizes. The plurality of fillers may include a plurality of small size fillers, a plurality of medium size fillers and a plurality of large size fillers. The plurality of fillers are preferably added into the matrix resin with a content (density) being in this order of the small size fillers, the medium size fillers and the large size fillers.

The small size fillers may have a thickness less than the thickness of the source electrode 32 (the gate electrode 30). The particle sizes of the small size fillers may be not less than 1 nm and not more than 1 μm. The medium size fillers may have a thickness exceeding the thickness of the source electrode 32 and not more than the thickness of the upper insulating film 38. The particle sizes of the medium size fillers may be not less than 1 μm and not more than 20 μm.

The large size fillers may have a thickness exceeding the thickness of the upper insulating film 38. The plurality of fillers may include at least one large size filler exceeding any one of the thickness of the first semiconductor region 6 (the epitaxial layer), the thickness of the second semiconductor region 7 (the substrate) and the thickness of the chip 2. The particle sizes of the large size fillers may be not less than 20 μm and not more than 100 μm. The particle sizes of the large size fillers are preferably not more than 50 μm.

An average particle size of the plurality of fillers may be not less than 1 μm and not more than 10 μm. The average particle size of the plurality of fillers is preferably not less than 4 μm and not more than 8 μm. As a matter of course, the plurality of fillers does not necessarily have to include all of the small size fillers, the medium size fillers and the large size fillers at the same time, and may be composed of one of or both of the small size fillers and the medium size fillers. For example, in this case, a maximum particle size of the plurality of fillers (the medium size fillers) may be not more than 10 μm.

The first sealing insulator 74 may include a plurality of filler fragments each having a broken particle shape in a surface layer portion of the first insulating main surface 74a and in a surface layer portion of the first insulating side wall 74b. Also, the second sealing insulator 75 may include a plurality of filler fragments each having a broken particle shape in a surface layer portion of the second insulating main surface 75a and in a surface layer portion of the second insulating side wall 75b. The plurality of filler fragments may each be formed by any one of a part of the small size fillers, a part of the medium size fillers and a part of the large size fillers.

The plurality of filler fragments positioned on the first insulating main surface 74a side each has a broken portion that is formed along the first insulating main surface 74a such as to be oriented to the first insulating main surface 74a. The plurality of filler fragments positioned on the first insulating side wall 74b side each has a broken portion that is formed along the first insulating side wall 74b such as to be oriented to the first insulating side wall 74b. The broken portions of the plurality of filler fragments may be exposed from the first insulating main surface 74a and the first insulating side wall 74b, or may be partially or wholly covered with the matrix resin. The plurality of filler fragments do not affect the structures on the chip 2 side, since the plurality of filler fragments are located in the surface layer portions of the first insulating main surface 74a and the first insulating side wall 74b.

The plurality of filler fragments positioned on the second insulating main surface 75a side each has a broken portion that is formed along the second insulating main surface 75a such as to be oriented to the second insulating main surface 75a. The plurality of filler fragments positioned on the second insulating side wall 75b side each has a broken portion that is formed along the second insulating side wall 75b such as to be oriented to the second insulating side wall 75b. The broken portions of the plurality of filler fragments may be exposed from the second insulating main surface 75a and the second insulating side wall 75b, or may be partially or wholly covered with the matrix resin. The plurality of filler fragments do not affect the structures on the chip 2 side, since the plurality of filler fragments are located in the surface layer portions of the second insulating main surface 75a and the second insulating side wall 75b.

The plurality of flexible particles are added into the matrix resin. The plurality of flexible particles may include at least one of a silicone-based flexible particles, an acrylic-based flexible particles and a butadiene-based flexible particles. The sealing insulator 71 preferably includes the silicone-based flexible particles. The plurality of flexible particles preferably have an average particle size less than the average particle size of the plurality of fillers. The average particle size of the plurality of flexible particles is preferably not less than 1 nm and not more than 1 μm. A maximum particle size of the plurality of flexible particles is preferably not more than 1 μm.

The plurality of flexible particles are added into the matrix resin such that a ratio of a total cross-sectional area with respect to a unit cross-sectional area is to be not less than 0.1% and not more than 10%. In other words, the plurality of flexible particles are added into the matrix resin with a content of a range of not less than 0.1 wt % and not more than 10 wt %. The average particle size and the content of the plurality of flexible particles are to be adjusted in accordance with an elastic modulus to be imparted to the sealing insulator 71 at a time of manufacturing and/or after manufacturing. For example, according to the plurality of flexible particles having the average particle size of a submicron order (=not more than 1 μm), it makes it possible to contribute to a low elastic modulus and a low curing shrinkage of the sealing insulator 71.

The semiconductor device 1A includes a drain electrode 77 (second main surface electrode) that covers the second main surface 4. The drain electrode 77 is electrically connected to the second main surface 4. The drain electrode 77 forms an ohmic contact with the second semiconductor region 7 that is exposed from the second main surface 4. The drain electrode 77 may cover a whole region of the second main surface 4 such as to be continuous with the peripheral edge of the chip 2 (the first to fourth side surfaces 5A to 5D).

The drain electrode 77 may cover the second main surface 4 at an interval from the peripheral edge of the chip 2. The drain electrode 77 is configured such that a drain source voltage of not less than 500 V and not more than 3000 V is to be applied between the source terminal electrode 55 and the drain electrode 77. That is, the chip 2 is formed such that the voltage of not less than 500 V and not more than 3000 V is to be applied between the first main surface 3 and the second main surface 4.

As described above, the semiconductor device 1A includes the chip 2, the gate electrode 30 (main surface electrode), the gate terminal electrode 45 and the sealing insulator 71. The chip 2 has the first main surface 3. The gate electrode 30 is arranged on the first main surface 3. The gate terminal electrode 45 is arranged on the gate electrode 30, and has the gate terminal surface 46 and the gate terminal side wall 47. The gate terminal electrode 45 has the gate recessed portion 48 that is recessed toward the gate electrode 30 side in the gate terminal surface 46. The sealing insulator 71 covers a periphery of the gate terminal electrode 45 on the first main surface 3 such as to expose the gate terminal surface 46 and cover the gate terminal side wall 47.

According to this structure, a volume of the gate terminal electrode 45 is reduced by the gate recessed portion 48, and a stress due to the gate terminal electrode 45 is decreased. Thereby, it is possible to suppress a failure in formation of the chip 2 and a change in electrical characteristics due to a stress of the gate terminal electrode 45. According to this structure, it is also possible to protect an object to be sealed from an external force and humidity by the sealing insulator 71. That is, it is possible to protect an object to be sealed from damage due to an external force or deterioration due to humidity. Thereby, it is possible to suppress a failure in formation and a change in electrical characteristics. It is, thus, possible to provide the semiconductor device 1A capable of improving the reliability.

From another point of view, the semiconductor device 1A includes the chip 2, the source electrode 32 (main surface electrode), the source terminal electrode 55 and the sealing insulator 71. The chip 2 has the first main surface 3. The source electrode 32 is arranged on the first main surface 3. The source terminal electrode 55 is arranged on the source electrode 32, and has the source terminal surface 56 and the source terminal side wall 57. The source terminal electrode 55 has the source recessed portion 58 that is recessed toward the source electrode 32 side in the source terminal surface 56. The sealing insulator 71 covers a periphery of the source terminal electrode 55 on the first main surface 3 such as to expose the source terminal surface 56 and cover the source terminal side wall 57.

According to this structure, a volume of the source terminal electrode 55 is reduced by the source recessed portion 58, and a stress due to the source terminal electrode 55 is decreased. It is, thereby, possible to suppress a failure in formation of the chip 2 and a change in electrical characteristics due to a stress of the source terminal electrode 55. According to this structure, it is also possible to protect an object to be sealed from an external force and humidity by the sealing insulator 71. That is, it is possible to protect an object to be sealed from damage due to an external force or deterioration due to humidity. It is, thereby, possible to suppress a failure in formation and a change in electrical characteristics. It is, thus, possible to provide the semiconductor device 1A capable of improving the reliability.

The semiconductor device 1A preferably includes the upper insulating film 38 that partially covers the gate electrode 30 (source electrode 32). According to this structure, the upper insulating film 38 is able to protect the gate electrode 30 (source electrode 32) from an external force or humidity. That is, according to this structure, the gate electrode 30 (source electrode 32) can be protected by both the upper insulating film 38 and the sealing insulator 71. The source terminal electrode 55 may have a portion that directly covers the gate electrode 30 (source electrode 32) and a portion that directly covers the upper insulating film 38.

The sealing insulator 71 preferably has a portion that directly covers the upper insulating film 38. The sealing insulator 71 preferably has a portion that covers the gate electrode 30 (source electrode 32) across the upper insulating film 38. The upper insulating film 38 preferably includes one of or both of the inorganic insulating film 42 and the organic insulating film 43. The organic insulating film 43 preferably consists of a photosensitive resin film.

The upper insulating film 38 is preferably thicker than the gate electrode 30 (source electrode 32). The upper insulating film 38 is preferably thinner than the chip 2. The sealing insulator 71 is preferably thicker than the gate electrode 30 (source electrode 32). The sealing insulator 71 is preferably thicker than the upper insulating film 38. The sealing insulator 71 is particularly preferably thicker than the chip 2.

The above configuration is effective in applying the gate terminal electrode 45 (source terminal electrode 55) having a relatively large planar area and/or a relatively large thickness to the chip 2 having a relatively large planar area and/or a relatively small thickness. The gate terminal electrode 45 (source terminal electrode 55) having a relatively large planar area and/or a relatively large thickness is effective in absorbing a heat generated on the chip 2 side and diffusing it outside.

For example, the gate terminal electrode 45 (source terminal electrode 55) is preferably thicker than the source electrode 32. The gate terminal electrode 45 (source terminal electrode 55) is preferably thicker than the upper insulating film 38. The gate terminal electrode 45 (source terminal electrode 55) is particularly preferably thicker than the chip 2. The gate terminal electrode 45 may cover not more than 25% of a region of the first main surface 3 in plan view. The source terminal electrode 55 may cover not less than 50% of a region of the first main surface 3 in plan view.

For example, the chip 2 may have the first main surface 3 having the area of not less than 1 mm square in plan view. The chip 2 may have the thickness of not more than 100 μm in cross sectional view. The chip 2 preferably has the thickness of not more than 50 μm in cross sectional view. The chip 2 may have the laminated structure that includes the semiconductor substrate and the epitaxial layer. In this case, the epitaxial layer is preferably thicker than the semiconductor substrate.

In those above structures, the chip 2 preferably includes the monocrystal of the wide bandgap semiconductor. The monocrystal of the wide bandgap semiconductor is effective in improving electrical characteristics. Also, according to the monocrystal of the wide bandgap semiconductor, it is possible to achieve a thinning of the chip 2 and an increasing of the planar area of the chip 2 while suppressing a deformation of the chip 2 with a relatively high hardness. The thinning of the chip 2 and the increasing of the planar area of the chip 2 are also effective in improving the electrical characteristics.

The structure having the sealing insulator 71 is also effective in a structure that includes the drain electrode 77 covering the second main surface 4 of the chip 2. The drain electrode 77 forms a potential difference (for example, not less than 500 V and not more than 3000 V) with the source electrode 32 via the chip 2. In a case in which the chip 2 is relatively thin, a risk of a discharge phenomenon between the peripheral edge of the first main surface 3 and the source electrode 32 increases, since a distance between the source electrode 32 and the drain electrode 77 is shortened. In this point, according to the structure having the sealing insulator 71, an insulation property between the peripheral edge of the first main surface 3 and the source electrode 32 can be improved, and therefore the discharge phenomenon can be suppressed.

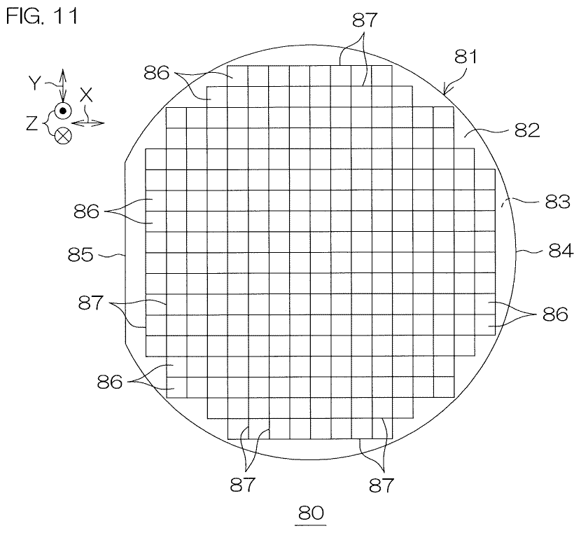

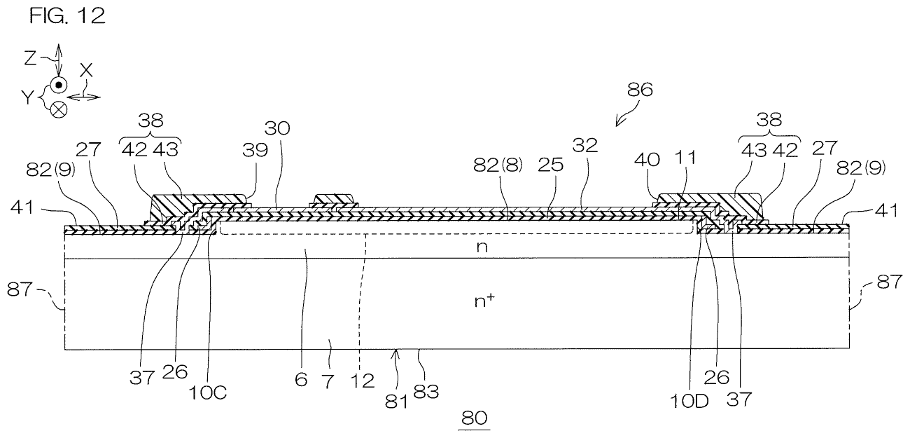

FIG. 11 is a plan view showing a wafer structure 80 that is to be used at a time of manufacturing of the semiconductor device 1A shown in FIG. 1. FIG. 12 is a cross sectional view showing a device region 86 shown in FIG. 11. With reference to FIG. 11 and FIG. 12, the wafer structure 80 includes a wafer 81 formed in a disc shape. The wafer 81 is to be a base of the chip 2. The wafer 81 has a first wafer main surface 82 on one side, a second wafer main surface 83 on the other side, and a wafer side surface 84 connecting the first wafer main surface 82 and the second wafer main surface 83.

The wafer 81 has a mark 85 indicating a crystal orientation of the SiC monocrystal on the wafer side surface 84. The mark 85 includes an orientation flat cut out in a straight line in plan view, in this embodiment. The orientation flat extends in the second direction Y, in this embodiment. The orientation flat does not necessarily have to extend in the second direction Y and may extend in the first direction X.

As a matter of course, the mark 85 may include a first orientation flat extending in the first direction X and a second orientation flat extending in the second direction Y. Also, the mark 85 may have an orientation notch, instead of the orientation flat, cut out toward a central portion of the wafer 81. The orientation notch may be a notched portion cut into a polygonal shape such as a triangle shape and a quadrangle shape in plan view.

The wafer 81 may have a diameter of not less than 50 mm and not more than 300 mm (that is, not less than 2 inch and not more than 12 inch). The diameter of the wafer structure 80 is defined by a length of a chord passing through a center of the wafer structure 80 outside the mark 85. The wafer structure 80 may have a thickness of not less than 100 μm and not more than 1100 μm.

The wafer structure 80 includes the first semiconductor region 6 formed in a region on the first wafer main surface 82 side and the second semiconductor region 7 formed in a region on the second wafer main surface 83 side, inside the wafer 81. The first semiconductor region 6 is formed by an epitaxial layer, and the second semiconductor region 7 formed by a semiconductor substrate. That is, the first semiconductor region 6 is formed by an epitaxial growth of a semiconductor monocrystal from the second semiconductor region 7 by an epitaxial growth method. The second semiconductor region 7 preferably has a thickness exceeding a thickness of the first semiconductor region 6.

The wafer structure 80 includes a plurality of device regions 86 and a plurality of scheduled cutting lines 87 that are provided in the first wafer main surface 82. The plurality of device regions 86 are regions each corresponding to the semiconductor device 1A. The plurality of device regions 86 are each set in a quadrangle shape in plan view. The plurality of device regions 86 are arrayed in a matrix pattern along the first direction X and the second direction Y in plan view, in this embodiment.

The plurality of scheduled cutting lines 87 are lines (regions extending in band shapes) that define positions to be the first to fourth side surfaces 5A to 5D of the chip 2. The plurality of scheduled cutting lines 87 are set in a lattice pattern extending along the first direction X and the second direction Y such as to define the plurality of device regions 86. For example, the plurality of scheduled cutting lines 87 may be defined by alignment marks and the like that are provided inside and/or outside the wafer 81.

The wafer structure 80 includes the mesa portion 11, the MISFET structure 12, the outer contact region 19, the outer well region 20, the field regions 21, the main surface insulating film 25, the side wall structure 26, the interlayer insulating film 27, the gate electrode 30, the source electrode 32, the plurality of gate wirings 36A, 36B, the source wiring 37 and the upper insulating film 38 formed in each of the device regions 86, in this embodiment.

The wafer structure 80 includes the dicing street 41 defined in regions among the plurality of upper insulating films 38. The dicing street 41 straddles the plurality of device regions 86 across the plurality of scheduled cutting lines 87 such as to expose the plurality of scheduled cutting lines 87. The dicing street 41 is formed in a lattice pattern extending along the plurality of scheduled cutting lines 87. The dicing street 41 exposes the interlayer insulating film 27, in this embodiment. As a matter of course, in a case in which the interlayer insulating film 27 exposing the first wafer main surface 82, the dicing street 41 may expose the first wafer main surface 82.

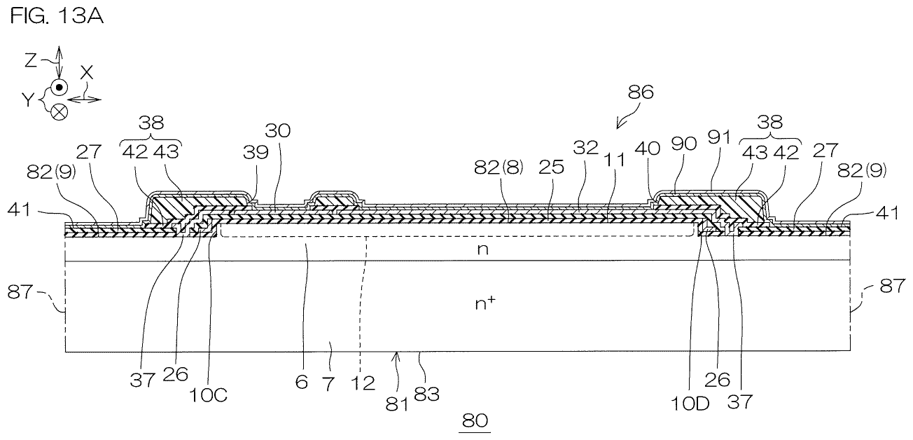

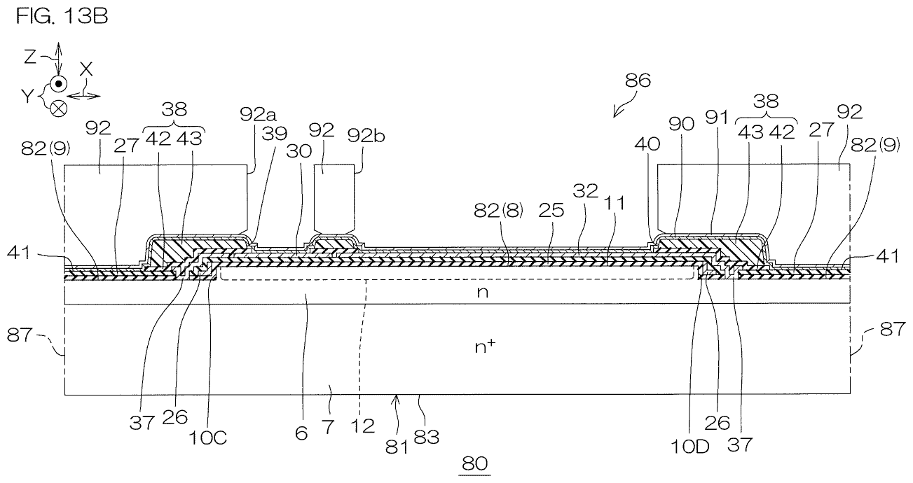

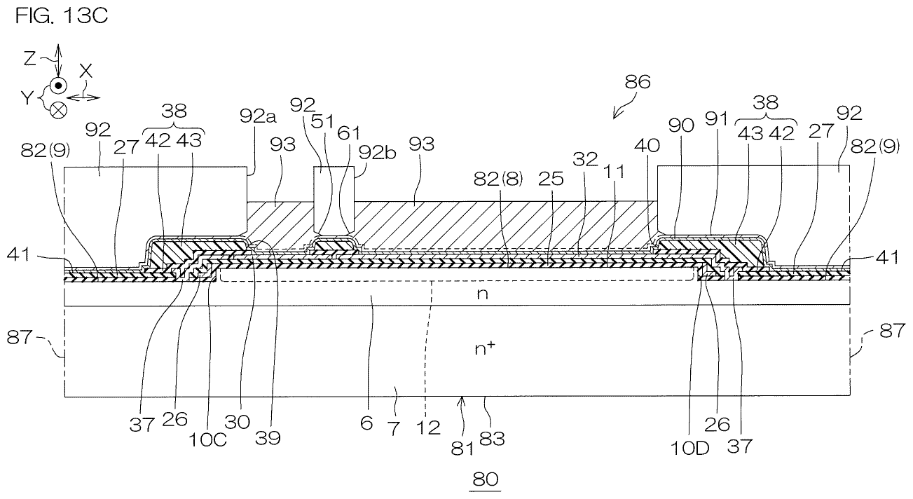

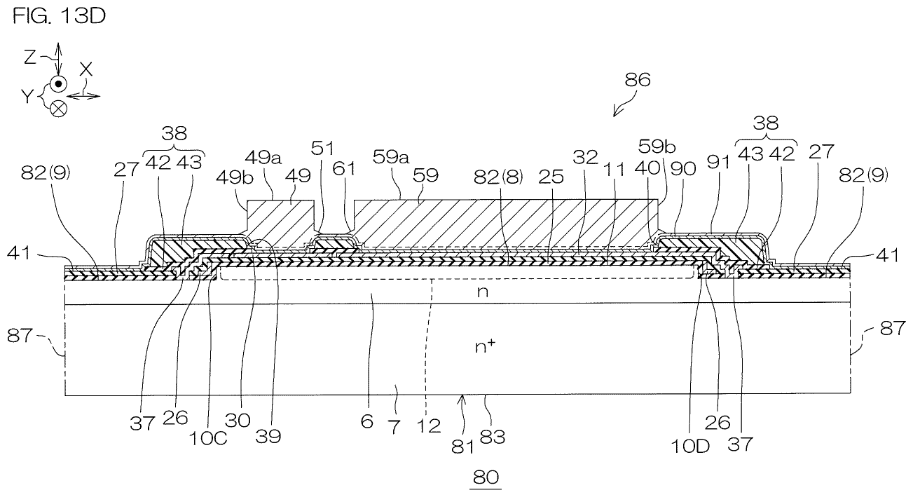

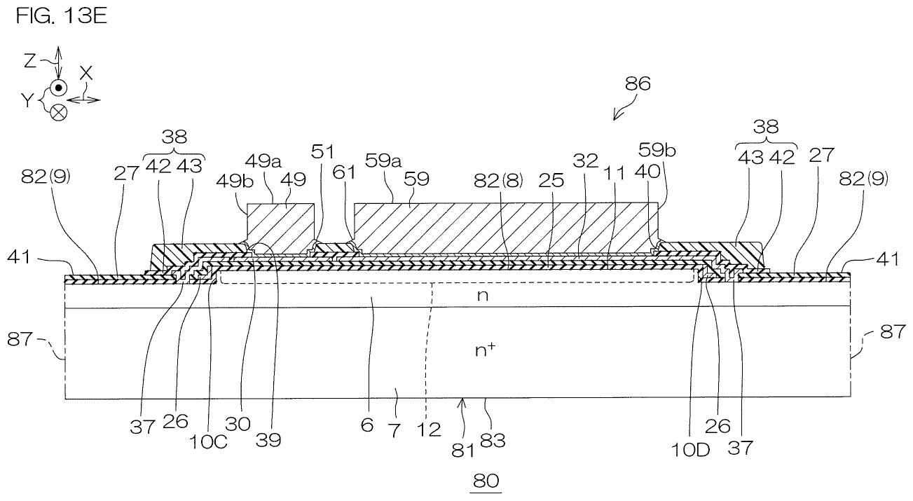

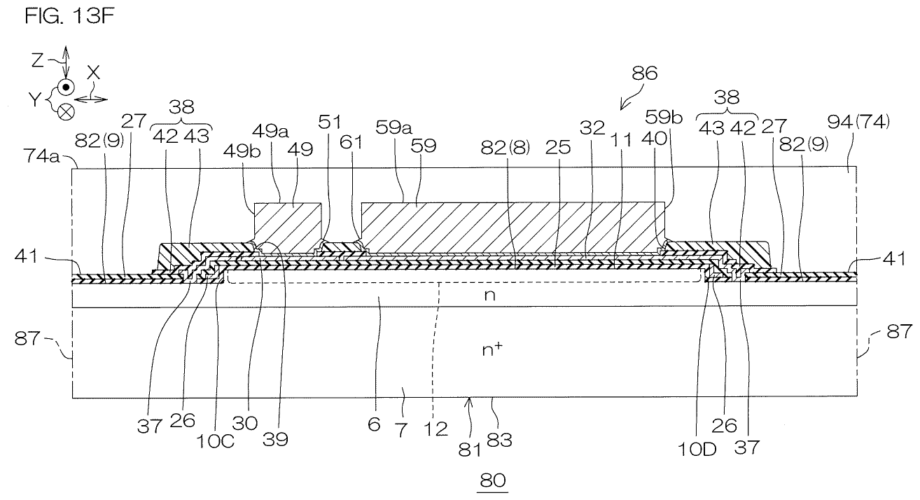

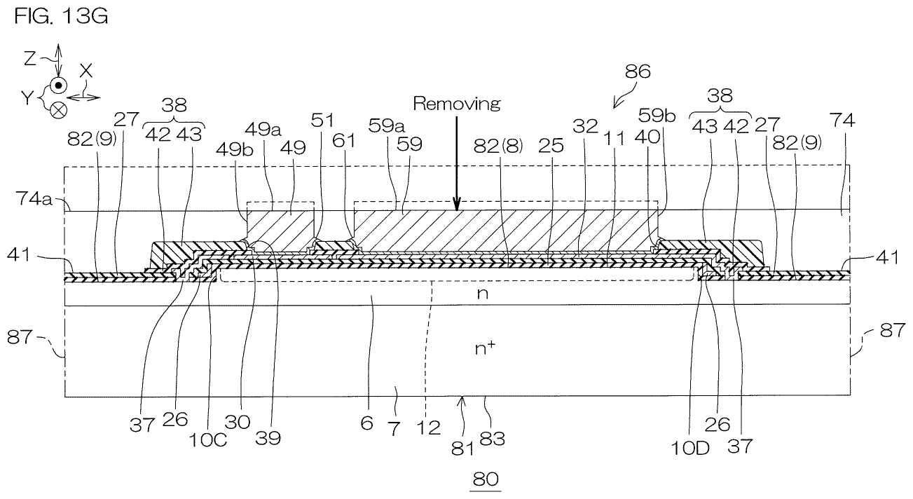

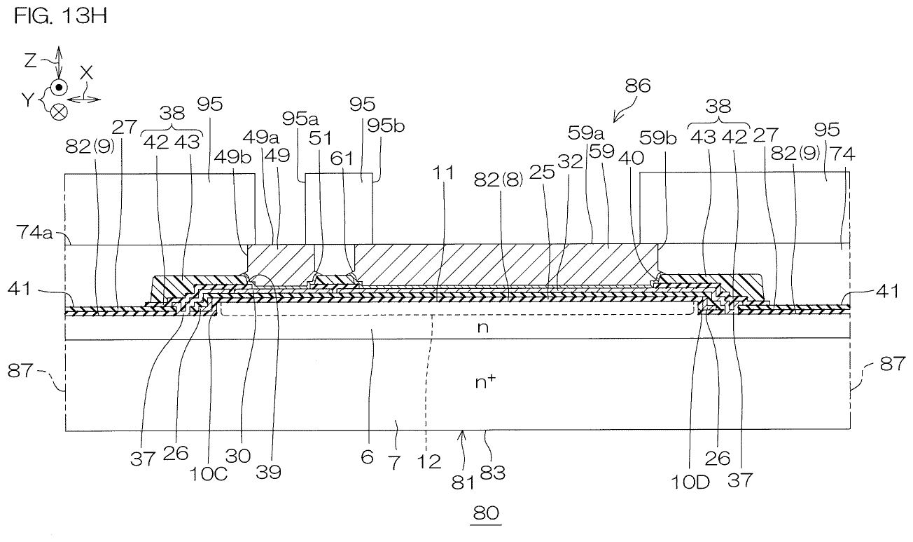

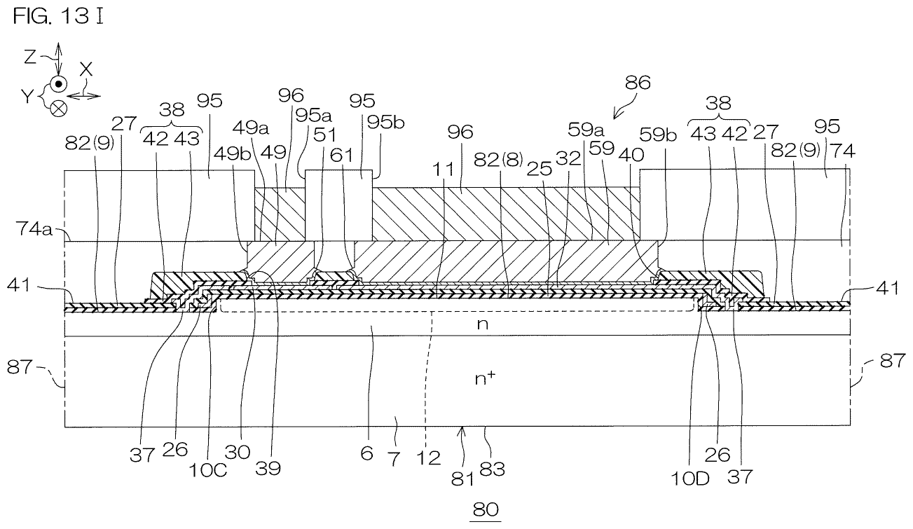

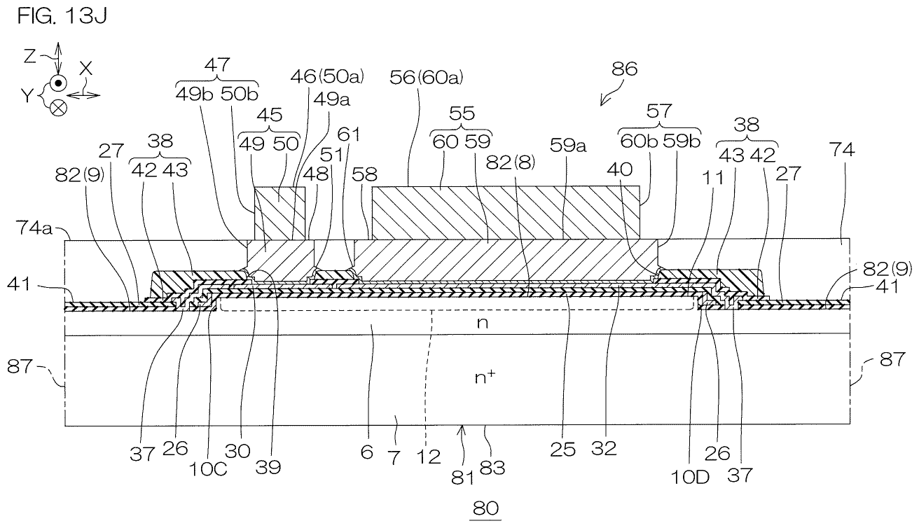

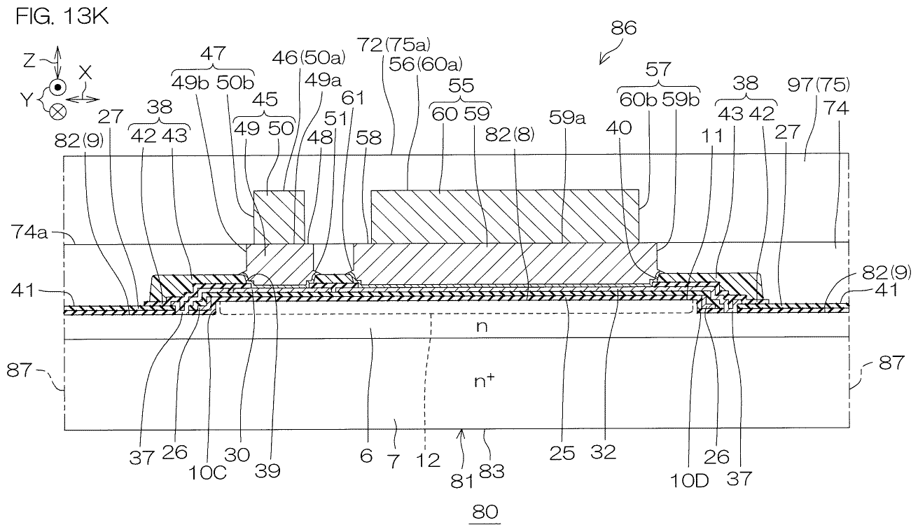

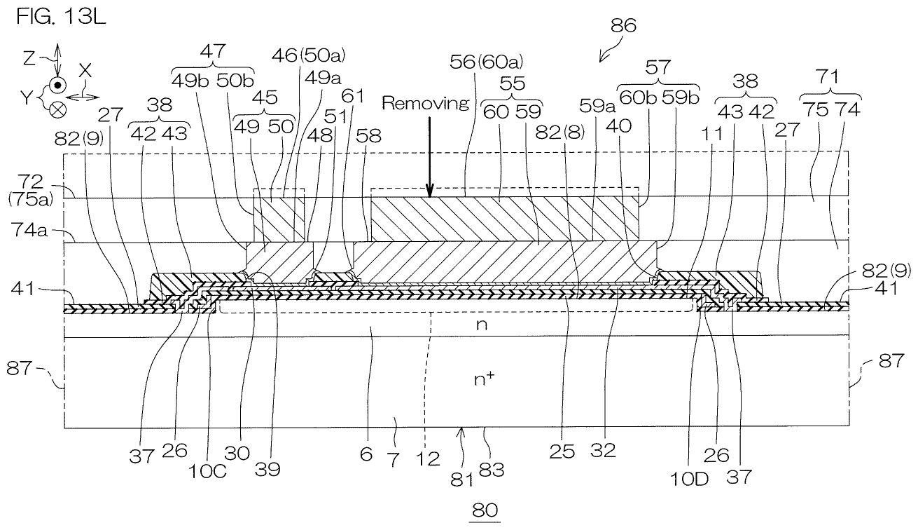

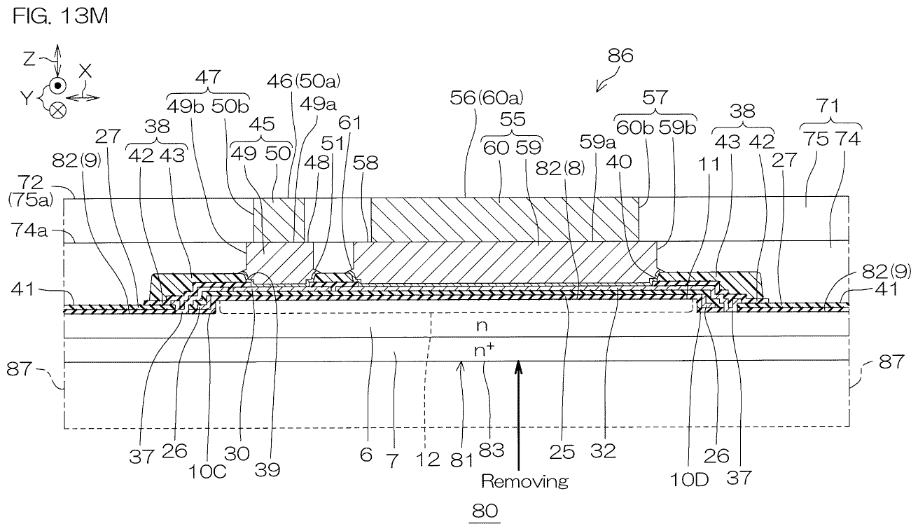

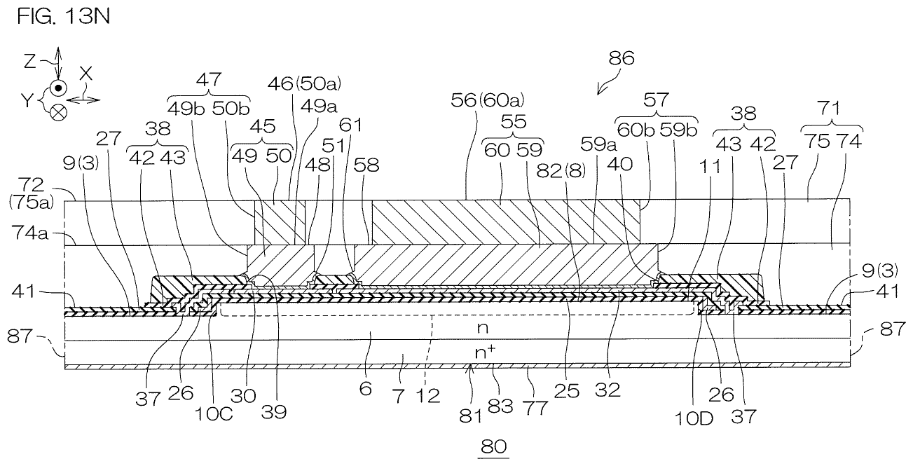

FIG. 13A to FIG. 13N are cross sectional views showing a manufacturing method example for the semiconductor device 1A shown in FIG. 1. Descriptions of the specific features of each structure formed in each process shown in FIG. 13A to FIG. 13N shall be omitted or simplified, since those have been as described above.

With reference to FIG. 13A, the wafer structure 80 is prepared (see FIG. 11 and FIG. 12). Next, a first base conductor film 90 to be a base of the first gate conductor film 52 and the first source conductor film 62 is formed on the wafer structure 80. The first base conductor film 90 is formed in a film shape along the interlayer insulating film 27, the gate electrode 30, the source electrode 32, the plurality of gate wirings 36A, 36B, the source wiring 37 and the upper insulating film 38. The first base conductor film 90 includes a Ti-based metal film. The first base conductor film 90 may be formed by a sputtering method and/or a vapor deposition method.

Next, a second base conductor film 91 to be a base of the second gate conductor film 53 and the second source conductor film 63 is formed on the first base conductor film 90. The second base conductor film 91 covers the interlayer insulating film 27, the gate electrode 30, the source electrode 32, the plurality of gate wirings 36A, 36B, the source wiring 37 and the upper insulating film 38 in a film shape with the first base conductor film 90 interposed therebetween. The second base conductor film 91 includes a Cu-based metal film. The second base conductor film 91 may be formed by a sputtering method and/or a vapor deposition method.

Next, with reference to FIG. 13B, a first resist mask 92 having a predetermined pattern is formed on the second base conductor film 91. The first resist mask 92 includes a first opening 92a exposing the gate electrode 30 and a second opening 92b exposing the source electrode 32. The first opening 92a exposes a region in which the first gate terminal layer 49 is to be formed at a region on the gate electrode 30. The second opening 92b exposes a region in which the first source terminal layer 59 is to be formed at a region on the source electrode 32.

This step includes a step of reducing an adhesion of the first resist mask 92 with respect to the second base conductor film 91. The adhesion of the first resist mask 92 is to be adjusted by adjusting exposure conditions and/or bake conditions (baking temperature, time, etc.) after exposure for the first resist mask 92. Through this step, a growth starting point of the first protrusion portion 51 is formed at a lower end portion of the first opening 92a, and a growth starting point of the second protrusion portion 61 is formed at a lower end portion of the second opening 92b.

Next, with reference to FIG. 13C, a third base conductor film 93 to be a base of the second gate conductor film 53 and the second source conductor film 63 is formed on the second base conductor film 91. The third base conductor film 93 is formed by depositing a conductor (in this embodiment, Cu-based metal) in the first opening 92a and the second opening 92b by a plating method (for example, electroplating method), in this embodiment. The third base conductor film 93 integrates with the second base conductor film 91 inside the first opening 92a and the second opening 92b.

This step includes a step of entering a plating solution between the second base conductor film 91 and the first resist mask 92 at the lower end portion of the first opening 92a. Also, this step includes a step of entering the plating solution between the second base conductor film 91 and the first resist mask 92 at the lower end portion of the second opening 92b. Through this step, a part of the third base conductor film 93 (the first gate terminal layer 49) is grown into a protrusion shape at the lower end portion of the first opening 92a and the first protrusion portion 51 is thereby formed. Also, a part of the third base conductor film 93 (the first source terminal layer 59) is grown into a protrusion shape at the lower end portion of the second opening 92b and the second protrusion portion 61 is thereby formed.

Next, with reference to FIG. 13D, the first resist mask 92 is removed. Through this step, the first gate terminal layer 49 and the first source terminal layer 59 are exposed outside.

Next, with reference to FIG. 13E, a portion of the second base conductor film 91 that is exposed from the first gate terminal layer 49 and the first source terminal layer 59 is removed. An unnecessary portion of the second base conductor film 91 may be removed by an etching method. The etching method may be a wet etching method and/or a dry etching method. Next, a portion of the first base conductor film 90 that is exposed from the first gate terminal layer 49 and the first source terminal layer 59 is removed. An unnecessary portion of the first base conductor film 90 may be removed by an etching method. The etching method may be a wet etching method and/or a dry etching method.

Next, with reference to FIG. 13F, a first sealant 94 is supplied on the first wafer main surface 82 such as to cover the first gate terminal layer 49 and the first source terminal layer 59. The first sealant 94 is to be a base of the first sealing insulator 74. The first sealant 94 fills a periphery of the first gate terminal layer 49 and a periphery of the first source terminal layer 59, and covers a whole region of the upper insulating film 38, a whole region of the first gate terminal layer 49 and a whole region of the first source terminal layer 59.

The first sealant 94 includes the thermosetting resin, the plurality of fillers and the plurality of flexible particles (flexible agent) in this embodiment, and is hardened by heating. Through this step, the first sealing insulator 74 is formed. The first sealing insulator 74 has the first insulating main surface 74a that covers the whole region of the first gate terminal layer 49 and the whole region of the first source terminal layer 59.

Next, with reference to FIG. 13G, the first sealing insulator 74 is partially removed. The first sealing insulator 74 is ground from the first insulating main surface 74a side by a grinding method, in this embodiment. The grinding method may be a mechanical polishing method and/or a chemical mechanical polishing method. The first insulating main surface 74a is ground until the first gate terminal layer 49 and the first source terminal layer 59 are exposed. This step includes a grinding step of the first gate terminal layer 49 and the first source terminal layer 59. Through this step, the first insulating main surface 74a that forms the single grinding surface with the first gate main surface 49a and the source main surface 59a is formed.

The first sealing insulator 74 may be formed in a semi-cured state (incompletely cured state) by adjusting the heating conditions in the step of FIG. 13F aforementioned. In this case, the first sealing insulator 74 is ground in the step of FIG. 13G and then heated again to form a fully cured state (completely cured state). In this case, it is possible to easily remove the first sealing insulator 74.

Next, with reference to FIG. 13H, a second resist mask 95 having a predetermined pattern is formed on the first sealing insulator 74. The second resist mask 95 includes a first upper opening 95a that exposes the first gate terminal layer 49 and a second upper opening 95b that exposes the first source terminal layer 59. The first upper opening 95a exposes a region in which the second gate terminal layer 50 is to be formed in a region on the first gate terminal layer 49. The second upper opening 95b exposes a region in which the second source terminal layer 60 is to be formed in a region on the first source terminal layer 59.

Specifically, the second resist mask 95 covers a part of the first gate terminal layer 49 and includes the first upper opening 95a that partially exposes the first gate terminal layer 49. In this embodiment, the second resist mask 95 covers a peripheral edge portion of the first gate terminal layer 49 and has the first upper opening 95a that exposes an inner portion of the first gate terminal layer 49. In this embodiment, the second resist mask 95 covers the peripheral edge portion of the first gate terminal layer 49 over an entire circumference.

Also, the second resist mask 95 covers a part of the first source terminal layer 59 and includes the second upper opening 95b that partially exposes the first source terminal layer 59. In this embodiment, the second resist mask 95 covers a peripheral edge portion of the first source terminal layer 59 and has the second upper opening 95b that exposes an inner portion of the first source terminal layer 59. In this embodiment, the second resist mask 95 covers the peripheral edge portion of the first source terminal layer 59 over an entire circumference.

Next, with reference to FIG. 13I, a fourth base conductor film 96 that is to be a base of the third gate conductor film 54 (second gate terminal layer 50) and that of the third source conductor film 64 (second source terminal layer 60) is formed on the first gate terminal layer 49 and the first source terminal layer 59. In this embodiment, the fourth base conductor film 96 is formed by depositing a conductor (Cu-based metal in this embodiment) inside the first upper opening 95a and the second upper opening 95b by a plating method (for example, electroplating method). The second gate terminal layer 50 that covers the first gate terminal layer 49 and the second source terminal layer 60 that covers the first source terminal layer 59 are thereby formed.

Next, with reference to FIG. 13J, the second resist mask 95 is removed. Thereby, a part of the first gate terminal layer 49 (peripheral edge portion), a part of the first source terminal layer 59 (peripheral edge portion), the second gate terminal layer 50 and the second source terminal layer 60 are exposed outside. Further, the gate recessed portion 48 is formed at a portion of the second resist mask 95 that covers the first gate terminal layer 49. Further, the source recessed portion 58 is formed at a portion of the second resist mask 95 that covers the first source terminal layer 59. The gate terminal electrode 45 having the gate recessed portion 48 and the source terminal electrode 55 having the source recessed portion 58 are thereby formed.

Next, with reference to FIG. 13K, a second sealant 97 is supplied on the first sealing insulator 74 such as to cover a part of the first gate terminal layer 49 (peripheral edge portion), a part of the first source terminal layer 59 (peripheral edge portion), the second gate terminal layer 50 and the second source terminal layer 60. The second sealant 97 is to be a base of the second sealing insulator 75. The second sealant 97 fills a periphery of the second gate terminal layer 50 and a periphery of the second source terminal layer 60 and covers a whole region of the first sealing insulator 74, a whole region of the second gate terminal layer 50 and a whole region of the second source terminal layer 60.

The second sealant 97 enters into the gate recessed portion 48 on the second gate terminal layer 50 side and covers the first gate terminal layer 49 and the second gate terminal layer 50 inside the gate recessed portion 48. Further, the second sealant 97 enters into the source recessed portion 58 on the second source terminal layer 60 side and covers the first source terminal layer 59 and the second source terminal layer 60 inside the source recessed portion 58.

In this embodiment, the second sealant 97 includes a thermosetting resin, a plurality of fillers and a plurality of flexible particles (flexible agents) and is cured by heating. The second sealing insulator 75 is, thereby, formed. The second sealing insulator 75 has the second insulating main surface 75a which covers a whole region of the first sealing insulator 74, a whole region of the second gate terminal layer 50 and a whole region of the second source terminal layer 60.

Next, with reference to FIG. 13L, the second sealing insulator 75 is partially removed. In this embodiment, the second sealing insulator 75 is ground from the second insulating main surface 75a side by a grinding method. The grinding method may be a mechanical polishing method and/or a chemical mechanical polishing method. The second insulating main surface 75a is ground until the second gate terminal layer 50 and the second source terminal layer 60 are exposed. This step includes a step of grinding the second gate terminal layer 50 and the second source terminal layer 60. The second insulating main surface 75a that forms one ground surface between the second gate main surface 50a and the second source main surface 60a is thereby formed. Thereby, the sealing insulator 71 having a laminated structure that includes the first sealing insulator 74 and the second sealing insulator 75 is formed.

The second sealing insulator 75 may be formed in a semi-cured state (incompletely cured state) by adjusting the heating conditions in the step of FIG. 13K aforementioned. In this case, the second sealing insulator 75 is ground in the step of FIG. 13L and then heated again to form a fully cured state (completely cured state). In this case, it is possible to easily remove the second sealing insulator 75.

Next, with reference to FIG. 13M, the wafer 81 is partially removed from the second wafer main surface 83 side, and the wafer 81 is thinned until a desired thickness is obtained. The thinning step of the wafer 81 is performed by an etching method and/or a grinding method. The etching method may be a wet etching method and/or a dry etching method. The grinding method may be a mechanical polishing method and/or a chemical mechanical polishing method.

This step includes a step of thinning the wafer 81 by using the sealing insulator 71 as a supporting member that supports the wafer 81. This allows for proper handling of the wafer 81. Also, it is possible to suppress a deformation (warpage due to thinning) of the wafer 81 with the sealing insulator 71, and therefore the wafer 81 can be appropriately thinned.

As one example, in a case in which the thickness of the wafer 81 is less than the thickness of the sealing insulator 71, the wafer 81 is further thinned. As the other example, in a case in which the thickness of the wafer 81 is not less than the thickness of the sealing insulator 71, the wafer 81 is thinned until the thickness of the wafer 81 becomes less than the thickness of the sealing insulator 71. In those cases, the wafer 81 is preferably thinned until a thickness of the second semiconductor region 7 (the semiconductor substrate) becomes less than a thickness of the first semiconductor region 6 (the epitaxial layer).

As a matter of course, the thickness of the second semiconductor region 7 (the semiconductor substrate) may be not less than the thickness of the first semiconductor region 6 (the epitaxial layer). Also, the wafer 81 may be thinned until the first semiconductor region 6 is exposed from the second wafer main surface 83. That is, all of the second semiconductor region 7 may be removed.

Next, with reference to FIG. 13N, the drain electrode 77 covering the second wafer main surface 83 is formed. The drain electrode 77 may be formed by a sputtering method and/or a vapor deposition method. Then, the wafer structure 80 and the sealing insulator 71 are cut along the plurality of scheduled cutting lines 87. The wafer structure 80 and the sealing insulator 71 may be cut by a dicing blade (not shown). Through the steps including the above, the plurality of semiconductor devices 1A are manufactured from the single wafer structure 80.

As described above, the manufacturing method for the semiconductor device 1A includes the step of preparing the wafer structure 80, the step of forming the source terminal electrode 55 and the step of forming the sealing insulator 71. In the step of preparing the wafer structure 80, the wafer structure 80 that includes the wafer 81 and the source electrode 32 is prepared. The wafer 81 has the first wafer main surface 82. The source electrode 32 is arranged on the first wafer main surface 82.

In the step of forming the source terminal electrode 55, the source terminal electrode 55 is formed on the source electrode 32. The source terminal electrode 55 has the source terminal surface 56 and the source terminal side wall 57. The source terminal electrode 55 has the source recessed portion 58 that is recessed toward the source electrode 32 side in the source terminal surface 56. In the step of forming the sealing insulator 71, the sealing insulator 71 that covers the periphery of the source terminal electrode 55 is formed such as to expose the source terminal surface 56 and cover the source terminal side wall 57.

According to this manufacturing method, a volume of the source terminal electrode 55 is reduced by the source recessed portion 58, and a stress due to the source terminal electrode 55 is decreased. Thereby, it is possible to suppress a failure in formation of the wafer 81 and a change in electrical characteristics due to a stress of the source terminal electrode 55. Also, according to the manufacturing method, it is possible to protect an object to be sealed from an external force or humidity by the sealing insulator 71. That is, it is possible to protect an object to be sealed from damage due to an external force or deterioration due to humidity. It is, thereby, possible to suppress a failure in formation and a change in electrical characteristics. It is, thus, possible to manufacture the semiconductor device 1A capable of improving the reliability.

The step of forming the sealing insulator 71 preferably includes the step of forming the sealing insulator 71 having the portion that covers the source recessed portion 58. According to this step, it is possible to protect the source terminal electrode 55 having the source recessed portion 58 by the sealing insulator 71. The step of forming the source terminal electrode 55 preferably includes the step of forming the source terminal electrode 55 having the source recessed portion 58 at the corner portion of the source terminal surface 56 such as to define the step portion in the source terminal side wall 57.

The step of forming the source terminal electrode 55 preferably includes the step of forming the source terminal electrode 55 having the source recessed portion 58 that extends in an annular shape along the peripheral edge of the source terminal surface 56 such as to surround the inner portion of the source terminal surface 56 in plan view. In this case, the step of forming the sealing insulator 71 preferably includes the step of forming the sealing insulator 71 having the portion that surrounds the source terminal surface 56 along the source recessed portion 58.

The step of forming the source terminal electrode 55 preferably includes the step of forming the first source terminal layer 59 (first layer portion) on the source electrode 32 and the step of forming the second source terminal layer 60 (second layer portion) on the first source terminal layer 59 such as to define the source recessed portion 58 with the first source terminal layer 59. In this case, the step of forming the sealing insulator 71 preferably includes the step of forming the sealing insulator 71 that covers the first source terminal layer 59 and the second source terminal layer 60 such as to expose a part of the second source terminal layer 60 as the source terminal surface 56.

The step of forming the source terminal electrode 55 preferably includes the step of forming the first source terminal layer 59 having the first source planar area and the step of forming the second source terminal layer 60 having the second source planar area less than the first source planar area.

The step of forming the source terminal electrode 55 may include the step of forming the first source terminal layer 59 having the first source thickness and the step of forming the second source terminal layer 60 having the second source thickness exceeding the first source thickness. The step of forming the source terminal electrode 55 may include the step of forming the first source terminal layer 59 having the first source thickness and the step of forming the second source terminal layer 60 having the second source thickness less than the first source thickness.

The step of forming the sealing insulator 71 may include the step of forming the first sealing insulator 74 that covers the periphery of the first source terminal layer 59 on the first wafer main surface 82 and the step of forming the second sealing insulator 75 that covers the periphery of the second source terminal layer 60 on the first sealing insulator 74.

The step of forming the first sealing insulator 74 may include the step of forming the first sealing insulator 74 that covers the periphery of the first source terminal layer 59 on the first wafer main surface 82 such as to expose the first source main surface 59a (first layer main surface) and cover the first source side wall 59b (first layer side wall). The step of forming the second sealing insulator 75 may include the step of forming the second sealing insulator 75 that covers the periphery of the second source terminal layer 60 on the first wafer main surface 82 such as to expose the second source main surface 60a (second layer main surface) as the source terminal surface 56 and cover the second source side wall 60b (second layer side wall).

The step of forming the first sealing insulator 74 may include the step of forming the first sealing insulator 74 having the first insulating main surface 74a that forms the single flat surface with the first source main surface 59a. The step of forming the second sealing insulator 75 may include the step of forming the second sealing insulator 75 having the second insulating main surface 75a that forms the single flat surface with the second source main surface 60a.

After the step of forming the sealing insulator 71, the step of thinning the wafer 81 is preferably included. The thinning step of the wafer 81 preferably includes the step of thinning the wafer 81 until it becomes thinner than the sealing insulator 71. The thinning step of the wafer 81 preferably includes the step of thinning the wafer 81 until it becomes thinner than the gate terminal electrode 45 and the source terminal electrode 55.

The step of preparing the wafer structure 80 may include the step of preparing the wafer structure 80 including the wafer 81 that has the laminated structure including the substrate and the epitaxial layer and that has the first wafer main surface 82 formed by the epitaxial layer. In this case, the thinning step of the wafer 81 may include the step of removing at least a part of the substrate. For example, the thinning step of the wafer 81 may include the step of thinning the substrate until it becomes thinner than the epitaxial layer. The step of preparing the wafer structure 80 may include the step of preparing the wafer structure 80 including the wafer 81 that contains the monocrystal of the wide bandgap semiconductor.

The manufacturing method for the semiconductor device 1A may include the step of forming the upper insulating film 38 that covers the source electrode 32 before the step of forming the source terminal electrode 55. In this case, the step of forming the source terminal electrode 55 may include the step of forming the source terminal electrode 55 having the portion that covers the upper insulating film 38. Further, the step of forming the sealing insulator 71 may include the step of forming the sealing insulator 71 having the portion that covers the upper insulating film 38.

From another point of view, the manufacturing method for the semiconductor device 1A includes the step of preparing the wafer structure 80, the step of forming the gate terminal electrode 45 (terminal electrode) and the step of forming the sealing insulator 71. In the step of preparing the wafer structure 80, the wafer structure 80 that includes the wafer 81 and the gate electrode 30 is prepared. The wafer 81 has the first wafer main surface 82 (main surface). The gate electrode 30 is arranged on the first wafer main surface 82.

In the step of forming the gate terminal electrode 45, the gate terminal electrode 45 is formed on the gate electrode 30. The gate terminal electrode 45 has the gate terminal surface 46 (terminal surface) and the gate terminal side wall 47 (terminal side wall). The gate terminal electrode 45 has the gate recessed portion 48 (recessed portion) that is recessed toward the gate electrode 30 side in the gate terminal surface 46. In the step of forming the sealing insulator 71, the sealing insulator 71 that covers the periphery of the gate terminal electrode 45 is formed such as to expose the gate terminal surface 46 and cover the gate terminal side wall 47. The same effects as those of the manufacturing method on the source terminal electrode 55 side are also achieved by the manufacturing method on the gate terminal electrode 45 side.

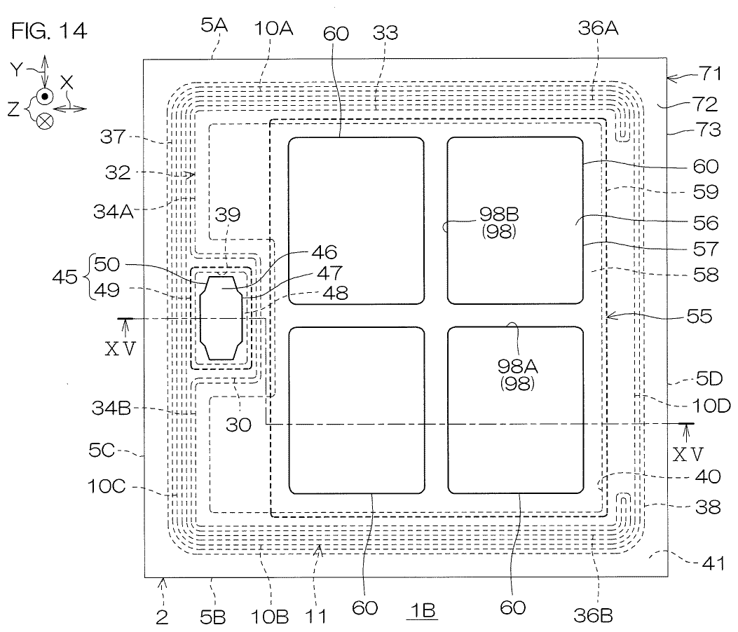

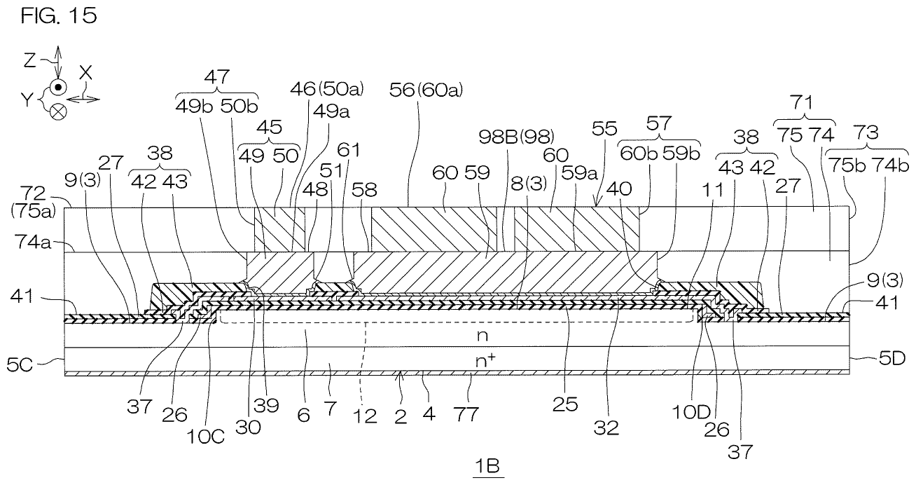

FIG. 14 is a plan view that shows a semiconductor device 1B according to a second embodiment. FIG. 15 is a cross sectional view taken along XV-XV line shown in FIG. 14. The semiconductor device 1B has a mode in which the semiconductor device 1A is deformed. Specifically, the semiconductor device 1B includes the source terminal electrode 55 having an inward recessed portion 98 that is recessed toward the source electrode 32 from the source terminal surface 56 at an inner portion of the source terminal surface 56, in addition to the aforementioned source recessed portion 58. The inward recessed portion 98 is one mode of the source recessed portion 58.

In this embodiment, the inward recessed portion 98 includes a first inward recessed portion 98A that extends in the first direction X and a second inward recessed portion 98B that extends in the second direction Y in plan view. In this embodiment, the first inward recessed portion 98A is formed in a band shape extending in the first direction X such as to cross the source terminal surface 56 in plan view. The first inward recessed portion 98A has a both end portion that is continuous to the source terminal side wall 57 (source recessed portion 58).

In this embodiment, when a line that passes through a gate terminal electrode 45 in the first direction X is set, the first inward recessed portion 98A is formed such as to be positioned on the line. As a matter of course, the first inward recessed portion 98A may be formed at an interval inward from the source terminal side wall 57 (source recessed portion 58) such as not to cross the source terminal surface 56. For example, the first inward recessed portion 98A may be formed in an opening shape at an interval inward from a peripheral edge of the source terminal surface 56.

In this embodiment, the second inward recessed portion 98B is formed in a band shape extending in the second direction Y such as to intersect the source terminal surface 56 in plan view. Thereby, the second inward recessed portion 98B intersects (specifically, perpendicularly intersect) the first inward recessed portion 98A in a crosswise pattern (lattice pattern) in plan view. The second inward recessed portion 98B has a both end portion that is continuous to the source terminal side wall 57 (source recessed portion 58).

In this embodiment, when a line that passes through a central portion of the first inward recessed portion 98A in the second direction Y is set, the second inward recessed portion 98B is formed such as to be positioned on this line. That is, an intersecting portion of the first inward recessed portion 98A and the second inward recessed portion 98B opposes the gate terminal electrode 45 in the first direction X in plan view. As a matter of course, the second inward recessed portion 98B may be formed at an interval inward from the source terminal side wall 57 (source recessed portion 58) such as not to cross the source terminal surface 56. For example, the second inward recessed portion 98B may be formed in an opening shape at an interval inward from the peripheral edge of the source terminal surface 56.

In this embodiment, the source terminal electrode 55 includes a single first source terminal layer 59 and a plurality of second source terminal layers 60. The first source terminal layer 59 has the same mode as that of the first embodiment. The plurality of second source terminal layers 60 each protrude toward the opposite side of the chip 2 from the first source terminal layer 59 such as to define the source recessed portion 58 and the inward recessed portion 98 with the first source terminal layer 59. That is, the plurality of second source terminal layers 60 are each arranged on the first source main surface 59a such as to expose a part of the first source main surface 59a.

The plurality of second source terminal layers 60 are formed at an interval from the peripheral edge of the first source terminal layer 59 such as to define the source recessed portion 58 in a notched shape with the peripheral edge (first source side wall 59b) of the first source terminal layer 59. In this embodiment, the plurality of second source terminal layers 60 are arranged at an interval inward from the entire peripheral edge of the first source terminal layer 59 and define the source recessed portion 58 that exposes the peripheral edge portion of the first source main surface 59a over an entire circumference.

The plurality of second source terminal layers 60 are arrayed at an interval with each other on the first source terminal layer 59 such as to define the inward recessed portion 98 in a trench shape with an inner portion (first source main surface 59a) of the first source terminal layer 59. In this embodiment, the plurality of second source terminal layers 60 are arrayed in a matrix shape at intervals in the first direction X and in the second direction Y in plan view.

A total area of a second source planar area is less than a first source planar area of the first source terminal layer 59 and adjusted according to the first source planar area. The total area of the second source planar area preferably exceeds a second gate planar area of the second gate terminal layer 50. Each second source planar area preferably exceeds a second gate planar area. As a matter of course, each second source planar area may be less than the second gate planar area. The total area of the second source planar area is preferably not less than 50% of a first main surface 3. The total area of the second source planar area is particularly preferably not less than 75% of the first main surface 3.

In a case in which the first main surface 3 has a planar area of not less than 1 mm square, a planar area of each second source planar area is preferably not less than 0.8 mm square. In this case, the planar area of each second source planar area is particularly preferably not less than 1 mm square. Each second source terminal layer 60 may be formed in a polygonal shape having a planar area of not less than 1 mm×1.4 mm. In this embodiment, each second source terminal layer 60 is formed in a quadrangle shape having four sides parallel to first to fourth side surfaces 5A to 5D in plan view. As a matter of course, each second source terminal layer 60 may be formed in a polygonal shape other than the quadrangle shape, a circular shape or an elliptical shape in plan view.

As described so far, the source terminal electrode 55 has the ruggedness structure including the inward recessed portion 98, in addition to the aforementioned source recessed portion 58. A volume of the source terminal electrode 55 is reduced only by an extent of the source recessed portion 58 and that of the inward recessed portion 98. A planar shape, an area, a depth, etc., of the inward recessed portion 98 are adjusted by adjusting a planar shape, an area and a thickness of the second source terminal layer 60. The plurality of second source terminal layers 60 are to be connecting portions to which conducting wires (for example, a bonding wire and a conductor plate) and conductive adhesives (for example, a solder and a conductive paste), etc., are connected. Therefore, modes of the plurality of second source terminal layers 60 are each adjusted as long as a connection area for the conducting wire, the conductive adhesives, etc., can be secured.

A sealing insulator 71 covers the first source terminal layer 59 and the plurality of second source terminal layers 60 such as to expose some of the plurality of second source terminal layers 60 on the source terminal electrode 55 side. Specifically, the sealing insulator 71 covers the first source side wall 59b and the plurality of second source side walls 60b such as to expose the plurality of second source main surfaces 60a.

The sealing insulator 71 includes the portion that is positioned inside the source recessed portion 58 and a portion that is positioned inside the inward recessed portion 98. That is, in this embodiment, the sealing insulator 71 includes the portion that covers the peripheral edge portion and the inner portion of the first source terminal layer 59. Specifically, the sealing insulator 71 includes a portion that is positioned inside the first inward recessed portion 98A and a portion that is positioned inside the second inward recessed portion 98B.

In a case in which the first inward recessed portion 98A is formed in an opening shape, a portion of the sealing insulator 71 that is positioned inside the first inward recessed portion 98A is formed in separation from other portions. In a case in which the second inward recessed portion 98B is formed in an opening shape, a portion of the sealing insulator 71 that is positioned inside the second inward recessed portion 98B is formed in separation from other portions.

The sealing insulator 71 extends in a band shape inside the first inward recessed portion 98A in the first direction X and covers the inner portion of the first source terminal layer 59. The sealing insulator 71 covers the first source main surface 59a of the first source terminal layer 59 inside the first inward recessed portion 98A and covers the second source side walls 60b of the plurality of second source terminal layers 60.

The sealing insulator 71 extends in a band shape inside the second inward recessed portion 98B in the second direction Y and covers the inner portion of the first source terminal layer 59. The sealing insulator 71 covers the first source main surface 59a of the first source terminal layer 59 inside the second inward recessed portion 98B and covers the second source side walls 60b of the plurality of second source terminal layers 60. As described so far, the sealing insulator 71 includes the portion that covers the first source terminal layer 59 in a crosswise pattern (lattice pattern) in plan view. A planar area of the inward recessed portion 98 preferably exceeds a planar area of the gate recessed portion 48. The planar area of the inward recessed portion 98 preferably exceeds a planar area of the gate terminal electrode 45.

The sealing insulator 71 has the laminated structure including the first sealing insulator 74 and the second sealing insulator 75, as with the case of the first embodiment. The first sealing insulator 74 has the same mode as that of the first embodiment. The second sealing insulator 75 covers peripheries of the plurality of second source terminal layers 60 on the first sealing insulator 74 such as to expose the second source main surface 60a and cover the second source side wall 60b on the source terminal electrode 55 side.

In this embodiment, the second sealing insulator 75 enters into the source recessed portion 58 and the inward recessed portion 98 from on the first sealing insulator 74. The second sealing insulator 75 covers the first source main surface 59a and the second source side wall 60b inside the inward recessed portion 98. That is, in this embodiment, the second sealing insulator 75 includes the portion that covers the first source terminal layer 59 in the crosswise pattern (lattice pattern) in plan view.

As described above, the semiconductor device 1B includes the source terminal electrode 55 having the inward recessed portion 98 that is formed at the inner portion of the source terminal surface 56. According to this structure, a volume of the source terminal electrode 55 is reduced by the inward recessed portion 98, and a stress due to the source terminal electrode 55 is decreased. Thereby, it is possible to suppress a failure in formation of the chip 2 and a change in electrical characteristics due to a stress of the source terminal electrode 55. It is, thereby, possible to provide the semiconductor device 1B capable of improving the reliability.

In this structure, the source terminal electrode 55 preferably includes the first source terminal layer 59 that is arranged on the source electrode 32 and at least one second source terminal layer 60 that is arranged on the first source terminal layer 59 such as to define the inward recessed portion 98 with the first source terminal layer 59. According to this structure, it is possible to freely adjust a layout of the second source terminal layer 60 while a volume of the source terminal electrode 55 is reduced. For example, at least one second source terminal layer 60 may be arranged on the first source terminal layer 59 such as to define at least one inward recessed portion 98 with the first source terminal layer 59.

The source terminal electrode 55 does not necessarily have to include both of the source recessed portion 58 and the inward recessed portion 98 at the same time. Therefore, the source terminal electrode 55 may not have the source recessed portion 58 but may have only the inward recessed portion 98. Further, the inward recessed portion 98 does not necessarily have to be formed in a crosswise pattern (lattice pattern) in plan view. The inward recessed portion 98 may include, for example, the first inward recessed portion 98A extending in the first direction X in plan view and the second inward recessed portion 98B extending in the second direction Y such as to intersect the first inward recessed portion 98A in an L letter shape in plan view.

Further, the inward recessed portion 98 does not necessarily have to include both of the first inward recessed portion 98A and the second inward recessed portion 98B at the same time. The inward recessed portion 98 may be configured of a single first inward recessed portion 98A or a single second inward recessed portion 98B. As a matter of course, the inward recessed portion 98 may be formed in stripes extending in the first direction X by the plurality of first inward recessed portions 98A. The inward recessed portion 98 may also be formed in stripes extending in the second direction Y by the plurality of second inward recessed portions 98B. As a matter of course, the inward recessed portion 98 may be formed in a lattice pattern by the plurality of first inward recessed portions 98A and the plurality of second inward recessed portions 98B.

The inward recessed portion 98 is preferably applied to the source terminal electrode 55 having a planar area (volume) larger than that of the gate terminal electrode 45. In this case, it is possible to appropriately decrease a stress due to the source terminal electrode 55 having a relatively large planar area (volume). As a matter of course, the gate terminal electrode 45 may have the inward recessed portion 98 that is formed at an inner portion of the gate terminal surface 46.

The semiconductor device 1B is manufactured through the same manufacturing method as that of the semiconductor device 1A. In the manufacturing method for the semiconductor device 1B, the second resist mask 95 including the plurality of second upper openings 95b for partially exposing the first source terminal layer 59 is formed in the step of forming the second resist mask 95 (refer to FIG. 13H), and the steps similar to those described in FIG. 13I to FIG. 13N are performed. Therefore, the same effects as those of the manufacturing method for the semiconductor device 1A are also achieved by the manufacturing method for the semiconductor device 1B.

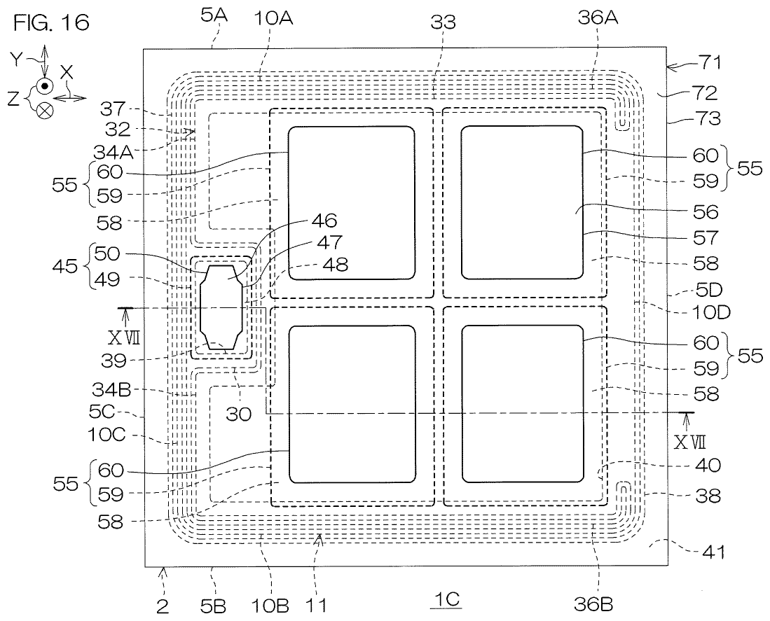

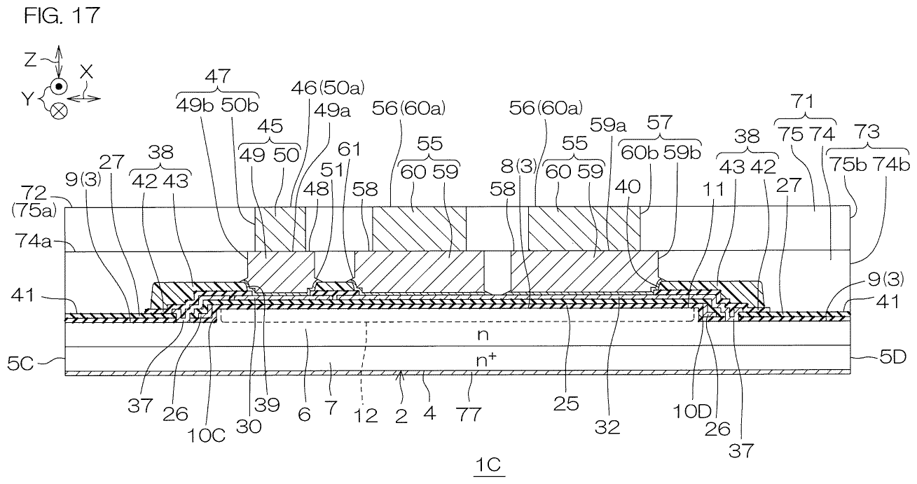

FIG. 16 is a plan view that shows a semiconductor device 1C according to a third embodiment. FIG. 17 is a cross sectional view taken along XVII-XVII line shown in FIG. 16. The semiconductor device 1C has a mode in which the semiconductor device 1A is deformed. Specifically, the semiconductor device 1C includes a plurality of the source terminal electrodes 55 that are arranged on the source electrode 32. The number of the plurality of source terminal electrodes 55 is arbitrary. In this embodiment, the four source terminal electrodes 55 are arrayed in a matrix shape at an interval in the first direction X and in the second direction Y such as to expose a part of the source electrode 32. In this embodiment, the source electrode 32 is exposed from a region outside the plurality of source terminal electrodes 55 in a lattice pattern (crosswise pattern) in plan view.

As with the case of the first embodiment, the plurality of source terminal electrodes 55 each have the ruggedness structure. Specifically, the plurality of source terminal electrodes 55 each have the source recessed portion 58 that is recessed toward the source electrode 32 from the source terminal surface 56. The source recessed portion 58 is formed in each source terminal surface 56 in the same mode as that of the first embodiment.

The plurality of source terminal electrodes 55 each have the laminated structure that includes the first source terminal layer 59 and the second source terminal layer 60. The first source terminal layer 59 and the second source terminal layer 60 are formed in the same mode as that of the first embodiment except for a difference in planar area. Each of the first source terminal layers 59 has the first source planar area, and each of the second source terminal layers 60 has the second source planar area.

A total area of the first source planar area is less than the planar area of the source electrode 32 and adjusted according to the planar area of the first main surface 3. The total area of the first source planar area preferably exceeds the first gate planar area of the first gate terminal layer 49. Each first source planar area particularly preferably exceeds the first gate planar area. The total area of the first source planar area is preferably not less than 50% of the first main surface 3. The total area of the first source planar area is particularly preferably not less than 75% of the first main surface 3.

In a case in which the first main surface 3 has the planar area of not less than 1 mm square, the planar area of each first source planar area is preferably not less than 0.8 mm square. In this case, the planar area of each first source planar area is particularly preferably not less than 1 mm square. Each of the first source terminal layers 59 may be formed in a polygonal shape having a planar area of not less than 1 mm×1.4 mm. In this embodiment, each of the first source terminal layers 59 is formed in a quadrangle shape having four sides parallel to first to fourth side surfaces 5A to 5D in plan view. As a matter of course, each of the first source terminal layers 59 may be formed in a polygonal shape other than the quadrangle shape, a circular shape or an elliptical shape in plan view.

The second source planar area is less than the first source planar area of the first source terminal layer 59 and adjusted according to the first source planar area. The total area of the second source planar area preferably exceeds a second gate planar area of a second gate terminal layer 50. Each second source planar area preferably exceeds the second gate planar area. As a matter of course, each second source planar area may be less than the second gate planar area. A total area of the second source planar area is preferably not less than 50% of the first main surface 3. The total area of the second source planar area is particularly preferably not less than 75% of the first main surface 3.

In a case in which the first main surface 3 has the planar area of not less than 1 mm square, the planar area of each second source planar area is preferably not less than 0.8 mm square. In this case, the planar area of each second source planar area is particularly preferably not less than 1 mm square. Each of the second source terminal layers 60 may be formed in a polygonal shape having a planar area of not less than 1 mm×1.4 mm. In this embodiment, each of the second source terminal layers 60 is formed in a quadrangle shape having four sides parallel to the first to fourth side surfaces 5A to 5D in plan view. As a matter of course, each of the second source terminal layers 60 may be formed in a polygonal shape other than the quadrangle shape, a circular shape or an elliptical shape in plan view.

In this embodiment, the sealing insulator 71 covers the periphery of the gate terminal electrode 45 and peripheries of the plurality of the source terminal electrodes 55 such as to expose the gate terminal electrode 45 and the plurality of source terminal electrodes 55 on the first main surface 3. That is, the sealing insulator 71 fills a region between the plurality of source terminal electrodes 55. The sealing insulator 71 has a portion that directly covers a portion exposed from a region between the plurality of source terminal electrodes 55 in the source electrode 32. That is, in this embodiment, the sealing insulator 71 includes a portion that covers in a lattice pattern (a crosswise pattern) a portion of the source electrode 32 that is exposed from the plurality of source terminal electrodes 55 in plan view.

With regard to each of the source terminal electrodes 55, the sealing insulator 71 covers the first source terminal layer 59 and the second source terminal layer 60 such as to expose a part of the second source terminal layer 60. Specifically, the sealing insulator 71 covers the first source side wall 59b and the second source side wall 60b such as to expose the second source main surface 60a. The sealing insulator 71 includes the portion that is positioned inside the source recessed portion 58 of each of the source terminal electrodes 55. That is, in this embodiment, the sealing insulator 71 includes the portion that surrounds each of the second source terminal layers 60 on each of the first source terminal layers 59 in plan view.

The sealing insulator 71 has the laminated structure that includes the first sealing insulator 74 and the second sealing insulator 75. The first sealing insulator 74 covers the periphery of each of the first source terminal layers 59 in the same mode as that of the first embodiment. The second sealing insulator 75 covers the periphery of each of the second source terminal layers 60 in the same mode as that of the first embodiment. In this embodiment, the second sealing insulator 75 includes the portion that covers each of the source recessed portions 58 on each of the first source terminal layers 59 and surrounds each of the second source terminal layers 60 in plan view.

As described above, the semiconductor device 1C includes the plurality of source terminal electrodes 55 that are arranged on the source electrode 32. According to this structure, as compared with a case that the single source terminal electrode 55 is formed on the source electrode 32, it is possible to reduce a total planar area (total volume) of the source terminal electrode 55. Further, the plurality of source terminal electrodes 55 each have the source recessed portion 58 that is formed in an inner portion of the source terminal surface 56.

Therefore, the plurality of source terminal electrodes 55 are each reduced in volume by the source recessed portion 58, and a stress due to the plurality of source terminal electrodes 55 is decreased. It is, thereby, possible to suppress a failure in formation of the chip 2 and a change in electrical characteristics due to a stress of the plurality of source terminal electrodes 55. It is, thereby, possible to provide the semiconductor device 1C capable of improving the reliability.

In the above-described structure, each of the source terminal electrodes 55 preferably includes the first source terminal layer 59 that is arranged on the source electrode 32 and at least one second source terminal layer 60 that is arranged on the first source terminal layer 59 such as to define the source recessed portion 58 with the first source terminal layer 59. According to this structure, it is possible to freely adjust a layout of the plurality of source terminal electrodes 55, while the plurality of source terminal electrodes 55 are reduced in volume.

The plurality of source terminal electrodes 55 do not necessarily have to have the same planar shape or the same planar area. Therefore, the plurality of source terminal electrodes 55 may have a planar shape and a planar area that are different from each other. Further, the plurality of source terminal electrodes 55 do not necessarily have to be arrayed in a matrix shape at an interval in the first direction X and in the second direction Y in plan view. The plurality of source terminal electrodes 55 may be arrayed in a zigzag (staggered) pattern at intervals in the first direction X and in the second direction Y in plan view. The plurality of source terminal electrodes 55 may also be arrayed at intervals only in one of the first direction X and the second direction Y in plan view.

In this case, the plurality of source terminal electrodes 55 may be arrayed in stripes extending in one of the first direction X and the second direction Y in plan view. Further, the plurality of source terminal electrodes 55 do not all have to include the source recessed portion 58 at the same time. There may be adopted a mode in which, for example, at least one of the plurality of source terminal electrodes 55 has the source recessed portion 58.

The structure according to the semiconductor device 1C is preferably applied to the source terminal electrode 55 having a total planar area (total volume) larger than the gate terminal electrode 45. In this case, it is possible to appropriately decrease a stress due to the source terminal electrode 55 having a relatively large total planar area (total volume). As a matter of course, the plurality of gate terminal electrodes 45 may be arrayed on a gate electrode 30.

The semiconductor device 1C is manufactured through the same manufacturing method as that of the semiconductor device 1A. In the manufacturing method for the semiconductor device 1C, a first resist mask 92 having a plurality of second openings 92b for exposing the source electrode 32 is formed in the step of forming the first resist mask 92 (refer to FIG. 13B), and the steps similar to those shown in FIG. 13C to FIG. 13G are performed.

Then, a second resist mask 95 including a plurality of second upper openings 95b for exposing a part of each of the plurality of first source terminal layers 59 is formed in the step of forming the second resist mask 95 (refer to FIG. 13H), and the steps similar to those shown in FIG. 13I to FIG. 13N are performed. Therefore, the same effects as those of the manufacturing method for the semiconductor device 1A are also achieved by the manufacturing method for the semiconductor device 1C.

The structure according to the semiconductor device 1C may be combined with the second embodiment. That is, at least one of the source terminal electrodes 55 according to the semiconductor device 1C may have an inward recessed portion 98 as with the case of the source terminal electrode 55 according to the semiconductor device 1B.

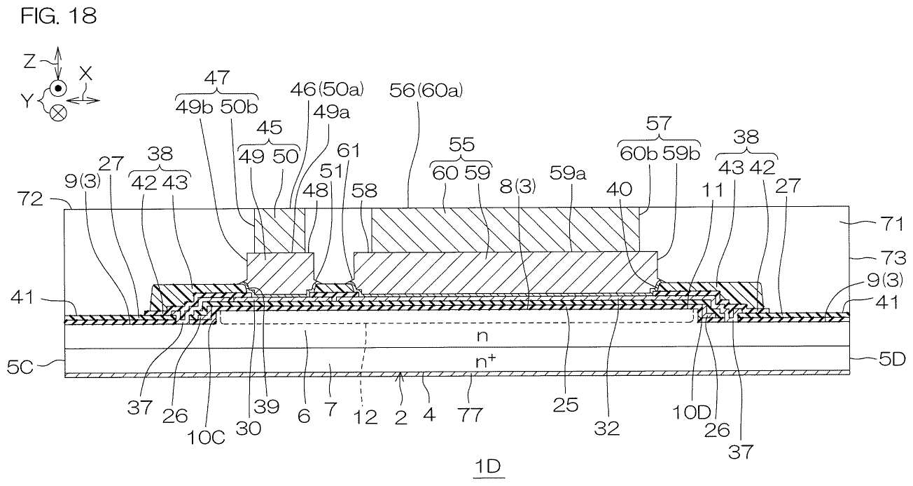

FIG. 18 is a plan view that shows a semiconductor device 1D according to a fourth embodiment. The semiconductor device 1D has a mode in which the semiconductor device 1A is deformed. In this embodiment, the semiconductor device 1D includes the first gate terminal layer 49 having the first gate main surface 49a that consists of a flat surface without grinding marks. That is, in this embodiment, the second gate terminal layer 50 is arranged on the first gate main surface 49a that consists of the flat surface. The second gate terminal layer 50 may be integrally formed with the first gate terminal layer 49. As a matter of course, the second gate terminal layer 50 may be arranged on the first gate terminal layer 49 in a mode that a boundary portion with the first gate terminal layer 49 can be identified.

In this embodiment, the semiconductor device 1D includes the first source terminal layer 59 having the first source main surface 59a that consists of a flat surface without grinding marks. That is, in this embodiment, the second source terminal layer 60 is arranged on the first source main surface 59a that consists of the flat surface. The second source terminal layer 60 may be integrally formed with the first source terminal layer 59. As a matter of course, the second source terminal layer 60 may be arranged on the first source terminal layer 59 in a mode that a boundary portion with the first source terminal layer 59 can be identified.

In this embodiment, the semiconductor device 1D includes the sealing insulator 71 consisting of a single layered structure. The sealing insulator 71 according to the semiconductor device 1D covers the gate terminal electrode 45 and the source terminal electrode 55 in the same mode as that of the sealing insulator 71 according to the semiconductor device 1A except that neither the first sealing insulator 74 nor the second sealing insulator 75 is included. As described above, the same effects as those of the semiconductor device 1A are also achieved by the semiconductor device 1D. As a matter of course, the structure according to the semiconductor device 1D may be combined with the second to third embodiments.

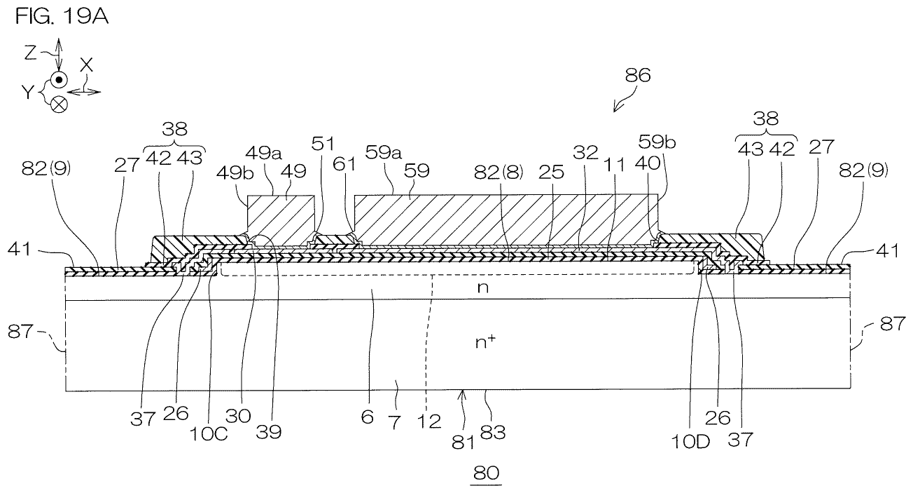

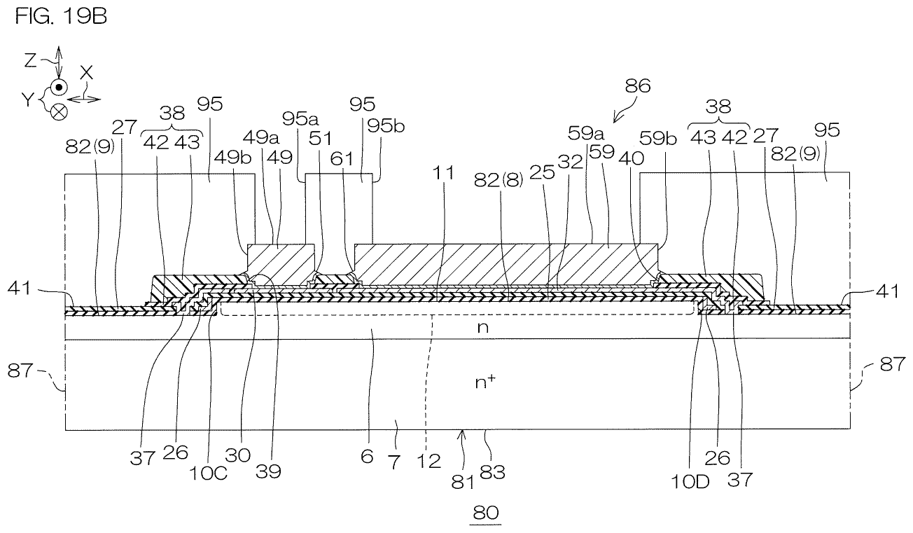

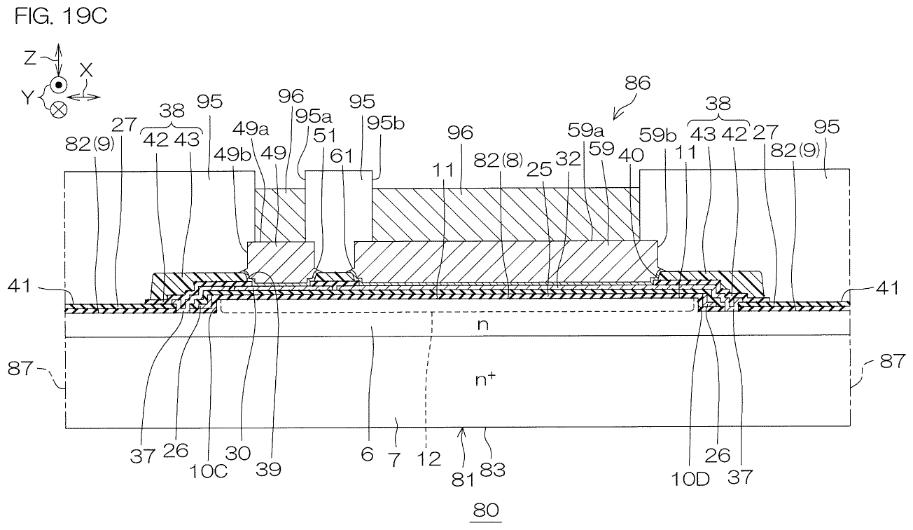

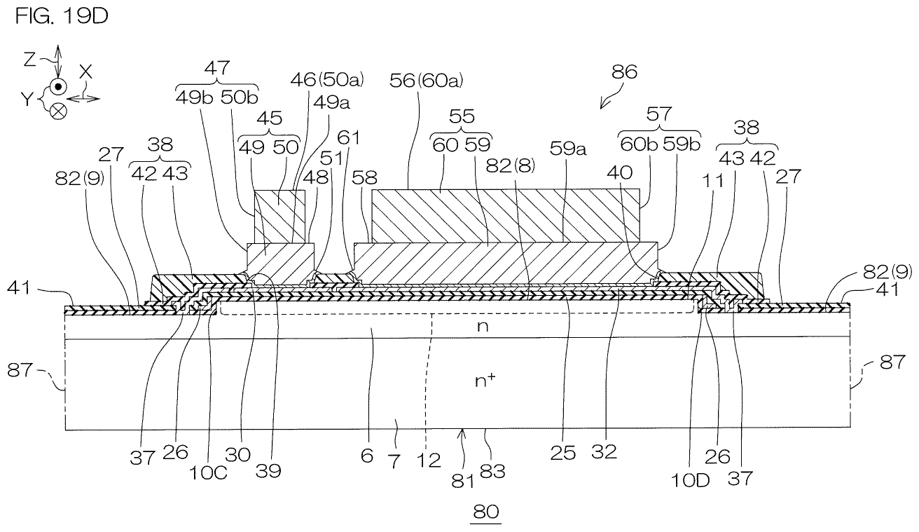

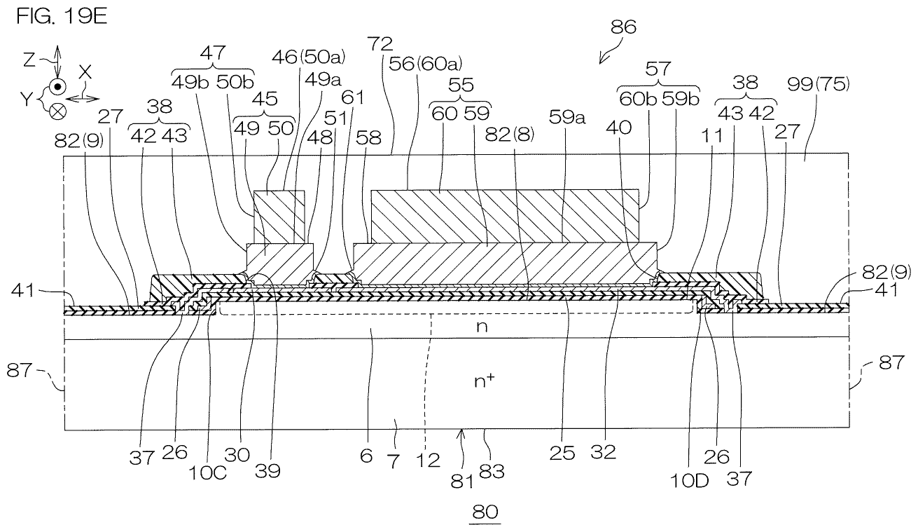

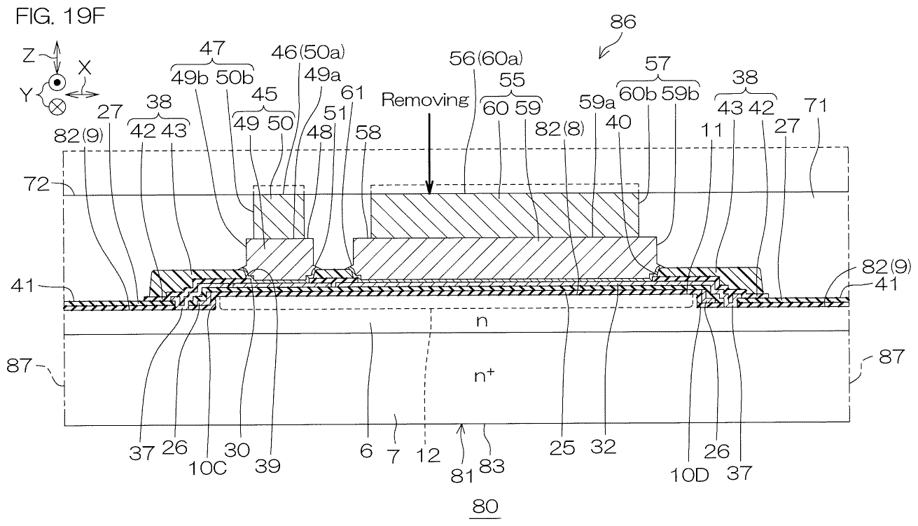

FIG. 19A to FIG. 19F are each a cross sectional view that shows an example of the manufacturing method for the semiconductor device 1D shown in FIG. 18. With reference to FIG. 19A, the steps of FIG. 13A to FIG. 13E are performed, and a wafer structure 80 that includes the first gate terminal layer 49 and the first source terminal layer 59 is prepared.

Next, with reference to FIG. 19B, the second resist mask 95 having a predetermined pattern is formed on the first wafer main surface 82. As with the case of the first embodiment, the second resist mask 95 includes the first upper opening 95a that exposes the first gate terminal layer 49 and the second upper opening 95b that exposes the first source terminal layer 59.

Next, with reference to FIG. 19C, as with the case of the first embodiment, the fourth base conductor film 96 which is to be the base of the third gate conductor film 54 (second gate terminal layer 50) and that of the third source conductor film 64 (second source terminal layer 60) is formed on the first gate terminal layer 49 and the first source terminal layer 59.

Next, with reference to FIG. 19D, the second resist mask 95 is removed. Thereby, the first gate terminal layer 49, the first source terminal layer 59, the second gate terminal layer 50 and the second source terminal layer 60 are exposed outside.

Next, with reference to FIG. 19E, a sealant 99 is supplied on the first wafer main surface 82 such as to cover the first gate terminal layer 49, the first source terminal layer 59, the second gate terminal layer 50 and the second source terminal layer 60. The sealant 99 is to be a base of the sealing insulator 71 consisting of the single layered structure. The sealant 99 fills a periphery of the first gate terminal layer 49, a periphery of the second gate terminal layer 50, a periphery of the first source terminal layer 59 and a periphery of the second source terminal layer 60 and covers a whole region of the upper insulating film 38, a whole region of the first gate terminal layer 49, a whole region of the second gate terminal layer 50, a whole region of the first source terminal layer 59 and a whole region of the second source terminal layer 60.

The sealant 99 enters into the gate recessed portion 48 on the second gate terminal layer 50 side and covers the first gate terminal layer 49 and the second gate terminal layer 50 inside the gate recessed portion 48. The sealant 99 also enters into the source recessed portion 58 on the second source terminal layer 60 side and covers the first source terminal layer 59 and the second source terminal layer 60 inside the source recessed portion 58. In this embodiment, the sealant 99 has the thermosetting resin, the plurality of fillers and the plurality of flexible particles and is cured by heating. The sealing insulator 71 has the insulating main surface 72 that covers a whole region of the second gate terminal layer 50 and a whole region of the second source terminal layer 60.

Next, with reference to FIG. 19F, the sealing insulator 71 is partially removed. In this embodiment, the sealing insulator 71 is ground by a grinding method from the insulating main surface 72 side. The grinding method may be a mechanical polishing method and/or a chemical mechanical polishing method. The insulating main surface 72 is ground until the second gate terminal layer 50 and the second source terminal layer 60 are exposed. This step includes the step of grinding the second gate terminal layer 50 and the second source terminal layer 60. Thereby, the insulating main surface 72 that forms one ground surface between a second gate main surface 50a and a second source main surface 60a is formed. Thereby, the sealing insulator 71 that has the single layered structure is also formed.

The sealing insulator 71 may be formed in a semi-cured state (incompletely cured state) by adjusting the heating conditions in the step of FIG. 19 aforementioned. In this case, the sealing insulator 71 is ground in the step of FIG. 19F and then heated again to form a fully cured state (completely cured state). In this case, it is possible to easily remove the sealing insulator 71. Thereafter, the steps of FIG. 13M to FIG. 13N are performed and the semiconductor device 1D is manufactured.

As described above, the same effects as those of the manufacturing method for the semiconductor device 1A are also achieved by the manufacturing method for the semiconductor device 1D. Further, according to the manufacturing method for the semiconductor device 1D, the grinding steps of the first gate terminal layer 49 and the first source terminal layer 59 can be omitted. It is, thereby, possible to reduce manufacturing man-hours and manufacturing costs.

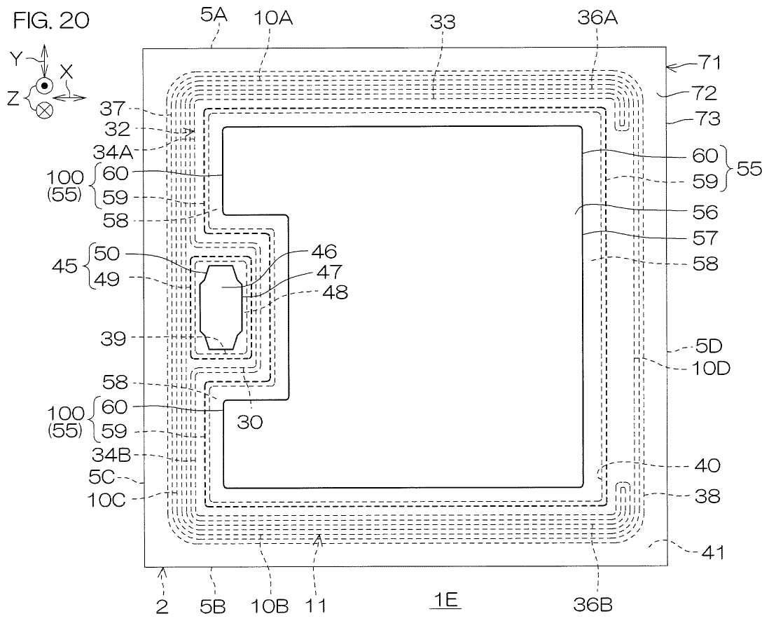

FIG. 20 is a plan view that shows a semiconductor device 1E according to a fifth embodiment. With reference to FIG. 20, the semiconductor device 1E has a mode in which a layout of the source terminal electrode 55 is deformed in the semiconductor device 1A. Specifically, the semiconductor device 1E includes the source terminal electrode 55 having at least one drawer terminal portion 100 (a plurality of them in this embodiment). In this embodiment, the plurality of drawer terminal portions 100 are formed by the first source terminal layer 59 and the second source terminal layer 60 and have the aforementioned source recessed portion 58.

The plurality of drawer terminal portions 100 are each drawn out onto the plurality of drawer electrode portions 34A, 34B of the source electrode 32 such as to oppose the gate terminal electrode 45 in the second direction Y. That is, the plurality of drawer terminal portions 100 sandwich the gate terminal electrode 45 from both sides in the second direction Y in plan view.

As described above, the same effects as those of the semiconductor device 1A are also achieved by the semiconductor device 1E. The semiconductor device 1E is also manufactured through the same manufacturing method as that of the semiconductor device 1A. Therefore, the same effects as those of the manufacturing method for the semiconductor device 1A are also achieved by the manufacturing method for the semiconductor device 1E. In this embodiment, there is shown an example in which the drawer terminal portion 100 is applied to the semiconductor device 1A. As a matter of course, the drawer terminal portion 100 may be applied to the second to fourth embodiments.

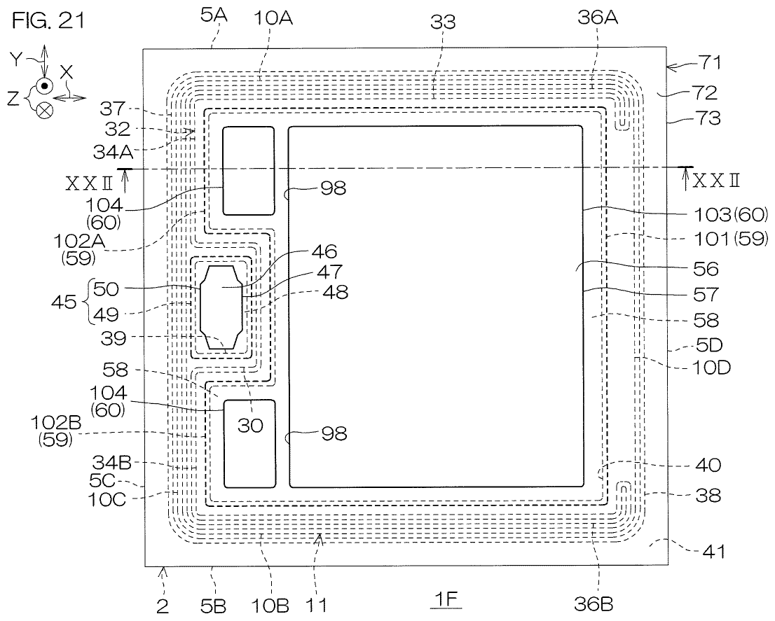

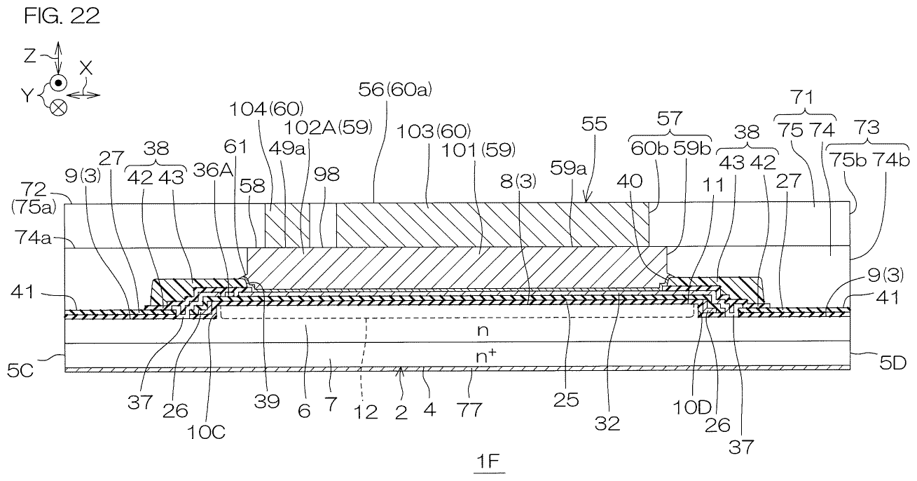

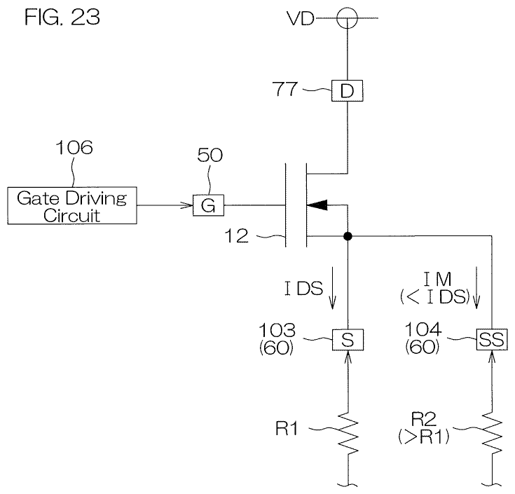

FIG. 21 is a plan view that shows a semiconductor device 1F according to a sixth embodiment. FIG. 22 is a cross sectional view taken along XXII-XXII line shown in FIG. 21. FIG. 23 is a circuit diagram that shows an electrical configuration of the semiconductor device 1F shown in FIG. 22. With reference to FIG. 21 to FIG. 23, the semiconductor device 1F has a mode in which a layout of the source terminal electrode 55 is deformed in the semiconductor device 1B (refer to FIG. 14 and FIG. 15).

In this embodiment, the source terminal electrode 55 includes a main body layer 101 and the first source terminal layer 59 having at least one (a plurality of them in this embodiment) drawer terminal layer 102A, 102B. The main body layer 101 is formed on the main body electrode portion 33 of the source electrode 32. The plurality of drawer terminal layers 102A, 102B are each drawn out onto the plurality of drawer electrode portions 34A, 34B of the source electrode 32 from the main body layer 101 such as to oppose the gate terminal electrode 45 in the second direction Y. That is, the plurality of drawer terminal layers 102A, 102B sandwich the gate terminal electrode 45 from both sides in the second direction Y in plan view.

In this embodiment, the semiconductor device 1F includes the plurality of second source terminal layers 60 that are arranged at an interval on the first source terminal layer 59. As with the case of the semiconductor device 1B, the plurality of second source terminal layers 60 define the source recessed portion 58 and the inward recessed portion 98 with the first source terminal layer 59. The plurality of second source terminal layers 60 include at least one (one in this embodiment) second source terminal layer 60 that is arranged on the main body layer 101 and at least one (the plurality of them in this embodiment) second source terminal layer 60 that are arranged on the drawer terminal layer 102A, 102B.

In this embodiment, the second source terminal layer 60 on the main body layer 101 side is formed as a main terminal layer 103 that conducts a drain source current IDS. In this embodiment, the plurality of source terminal electrodes 55 on the plurality of drawer layers side are formed as a sense terminal layer 104 that conducts a monitor current IM for monitoring the drain source current IDS. Each of the sense terminal layers 104 has an area that is less than an area of the main terminal layer 103 in plan view.

The sense terminal layer 104 is arranged on the drawer terminal layer 102A on one side and opposes the gate terminal electrode 45 in the second direction Y in plan view. The sense terminal layer 104 is arranged on the drawer terminal layer 102B on the other side and opposes the gate terminal electrode 45 in the second direction Y in plan view. Thereby, the plurality of sense terminal layers 104 sandwich the gate terminal electrode 45 from both sides in the second direction Y in plan view.

With reference to FIG. 23, in the semiconductor device 1F, a gate driving circuit 106 is to be electrically connected to the gate terminal electrode 45, at least one first resistance R1 is to be electrically connected to the main terminal layer 103, and at least one second resistance R2 is to be electrically connected to the plurality of sense terminal layers 104. The first resistance R1 is configured such as to conduct the drain source current IDS that is generated in the semiconductor device 1F. The second resistance R2 is configured such as to conduct the monitor current IM having a value less than that of the drain source current IDS.

The first resistance R1 may be a resistor or a conductive bonding member with a first resistance value. The second resistance R2 may be a resistor or a conductive bonding member with a second resistance value more than the first resistance value. The conductive bonding member may be a conductor plate or a conducting wire (for example, bonding wire). That is, at least one first bonding wire with the first resistance value may be connected to the main terminal layer 103.

Also, at least one second bonding wire with the second resistance value more than the first resistance value may be connected to at least one of the sense terminal layers 104. The second bonding wire may have a line thickness less than a line thickness of the first bonding wire. In this case, a bonding area of the second bonding wire with respect to the sense terminal layers 104 may be less than a bonding area of the first bonding wire with respect to the main terminal layer 103.

As described above, the same effects as those of the semiconductor device 1A are also achieved with the semiconductor device 1F. Also, the semiconductor device 1F can be manufactured through the same manufacturing method as that of the semiconductor device 1A (the semiconductor device 1B). Therefore, the same effects as those of the manufacturing method for the semiconductor device 1A are also achieved with the manufacturing method for the semiconductor device 1F.

In this embodiment, there is shown an example in which the sense terminal layer 104 is arranged on the drawer terminal layers 102A, 102B, and a site at which the sense terminal layer 104 is arranged is arbitrary. Therefore, the sense terminal layer 104 may be arranged on the main body layer 101. In this embodiment, there is shown an example in which the sense terminal layer 104 is applied to the semiconductor device 1B. As a matter of course, the sense terminal layer 104 may be applied to the first to fifth embodiments. In a case in which the sense terminal layer 104 is applied to the semiconductor device 1C (refer to FIG. 16 and FIG. 17) according to the third embodiment, at least one source terminal electrode 55 (second source terminal layer 60) is used as the sense terminal layer 104.

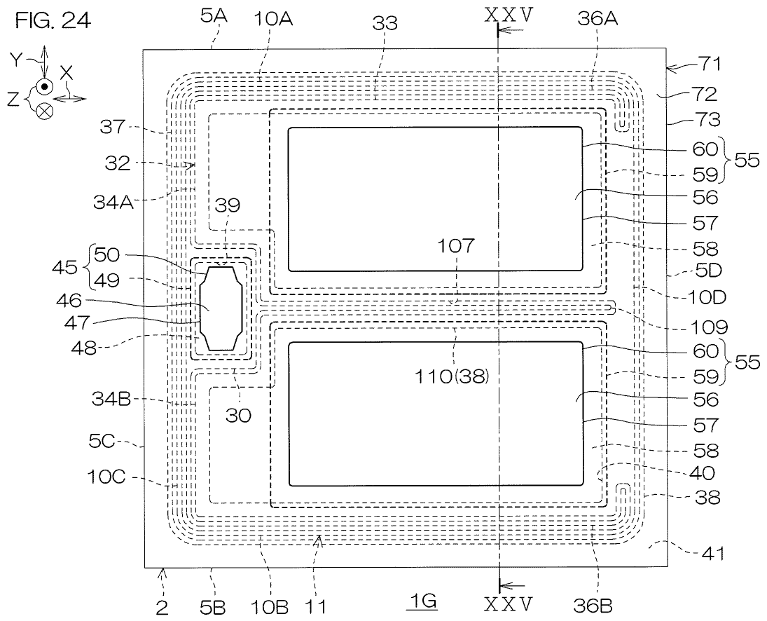

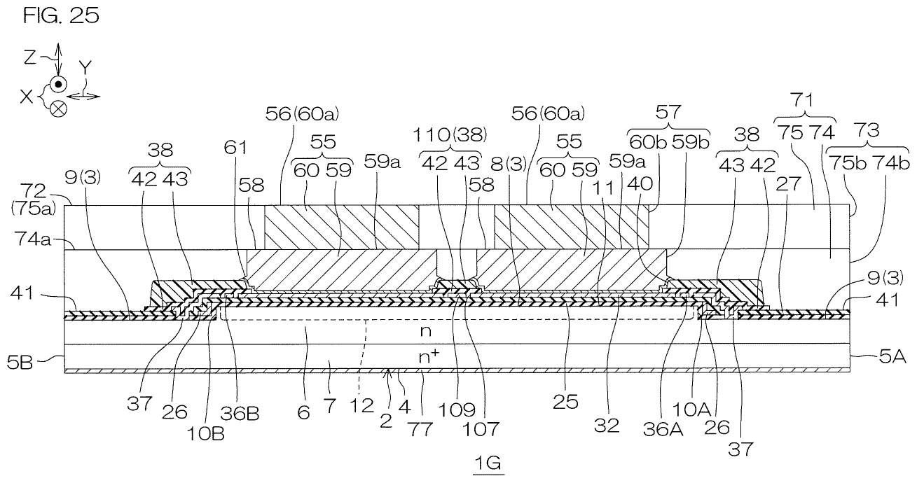

FIG. 24 is a plan view showing a semiconductor device 1G according to a seventh embodiment. FIG. 24 is a cross sectional view taken along XXIV-XXIV line shown in FIG. 24. With reference to FIG. 24 and FIG. 25, the semiconductor device 1G has a modified mode of the semiconductor device 1C (see FIG. 16 and FIG. 17). Specifically, the semiconductor device 1G includes a gap portion 107 formed in the source electrode 32.

The gap portion 107 is formed in the body electrode portion 33 of the source electrode 32. The gap portion 107 penetrates the source electrode 32 and exposes a part of the interlayer insulating film 27 in cross sectional view. The gap portion 107 extends in a band shape toward an inner portion of the source electrode 32 from a portion of a wall portion of the source electrode 32 that opposes the gate electrode 30 in the first direction X, in this embodiment.

The gap portion 107 is formed in a band shape extending in the first direction X, in this embodiment. The gap portion 107 crosses a central portion of the source electrode 32 in the first direction X in plan view, in this embodiment. The gap portion 107 has an end portion at a position at an interval inward (to the gate electrode 30 side) from a wall portion of the source electrode 32 on the fourth side surface 5D side in plan view. As a matter of course, the gap portion 107 may separate the source electrode 32 into the second direction Y.

The semiconductor device 1G includes a gate intermediate wiring 109 that is drawn out into the gap portion 107 from the gate electrode 30. The gate intermediate wiring 109 includes a laminated structure including the first gate conductor film 52 and the second gate conductor film 53 as with the gate electrode 30 (the plurality of gate wirings 36A, 36B). The gate intermediate wiring 109 formed at an interval from the source electrode 32 and extends in a band shape along the gap portion 107 in plan view.

The gate intermediate wiring 109 penetrates the interlayer insulating film 27 at an inner portion of the active surface 8 (the first main surface 3) and is electrically connected to the plurality of gate structures 15. The gate intermediate wiring 109 may be directly connected to the plurality of gate structures 15, or may be electrically connected to the plurality of gate structures 15 via a conductor film.

The upper insulating film 38 aforementioned includes the gap covering portion 110 that covers the gap portion 107 of the source electrode 32, in this embodiment. The gap covering portion 110 covers a whole region of the gate intermediate wiring 109 inside the gap portion 107. The gap covering portion 110 may be drawn out onto the source electrode 32 from inside the gap portion 107 such as to cover a peripheral edge portion of the source electrode 32.

In this embodiment, the semiconductor device 1G includes a plurality of the source terminal electrodes 55 that are arranged at an interval on the source electrode 32. The plurality of source terminal electrodes 55 are each arranged on the source electrode 32 at an interval from the gap portion 107 in plan view and oppose each other in the second direction Y. In this embodiment, the plurality of source terminal electrodes 55 are arranged such as to expose the gap covering portion 110.

In this embodiment, the plurality of source terminal electrodes 55 are each formed in a quadrangle shape (specifically, a rectangular shape extending in the first direction X) in plan view. A planar shape of the plurality of source terminal electrodes 55 is arbitrary and may be formed in a polygonal shape other than the quadrangle shape, a circular shape or an elliptical shape. The plurality of source terminal electrodes 55 may include the second protrusion portion 61 that is formed on the gap covering portion 110 of the upper insulating film 38.

The sealing insulator 71 (specifically the first sealing insulator 74) aforementioned covers the gap portion 107 in a region between the plurality of the source terminal electrodes 55. The sealing insulator 71 covers the gap covering portion 110 of the upper insulating film 38 in a region between the plurality of the source terminal electrodes 55. That is, the sealing insulator 71 covers the gate intermediate wiring 109 across the upper insulating film 38 interposed therebetween.

An example in which the upper insulating film 38 has the gap covering portion 110 has been shown, in this embodiment. However, the presence or the absence of the gap covering portion 110 is arbitrary, and the upper insulating film 38 without the gap covering portion 110 may be formed. In this case, the plurality of source terminal electrodes 55 are arranged on the source electrode 32 such as to expose the gate intermediate wiring 109. The sealing insulator 71 directly covers the gate intermediate wiring 109 and electrically isolates the gate intermediate wiring 109 from the source electrode 32. The sealing insulator 71 directly covers a part of the interlayer insulating film 27 exposed from a region between the source electrode 32 and the gate intermediate wiring 109 in the gap portion 107.

As described above, the same effects as those of the semiconductor device 1A are also achieved with the semiconductor device 1G. In the manufacturing method for the semiconductor device 1G, the wafer structure 80 in which structures corresponding to the semiconductor device 1G are formed in each device region 86 is prepared, and the similar steps to those of the manufacturing method for the semiconductor device 1A (the semiconductor device 1C) are performed. Therefore, the same effects as those of the manufacturing method for the semiconductor device 1A are also achieved with the manufacturing method for the semiconductor device 1G.

In this embodiment, an example in which the gap portion 107, the gate intermediate wiring 109, the gap covering portion 110, etc., are applied to the semiconductor device 1A is shown. As a matter of course, the gap portion 107, the gate intermediate wiring 109, the gap covering portion 110, etc., may be applied to any one of the first to sixth embodiments.

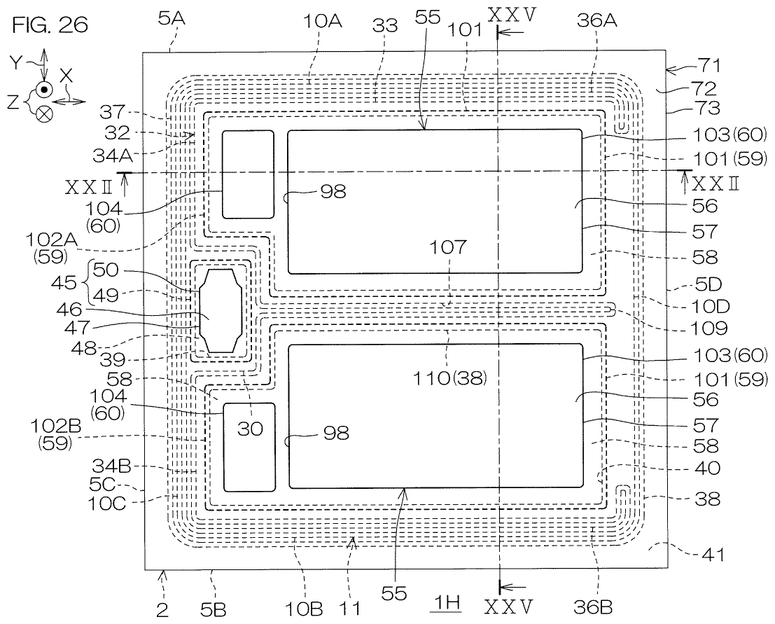

FIG. 26 is a plan view showing a semiconductor device 1H according to an eighth embodiment. The semiconductor device 1H has a mode in which the features (structures having the gate intermediate wiring 109) of the semiconductor device 1G according to the seventh embodiment are combined to the features (structures having the sense terminal portions 102) of the semiconductor device 1F according to the sixth embodiment. The same effects as those of the semiconductor device 1A are also achieved with the semiconductor device 1H having such a mode.

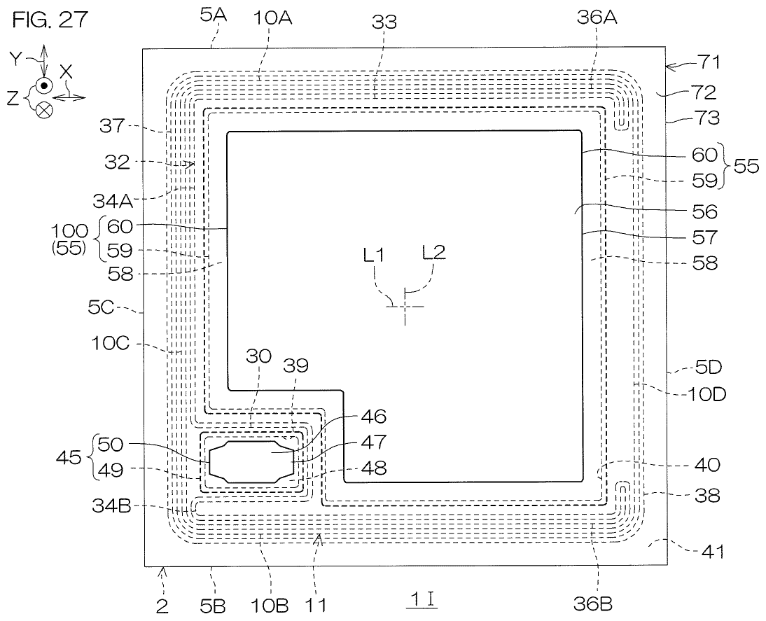

FIG. 27 is a plan view showing a semiconductor device 1I according to a ninth embodiment. With reference to FIG. 27, the semiconductor device 1I has a modified mode of the semiconductor device 1A. Specifically, the semiconductor device 1I has the gate electrode 30 arranged on a region along an arbitrary corner portion of the chip 2.

That is, when a first straight line L1 (see two-dot chain line portion) crossing the central portion of the first main surface 3 in the first direction X and a second straight line L2 (see two-dot chain line portion) crossing the central portion of the first main surface 3 in the second direction Y are set, the gate electrode 30 is arranged at a position offset from both of the first straight line L1 and the second straight line L2. The gate electrode 30 is arranged at a region along a corner portion that connects the second side surface 5B and the third side surface 5C in plan view, in this embodiment.

The plurality of drawer electrode portions 34A, 34B of the source electrode 32 aforementioned sandwich the gate electrode 30 from both sides of the second direction Y in plan view as with the case of the first embodiment. The first drawer electrode portion 34A is drawn out from the body electrode portion 33 with a first planar area. The second drawer electrode portion 34B is drawn out from the body electrode portion 33 with a second planar area less than the first planar area. As a matter of course, the source electrode 32 does not may have the second drawer electrode portion 34B and may only include the body electrode portion 33 and the first drawer electrode portion 34A.

The gate terminal electrode 45 aforementioned is arranged on the gate electrode 30 as with the case of the first embodiment. The gate terminal electrode 45 is arranged at a region along an arbitrary corner portion of the chip 2, in this embodiment. That is, the gate terminal electrode 45 is arranged at a position offset from both of the first straight line L1 and the second straight line L2 in plan view. The gate terminal electrode 45 is arranged at the region along the corner portion that connects the second side surface 5B and the third side surface 5C in plan view, in this embodiment.

The source terminal electrode 55 aforementioned has a drawer terminal portion 100 that is drawn out onto the first drawer electrode portion 34A. The source terminal electrode 55 does not have the drawer terminal portion 100 that is drawn out onto the second drawer electrode portion 34B, in this embodiment. The source terminal electrode 55 thereby face the gate terminal electrode 45 from one side of the second direction Y. The source terminal electrode 55 has portions that face the gate terminal electrode 45 from two directions including the first direction X and the second direction Y by having the drawer terminal portion 100.

As described above, the same effects as those of the semiconductor device 1A are also achieved with the semiconductor device 1I. In the manufacturing method for the semiconductor device 1I, the wafer structure 80 in which structures corresponding to the semiconductor device 1I are formed in each device region 86 is prepared, and the similar steps to those of the manufacturing method for the semiconductor device 1A are performed. Therefore, the same effects as those of the manufacturing method for the semiconductor device 1A are also achieved with the manufacturing method for the semiconductor device 1I. The structure in which the gate electrode 30 and the gate terminal electrode 45 are arranged at the corner portion of the chip 2 may be applied to the second to eighth embodiments.

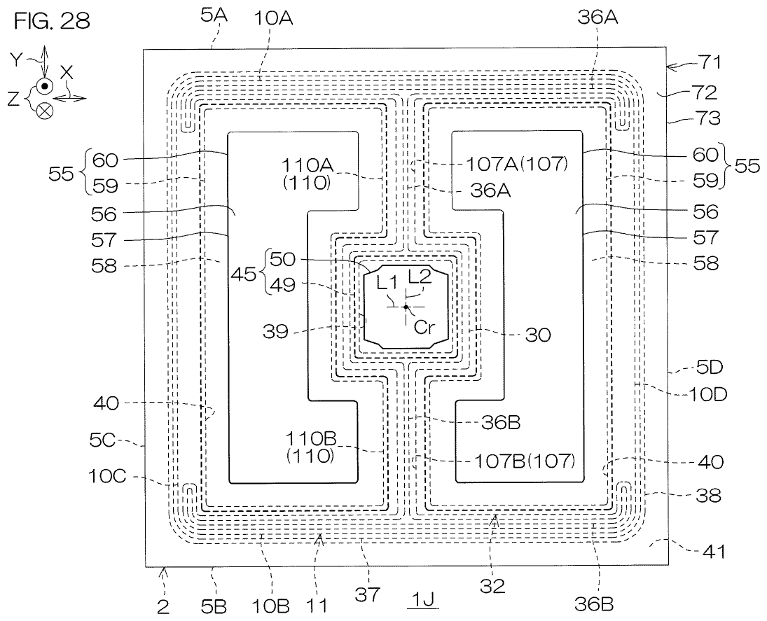

FIG. 28 is a plan view showing a semiconductor device 1J according to a tenth embodiment. With reference to FIG. 28, the semiconductor device 1J has a modified mode of the semiconductor device 1C (see FIG. 16 and FIG. 17) and the semiconductor device 1G (see FIG. 24 and FIG. 25). Specifically, the semiconductor device 1J has the gate electrode 30 arranged at the central portion of the first main surface 3 (the active surface 8) in plan view.

That is, when a first straight line L1 (see two-dot chain line portion) crossing the central portion of the first main surface 3 in the first direction X and a second straight line L2 (see two-dot chain line portion) crossing the central portion of the first main surface 3 in the second direction Y are set, the gate electrode 30 is arranged such as to overlap an intersecting portion Cr of the first straight line L1 and the second straight line L2. The source electrode 32 is formed in an annular shape (specifically, a quadrangle annular shape) surrounding the gate electrode 30 in plan view, in this embodiment.

The semiconductor device 1J includes a plurality of gap portions 107A, 107B that are formed in the source electrode 32. The plurality of gap portions 107A, 107B include a first gap portion 107A and a second gap portion 107B. The first gap portion 107A crosses a portion of the source electrode 32 that extends in the first direction X in a region on one side (the first side surface 5A side) of the source electrode 32 in the second direction Y. The first gap portion 107A faces the gate electrode 30 in the second direction Y in plan view.

The second gap portion 107B crosses a portion of the source electrode 32 that extends in the first direction X in a region on the other side (the second side surface 5B side) of the source electrode 32 in the second direction Y. The second gap portion 107B faces the gate electrode 30 in the second direction Y in plan view. The second gap portion 107B faces the first gap portion 107A with the gate electrode 30 interposed therebetween in plan view, in this embodiment.

The first gate wiring 36A aforementioned is drawn out into the first gap portion 107A from the gate electrode 30. Specifically, the first gate wiring 36A has a portion extending as a band shape in the second direction Y inside the first gap portion 107A and a portion extending as a band shape in the first direction X along the first side surface 5A (the first connecting surface 10A). The second gate wiring 36B aforementioned is drawn out into the second gap portion 107B from the gate electrode 30. Specifically, the second gate wiring 36B has a portion extending as a band shape in the second direction Y inside the second gap portion 107B and a portion extending as a band shape in the first direction X along the second side surface 5B (the second connecting surface 10B).

The plurality of gate wirings 36A, 36B intersect (specifically, perpendicularly intersect) the both end portions of the plurality of gate structures 15 as with the case of the first embodiment. The plurality of gate wirings 36A, 36B penetrate the interlayer insulating film 27 and are electrically connected to the plurality of gate structures 15. The plurality of gate wirings 36A, 36B may be directly connected the plurality of gate structures 15, or may be electrically connected to the plurality of gate structures 15 via a conductor film.

The source wiring 37 aforementioned is drawn out from a plural portions of the source electrode 32 and surrounds the gate electrode 30, the source electrode 32 and the gate wirings 36A, 36B. As a matter of course, the source wiring 37 may be drawn out from a single portion of the source electrode 32 as with the case of the first embodiment.

The upper insulating film 38 aforementioned includes a plurality of gap covering portions 110A, 110B each cover the plurality of gap portions 107A, 107B, in this embodiment. The plurality of gap covering portions 110A, 110B includes a first gap covering portion 110A and a second gap covering portion 110B. The first gap covering portion 110A covers a whole region of the first gate wiring 36A in the first gap portion 107A. The second gap covering portion 110B covers a whole region of the second gate wiring 36B in the second gap portion 107B. The plurality of gap covering portions 110A, 110B are drawn out onto the source electrode 32 from inside the plurality of gap portions 107A, 107B such as to cover a peripheral edge portion of the source electrode 32.

The gate terminal electrode 45 aforementioned is arranged on the gate electrode 30 as with the case of the first embodiment. The gate terminal electrode 45 is arranged on the central portion of the first main surface 3 (the active surface 8), in this embodiment. That is, when the first straight line L1 (see two-dot chain line portion) crossing the central portion of the first main surface 3 in the first direction X and the second straight line L2 (see two-dot chain line portion) crossing the central portion of the first main surface 3 in the second direction Y are set, the gate terminal electrode 45 is arranged such as to overlap the intersecting portion Cr of the first straight line L1 and the second straight line L2.

In this embodiment, the semiconductor device 1J includes a plurality of the source terminal electrodes 55 that are arranged at an interval on the source electrode 32. The plurality of source terminal electrodes 55 are each arranged on the source electrode 32 at an interval from the plurality of gap portions 107A, 107B in plan view and oppose each other in the first direction X. In this embodiment, the plurality of source terminal electrodes 55 are arranged such as to expose the plurality of gap portions 107A, 107B.

In this embodiment, the plurality of source terminal electrodes 55 are each formed in a band shape (specifically, a curved C-letter shape along the gate terminal electrode 45) extending along the source electrode 32 in plan view. A planar shape of the plurality of source terminal electrodes 55 is arbitrary and may be formed in a quadrangle shape, a polygonal shape other than the quadrangle shape, a circular shape or an elliptical shape. The plurality of source terminal electrodes 55 may include a second protrusion portion 61 that is formed on the gap covering portions 110A, 110B on the upper insulating film 38.

The sealing insulator 71 aforementioned covers the plurality of gap portions 107A, 107B in regions between the plurality of source terminal electrodes 55. The sealing insulator 71 covers the plurality of gap covering portions 110A, 110B in regions between the plurality of the source terminal electrodes 55. That is, the sealing insulator 71 covers the plurality of gate wirings 36A, 36B across the plurality of gap covering portions 110A, 110B interposed therebetween.

An example in which the upper insulating film 38 has the gap covering portions 110A, 110B has been shown, in this embodiment. However, the presence or the absence of the plurality of gap covering portions 110A, 110B is arbitrary, and the upper insulating film 38 without the plurality of gap covering portions 110A, 110B may be formed. In this case, the plurality of source terminal electrodes 55 are arranged on the source electrode 32 such as to expose the plurality of gate wirings 36A, 36B.

The sealing insulator 71 directly covers the gate wirings 36A, 36B and electrically isolates the gate wirings 36A, 36B from the source electrode 32. The sealing insulator 71 directly covers a part of the interlayer insulating film 27 exposed from a region between the source electrode 32 and the gate wirings 36A, 36B in the plurality of gap covering portions 110A, 110B.

As described above, the same effects as those of the semiconductor device 1A are also achieved with the semiconductor device 1J. In the manufacturing method for the semiconductor device 1J, the wafer structure 80 in which structures corresponding to the semiconductor device 1J are formed in each device region 86 is prepared, and the similar steps to those of the manufacturing method for the semiconductor device 1A are performed. Therefore, the same effects as those of the manufacturing method for the semiconductor device 1A are also achieved with the manufacturing method for the semiconductor device 1J. The structure in which the gate electrode 30 and the gate terminal electrode 45 are arranged at the central portion of the chip 2 may be applied to the second to ninth embodiments.

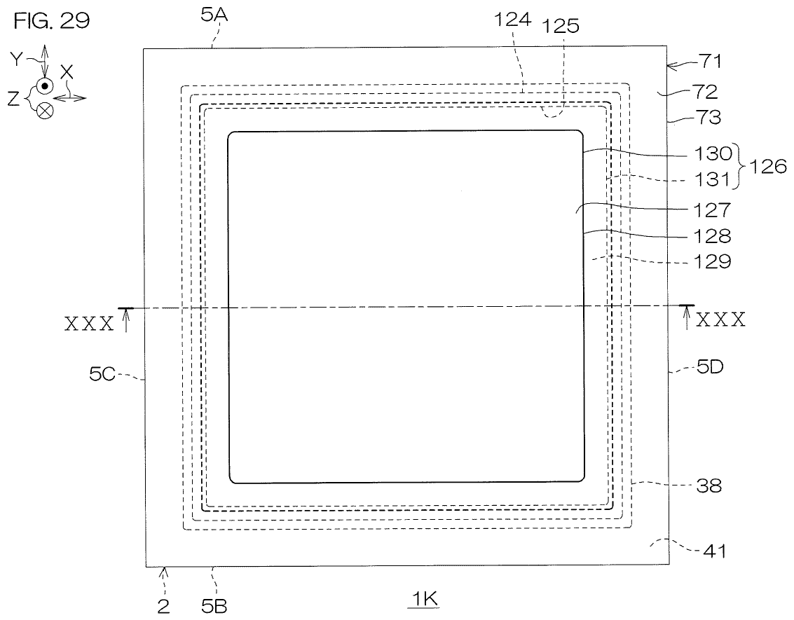

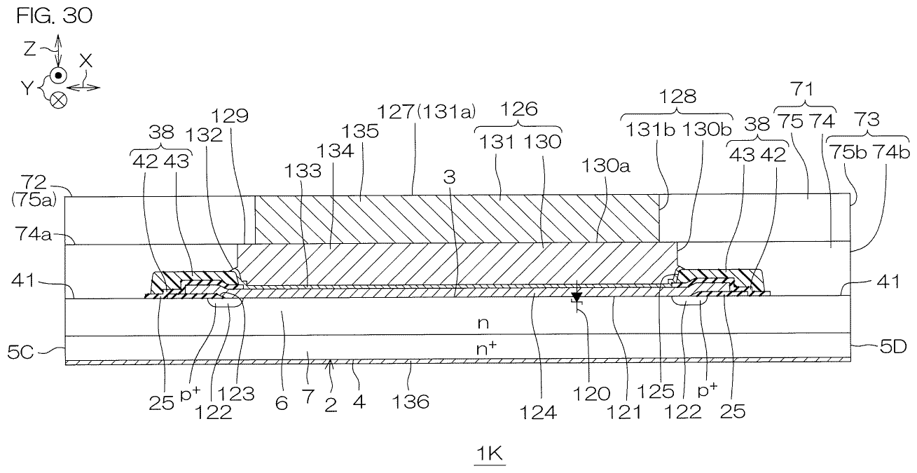

FIG. 29 is a plan view showing a semiconductor device 1K according to an eleventh embodiment. FIG. 30 is a cross sectional view taken along XXX-XXX line shown in FIG. 29. With reference to FIG. 29 and FIG. 30, the semiconductor device 1K includes the chip 2 aforementioned. The chip 2 is free from the mesa portion 11 in this embodiment and has the flat first main surface 3. The semiconductor device 1K has an SBD (Schottky Barrier Diode) structure 120 that is formed in the chip 2 as an example of a diode.

The semiconductor device 1K includes a diode region 121 of the n-type that is formed in an inner portion of the first main surface 3. The diode region 121 is formed by using a part of the first semiconductor region 6, in this embodiment.

The semiconductor device 1K includes a guard region 122 of the p-type that defines the diode region 121 from other region at the first main surface 3. The guard region 122 is formed in a surface layer portion of the first semiconductor region 6 at the interval from a peripheral edge of the first main surface 3. The guard region 122 is formed in an annular shape (in this embodiment, a quadrangle annular shape) surrounding the diode region 121 in plan view, in this embodiment. The guard region 122 has an inner end portion on the diode region 121 side and an outer end portion on the peripheral edge side of the first main surface 3.

The semiconductor device 1K includes the main surface insulating film 25 aforementioned that selectively covers the first main surface 3. The main surface insulating film 25 has a diode opening 123 that exposes the diode region 121 and the inner end portion of the guard region 122. The main surface insulating film 25 is formed at an interval inward from the peripheral edge of the first main surface 3 and exposes the first main surface 3 (the first semiconductor region 6) from the peripheral edge portion of the first main surface 3. As a matter of course, the main surface insulating film 25 may cover the peripheral edge portion of the first main surface 3. In this case, the peripheral edge portion of the main surface insulating film 25 may be continuous to the first to fourth side surfaces 5A to 5D.

The semiconductor device 1K includes a first polar electrode 124 (main surface electrode) that is arranged on the first main surface 3. The first polar electrode 124 is an “anode electrode”, in this embodiment. The first polar electrode 124 is arranged at an interval inward from the peripheral edge of the first main surface 3. The first polar electrode 124 is formed in a quadrangle shape along the peripheral edge of the first main surface 3 in plan view, in this embodiment. The first polar electrode 124 enters into the diode opening 123 from on the main surface insulating film 25, and is electrically connected to the first main surface 3 and the inner end portion of guard region 122.

The first polar electrode 124 forms a Schottky junction with the diode region 121 (the first semiconductor region 6). The SBD structure 120 is thereby formed. A planar area of the first polar electrode 124 is preferably not less than 50% of the first main surface 3. The planar area of the first polar electrode 124 is particularly preferably not less than 75% of the first main surface 3. The first polar electrode 124 may have a thickness of not less than 0.5 μm and not more than 15 μm.

The first polar electrode 124 may have a laminated structure that includes a Ti-based metal film and an Al-based metal film. The Ti-based metal film may have a single layered structure consisting of a Ti film or a TiN film. The Ti-based metal film may have a laminated structure that includes the Ti film and the TiN film laminated with an arbitrary order. The Al-based metal film is preferably thicker than the Ti-based metal film. The Al-based metal film may include at least one of a pure Al film (Al film with a purity of not less than 99%), an AlCu alloy film, an AlSi alloy film and an AlSiCu alloy film.

The semiconductor device 1K includes the upper insulating film 38 aforementioned that selectively covers the main surface insulating film 25 and the first polar electrode 124. The upper insulating film 38 has the laminated structure that includes the inorganic insulating film 42 and the organic insulating film 43 laminated in that order from the chip 2 side as with the case of the first embodiment. The upper insulating film 38 covers a peripheral edge portion of the first polar electrode 124 over an entire circumference and has a contact opening 125 exposing an inner portion of the first polar electrode 124 in plan view, in this embodiment. The contact opening 125 is formed in a quadrangle shape in plan view, in this embodiment.

The upper insulating film 38 is formed at an interval inward from the peripheral edge of the first main surface 3 (the first to fourth side surfaces 5A to 5D) and defines the dicing street 41 with the peripheral edge of the first main surface 3. The dicing street 41 is formed in a band shape extending along the peripheral edge of the first main surface 3 in plan view. The dicing street 41 is formed in an annular shape (specifically, a quadrangle annular shape) surrounding the inner portion of the first main surface 3 in plan view, in this embodiment.

The dicing street 41 exposes the first main surface 3 (the first semiconductor region 6), in this embodiment. As a matter of course, in a case in which the main surface insulating film 25 covers the peripheral edge portion of the first main surface 3, the dicing street 41 may expose the main surface insulating film 25. The upper insulating film 38 preferably has a thickness exceeding the thickness of the first polar electrode 124. The thickness of the upper insulating film 38 may be less than the thickness of the chip 2.

The semiconductor device 1K includes a terminal electrode 126 that is arranged on the first polar electrode 124. The terminal electrode 126 is erected in a columnar shape on a portion that is exposed from the contact opening 125 in the first polar electrode 124. The terminal electrode 126 has a ruggedness structure. Specifically, the terminal electrode 126 has a terminal surface 127 and a terminal side wall 128, and has a recessed portion 129 that is recessed toward the first polar electrode 124 from the terminal surface 127.

A site at which the recessed portion 129 is formed is arbitrary. In this embodiment, the recessed portion 129 is formed at a corner portion of the terminal surface 127 such as to be continuous to the terminal side wall 128. Thereby, the terminal side wall 128 has a step portion that is defined by the recessed portion 129. In this embodiment, the recessed portion 129 is formed in an annular shape extending along a peripheral edge of the terminal surface 127 such as to surround an inner portion of the terminal surface 127 in plan view.

The terminal electrode 126 preferably has a thickness exceeding the thickness of the first polar electrode 124. The thickness of the terminal electrode 126 particularly preferably exceeds the thickness of the upper insulating film 38. The thickness of the terminal electrode 126 exceeds the thickness of the chip 2, in this embodiment. As a matter of course, the thickness of the terminal electrode 126 may be less than the thickness of the chip 2. The thickness of the terminal electrode 126 may be not less than 10 μm and not more than 300 μm. The thickness of the terminal electrode 126 is preferably not less than 30 μm. The thickness of the terminal electrode 126 is particularly preferably not less than 80 μm and not more than 200 μm.

In this embodiment, the terminal electrode 126 has a laminated structure that includes a first terminal layer 130 (first layer portion) and a second terminal layer 131 (second layer portion). The first terminal layer 130 is arranged on the inner portion of the first polar electrode 124 at an interval from the peripheral edge of the first polar electrode 124. The first terminal layer 130 has a portion that is drawn out onto the upper insulating film 38 from on the first polar electrode 124 and positioned on the upper insulating film 38. That is, the first terminal layer 130 includes a portion in contact with the inorganic insulating film 42 and the organic insulating film 43. The first terminal layer 130 includes a portion that opposes the first polar electrode 124 across the upper insulating film 38.

The first terminal layer 130 has a first layer main surface 130a and a first layer side wall 130b. The first layer main surface 130a flatly extends along the first main surface 3. In this embodiment, the first layer main surface 130a consists of a ground surface with grinding marks. The first layer side wall 130b forms a part of the terminal side wall 128. In this embodiment, the first layer side wall 130b is positioned on the upper insulating film 38 (specifically, the organic insulating film 43). The first layer side wall 130b substantially perpendicularly extends in the normal direction Z. “Substantially perpendicularly” includes a mode that extends in a laminated direction while being curved (meandering). The first layer side wall 130b preferably consists of a flat surface without grinding marks.

In this embodiment, the first terminal layer 130 has a protrusion portion 132 that protrudes outside at a lower end portion of the first layer side wall 130b. The protrusion portion 132 is formed in a region further to the upper insulating film 38 (organic insulating film 43) side than an intermediate portion of the first layer side wall 130b. The protrusion portion 132 extends along an outer surface of the upper insulating film 38 and is formed in a tapered shape in which a thickness gradually decreases toward a tip portion from the first layer side wall 130b in cross sectional view. Thereby, the protrusion portion 132 has a sharp-shaped tip portion with an acute angle. As a matter of course, the first terminal layer 130 without the protrusion portion 132 may be formed.

The first terminal layer 130 has a first layer planar area and a first layer thickness. The first layer planar area is defined by a planar area of the first layer main surface 130a. The first layer thickness is defined by a distance between the first polar electrode 124 and the first layer main surface 130a. The first layer planar area is adjusted according to a planar area of the first main surface 3. The first layer planar area is preferably less than a planar area of the first polar electrode 124. The first layer planar area is preferably not less than 50% of the first main surface 3. The first layer planar area is particularly preferably not less than 75% of the first main surface 3.

In a case in which the first main surface 3 has a planar area that is not less than 1 mm square, the first layer planar area is preferably not less than 0.8 mm square. In this case, the first layer planar area is particularly preferably not less than 1 mm square. The first layer planar area may be formed in a polygonal shape having a planar area of not less than 1 mm×1.4 mm. In this embodiment, the first layer planar area is formed in a quadrangle shape parallel to first to fourth side surfaces 5A to 5D in plan view. As a matter of course, the first layer planar area may be formed in a polygonal shape other than the quadrangle shape, a circular shape or an elliptical shape in plan view.

The first layer thickness preferably exceeds the thickness of the first polar electrode 124. The first layer thickness particularly preferably exceeds the thickness of the upper insulating film 38. The first layer thickness may be not more than the thickness of the chip 2 or may exceed the thickness of the chip 2. The first layer thickness may be not less than ½ of a total thickness of the terminal electrode 126 or may be not more than ½ of the total thickness of the terminal electrode 126.

The terminal layer 130 has a laminated structure that includes a first conductor film 133 and a second conductor film 134 laminated in that order from the first polar electrode 124 side, in this embodiment. The first conductor film 133 may include a Ti-based metal film. The first conductor film 133 may have a single layered structure consisting of a Ti film or a TiN film.

The first conductor film 133 may have a laminated structure that includes the Ti film and the TiN film laminated with an arbitrary order. The first conductor film 133 has a thickness less than the thickness of the first polar electrode 124. The first conductor film 133 covers the first polar electrode 124 in a film shape inside the contact opening 125 and is drawn out onto the upper insulating film 38 in a film shape. The first conductor film 133 forms a part of the protrusion portion 132. The first conductor film 133 does not necessarily have to be formed and may be omitted.

The second conductor film 134 forms a body of the terminal layer 130. The second conductor film 134 may include a Cu-based metal film. The Cu-based metal film may be a pure Cu film (Cu film with a purity of not less than 99%) or Cu alloy film. The second conductor film 134 includes a pure Cu plating film, in this embodiment. The second conductor film 134 preferably has a thickness exceeding the thickness of the first polar electrode 124. The thickness of the second conductor film 134 particularly preferably exceeds the thickness of the upper insulating film 38. The thickness of the second conductor film 134 exceeds the thickness of the chip 2, in this embodiment.

The second conductor film 134 covers the first polar electrode 124 with the first conductor film 133 interposed therebetween inside the contact opening 125, and is drawn out onto the upper insulating film 38 with the first conductor film 133 interposed therebetween. The second conductor film 134 forms a part of the protrusion portion 132. That is, the protrusion portion 132 has a laminated structure that includes the first conductor film 133 and the second conductor film 134. The second conductor film 134 has a thickness exceeding a thickness of the first conductor film 133 in the protrusion portion 132.

The second terminal layer 131 protrudes toward the opposite side with respect to the chip 2 from the first terminal layer 130 such as to define the recessed portion 129 with the first terminal layer 130. That is, the second terminal layer 131 is arranged on the first layer main surface 130a such as to expose a part of the first layer main surface 130a. In this embodiment, the second terminal layer 131 includes a portion that is formed at an interval inward from a peripheral edge of the first terminal layer 130 such as to define the recessed portion 129 in a notched shape with a peripheral edge (first layer side wall 130b) of the first terminal layer 130.

In this embodiment, the second terminal layer 131 is arranged at an interval inward from an entire peripheral edge of the first terminal layer 130 and defines the recessed portion 129 that exposes a peripheral edge portion of the first layer main surface 130a over an entire circumference. That is, in this embodiment, the recessed portion 129 is formed in an annular shape that surrounds the second terminal layer 131 in plan view.

The second terminal layer 131 has a second layer main surface 131a and a second layer side wall 131b. The second layer main surface 131a is formed as the terminal surface 127. The second layer main surface 131a flatly extends along the first layer main surface 130a. In this embodiment, the second layer main surface 131a consists of a ground surface with grinding marks.

The second layer side wall 131b forms a part of the terminal side wall 128. The second layer side wall 131b is positioned on the first layer main surface 130a. In this embodiment, the second layer side wall 131b defines the recessed portion 129 that exposes the first layer main surface 130a with the first layer side wall 130b. That is, in this embodiment, the terminal side wall 128 is defined by the first layer main surface 130a, the first layer side wall 130b and the second layer side wall 131b. The second layer side wall 131b substantially perpendicularly extends in the normal direction Z. “Substantially perpendicularly” includes a mode that extends in a laminated direction while being curved (meandering). The second layer side wall 131b preferably consists of a flat surface without grinding marks.

The second layer side wall 131b is preferably formed at a portion that opposes the first polar electrode 124 across the first terminal layer 130. That is, the second terminal layer 131 preferably opposes only the first polar electrode 124 across the first terminal layer 130. As a matter of course, the second layer side wall 131b may be formed at a portion that opposes the upper insulating film 38 across the first terminal layer 130. That is, the second terminal layer 131 may have a portion that opposes the upper insulating film 38 across the first terminal layer 130.

The second terminal layer 131 has a second layer planar area and a second layer thickness. The second layer planar area is defined by a planar area of the second layer main surface 131a (terminal surface 127). The second layer thickness is defined by a distance between the first layer main surface 130a and the second layer main surface 131a. The second layer planar area is less than a first layer planar area of the first terminal layer 130 and adjusted according to the first layer planar area. The second layer planar area is preferably not less than 50% of the first main surface 3. The second layer planar area is particularly preferably not less than 75% of the first main surface 3.

In a case in which the first main surface 3 has a planar area of not less than 1 mm square, the second layer planar area is preferably not less than 0.8 mm square. In this case, the second layer planar area is particularly preferably not less than 1 mm square. The second terminal layer 131 may be formed in a polygonal shape having a planar area of not less than 1 mm×1.4 mm. In this embodiment, the second terminal layer 131 is formed in a quadrangle shape having four sides parallel to the first to fourth side surfaces 5A to 5D in plan view. As a matter of course, the second terminal layer 131 may be formed in a polygonal shape other than the quadrangle shape, a circular shape or an elliptical shape in plan view.

The second layer thickness preferably exceeds the thickness of the first polar electrode 124. The second layer thickness particularly preferably exceeds the thickness of the upper insulating film 38. The second layer thickness may be not more than the thickness of the chip 2 or may exceed the thickness of the chip 2. The second layer thickness may be not less than ½ of the total thickness of the terminal electrode 126 or may be not more than ½ of the total thickness of the terminal electrode 126.

The second layer thickness may be substantially equal to a first layer thickness of the first terminal layer 130, may be not less than the first layer thickness or may be less than the first layer thickness. The second layer thickness particularly preferably exceeds the first layer thickness. According to the second terminal layer 131 having the second layer thickness exceeding the first layer thickness, the recessed portion 129 having a depth exceeding the first layer thickness is defined.

In this embodiment, the second terminal layer 131 has a single layered structure consisting of a third conductor film 135 arranged on the first terminal layer 130. The third conductor film 135 (second terminal layer 131) may form a plurality of fine void spaces at a boundary portion with the second conductor film 134 (first terminal layer 130).

The third conductor film 135 may include a Cu-based metal film. The Cu-based metal film may be a pure Cu film (Cu film with a purity of not less than 99%) or a Cu alloy film. In this embodiment, the third conductor film 135 includes a pure Cu plating film. As a matter of course, as with the case of the first terminal layer 130, the second terminal layer 131 may have a laminated structure including a first conductor film 133 and a second conductor film 134 that are laminated in that order from the first terminal layer 130 side.

As described so far, the terminal electrode 126 has a ruggedness structure that includes the recessed portion 129. A volume of the terminal electrode 126 is reduced only by an extent of the recessed portion 129. A planar shape, an area, a depth, etc., of the recessed portion 129 are adjusted by adjusting a planar shape, an area and a thickness of the second terminal layer 131. The terminal electrode 126 is to be a connecting portion to which conducting wires (for example, a bonding wire and a conductor plate) and conductive adhesives (for example, a solder and a conductive paste), etc., are connected. Therefore, a mode of the second terminal layer 131 is adjusted as long as a connection area for conducting wires and conductive adhesives, etc., can be secured.

The semiconductor device 1K includes the aforementioned sealing insulator 71 that covers the first main surface 3. In this embodiment, the sealing insulator 71 covers a periphery of the terminal electrode 126 such as to expose a part of the terminal electrode 126 on the first main surface 3. Specifically, the sealing insulator 71 covers the first terminal layer 130 and the second terminal layer 131 such as to expose a part of the second terminal layer 131. More specifically, the sealing insulator 71 covers the first layer side wall 130b and the second layer side wall 131b such as to expose the second layer main surface 131a.

The sealing insulator 71 includes a portion that is positioned inside the recessed portion 129. In this embodiment, the sealing insulator 71 includes a portion that surrounds the second terminal layer 131 on the first terminal layer 130 in plan view. The sealing insulator 71 covers the first terminal layer 130 and the second terminal layer 131 inside the recessed portion 129.

Specifically, the sealing insulator 71 covers the first layer main surface 130a and the second layer side wall 131b inside the recessed portion 129. In this embodiment, the sealing insulator 71 has a portion that covers the protrusion portion 132 of the first terminal layer 130 and opposes the upper insulating film 38 across the protrusion portion 132. The sealing insulator 71 has a portion that directly covers the upper insulating film 38 in a region outside the terminal electrode 126.

The sealing insulator 71 covers the dicing street 41 defined by the upper insulating film 38 at the peripheral edge portion of the first main surface 3. The sealing insulator 71 directly covers the first main surface 3 (the first semiconductor region 6) at the dicing street 41, in this embodiment. As a matter of course, in a case in which the main surface insulating film 25 is exposed from the dicing street 41, the sealing insulator 71 may directly cover the main surface insulating film 25 at the dicing street 41.

The sealing insulator 71 has the insulating main surface 72 and the insulating side wall 73 as with the case of the first embodiment. The insulating main surface 72 forms a single flat surface (in this embodiment, a ground surface) with the second layer main surface 131a. Also, the insulating side wall 73 extends toward the chip 2 from the peripheral edge of the insulating main surface 72 and forms a single flat surface (in this embodiment, a ground surface) with the first to fourth side surfaces 5A to 5D.

The sealing insulator 71 preferably has a thickness exceeding the thickness of the first polar electrode 124. The thickness of the sealing insulator 71 particularly preferably exceeds the thickness of the upper insulating film 38. The thickness of the sealing insulator 71 exceeds the thickness of the chip 2, in this embodiment. As a matter of course, the thickness of the sealing insulator 71 may be less than the thickness of the chip 2. The thickness of the sealing insulator 71 may be not less than 10 μm and not more than 300 μm. The thickness of the sealing insulator 71 is preferably not less than 30 μm. The thickness of the sealing insulator 71 is particularly preferably not less than 80 μm and not more than 200 μm.

In this embodiment, the sealing insulator 71 has the laminated structure that includes the first sealing insulator 74 and the second sealing insulator 75. The first sealing insulator 74 covers a periphery of the first terminal layer 130 on the first main surface 3 such as to expose the second terminal layer 131. Specifically, the first sealing insulator 74 covers the first layer side wall 130b such as to expose the first layer main surface 130a. The first sealing insulator 74 has a portion that covers the protrusion portion 132 of the first terminal layer 130.

The first sealing insulator 74 has a portion that directly covers the upper insulating film 38 in a region outside the terminal electrode 126. The first sealing insulator 74 also covers the dicing street 41 at the peripheral edge portion of the outer surface 9. In this embodiment, the first sealing insulator 74 directly covers the first main surface 3 at the dicing street 41.

The first sealing insulator 74 has the first insulating main surface 74a and the first insulating side wall 74b. The first insulating side wall 74b forms a part of the insulating side wall 73. The first insulating main surface 74a flatly extends along the first main surface 3 and forms a single flat surface (a ground surface in this embodiment) with the first layer main surface 130a. The first insulating side wall 74b extends toward the chip 2 from a peripheral edge of the first insulating main surface 74a and forms a single flat surface (a ground surface in this embodiment) with the first to fourth side surfaces 5A to 5D.

The first sealing insulator 74 preferably has a thickness exceeding the thickness of the first polar electrode 124. The thickness of the first sealing insulator 74 particularly preferably exceeds the thickness of the upper insulating film 38. The thickness of the first sealing insulator 74 may be not more than the thickness of the chip 2 or may exceed the thickness of the chip 2. The thickness of the first sealing insulator 74 may be not less than ½ of a total thickness of the sealing insulator 71 or may be not more than ½ of the total thickness of the sealing insulator 71. The thickness of the first sealing insulator 74 is substantially equal to the first layer thickness of the first terminal layer 130.

The second sealing insulator 75 covers a periphery of the second terminal layer 131 on the first sealing insulator 74 such as to expose the second layer main surface 131a and cover the second layer side wall 131b. The second sealing insulator 75 includes a portion that is positioned inside the recessed portion 129. In this embodiment, the second sealing insulator 75 enters into the recessed portion 129 from on the first sealing insulator 74. The second sealing insulator 75 covers the first layer main surface 130a and the second layer side wall 131b inside the recessed portion 129. That is, in this embodiment, the second sealing insulator 75 includes a portion that surrounds the second terminal layer 131 on the first terminal layer 130 in plan view.

The second sealing insulator 75 has the second insulating main surface 75a and the second insulating side wall 75b. The second insulating main surface 75a forms the insulating main surface 72, and the second insulating side wall 75b forms a part of the insulating side wall 73. The second insulating main surface 75a flatly extends along the first insulating main surface 74a and forms a single flat surface (a ground surface in this embodiment) with the second layer main surface 131a. The second insulating side wall 75b extends from a peripheral edge of the second insulating main surface 75a toward the chip 2 and forms a single flat surface (a ground surface in this embodiment) with the first insulating side wall 74b of the first sealing insulator 74.

The second sealing insulator 75 preferably has a thickness exceeding the thickness of the first polar electrode 124. The thickness of the second sealing insulator 75 particularly preferably exceeds the thickness of the upper insulating film 38. The thickness of the second sealing insulator 75 may be not more than the thickness of the chip 2 or may exceed the thickness of the chip 2. The thickness of the second sealing insulator 75 may be not less than ½ of the total thickness of the sealing insulator 71 or may be not more than ½ of the total thickness of the sealing insulator 71. The thickness of the second sealing insulator 75 is substantially equal to the second layer thickness of the second terminal layer 131.

The semiconductor device 1K includes a second polar electrode 136 (second main surface electrode) that covers the second main surface 4. The second polar electrode 136 is a “cathode electrode”, in this embodiment. The second polar electrode 136 is electrically connected to the second main surface 4. The second polar electrode 136 forms an ohmic contact with the second semiconductor region 7 exposed from the second main surface 4. The second polar electrode 136 may cover a whole region of the second main surface 4 such as to be continuous with the peripheral edge of the chip 2 (the first to fourth side surfaces 5A to 5D).

The second polar electrode 136 may cover the second main surface 4 at an interval from the peripheral edge of the chip 2. The second polar electrode 136 is configured such that a voltage of not less than 500 V and not more than 3000 V is to be applied between the terminal electrode 126 and second polar electrode 136. That is, the chip 2 is formed such that the voltage of not less than 500 V and not more than 3000 V is to be applied between the first main surface 3 and the second main surface 4.

As described above, the semiconductor device 1K includes the chip 2, the first polar electrode 124 (main surface electrode), the terminal electrode 126 and the sealing insulator 71. The chip 2 has the first main surface 3. The first polar electrode 124 is arranged on the first main surface 3. The terminal electrode 126 is arranged on the first polar electrode 124 and has the terminal surface 127 and the terminal side wall 128. The terminal electrode 126 has the recessed portion 129 that is recessed toward the first polar electrode 124 side in the terminal surface 127. The sealing insulator 71 covers a periphery of the terminal electrode 126 such as to expose the terminal surface 127 and cover the terminal side wall 128.

According to this structure, a volume of the terminal electrode 126 is reduced by the recessed portion 129, and a stress due to the terminal electrode 126 is decreased. Thereby, it is possible to suppress a failure in formation of the chip 2 and a change in electrical characteristics due to a stress of the terminal electrode 126. Further, according to this structure, it is possible to protect an object to be sealed from an external force or humidity by the sealing insulator 71. That is, it is possible to protect an object to be sealed from damage due to an external force and deterioration due to humidity. It is, thereby, possible to suppress a failure in formation and a change in electrical characteristics. Thus, it is possible to provide the semiconductor device 1K capable of improving the reliability.

As described above, the same effects as those of the semiconductor device 1A can be achieved with the semiconductor device 1K. In the manufacturing method for the semiconductor device 1K, the wafer structure 80 in which structures corresponding to the semiconductor device 1K are formed in each device region 86 is prepared, and the similar steps to those of the manufacturing method for the semiconductor device 1A are performed. Therefore, the same effects as those of the manufacturing method for the semiconductor device 1A are also achieved with the manufacturing method for the semiconductor device 1K.

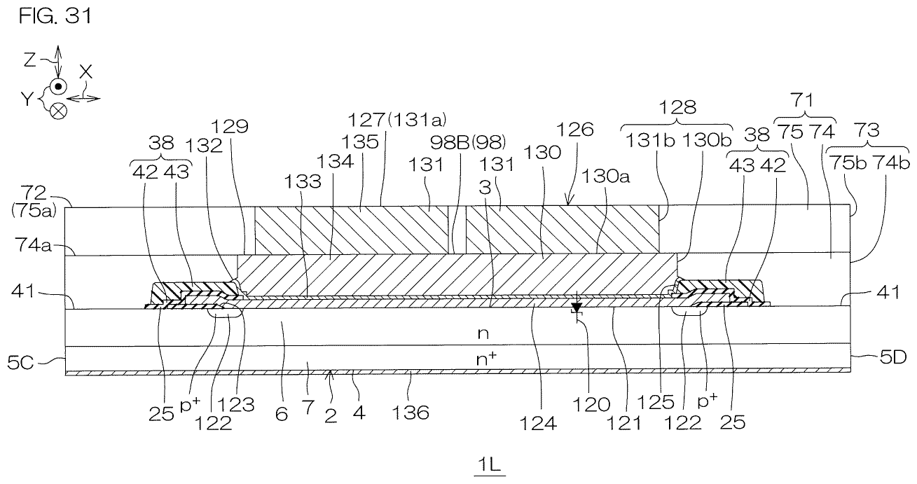

FIG. 31 is a cross sectional view that shows a semiconductor device 1L according to a twelfth embodiment. With reference to FIG. 31, the semiconductor device 1K has a mode in which technical ideas of the semiconductor device 1B (refer to FIG. 14 and FIG. 15) according to the second embodiment are combined with the semiconductor device 1K. That is, the semiconductor device 1L includes the terminal electrode 126 that includes the inward recessed portion 98 (first to second inward recessed portions 98A to 98B) that is recessed toward the first polar electrode 124 from the terminal surface 127 at an inner portion of the terminal surface 127.

The inward recessed portion 98 will be described with reference to a description of the inward recessed portion 98 according to the semiconductor device 1B and, therefore, the description thereof will be omitted. As described above, the same effects as those of the semiconductor device 1K (semiconductor device 1B) are also achieved by the semiconductor device 1L.

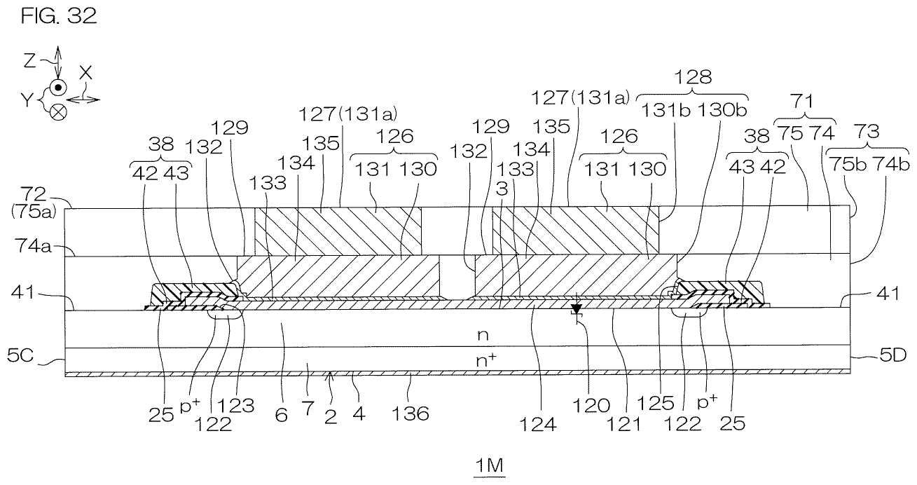

FIG. 32 is a cross sectional view that shows a semiconductor device 1M according to a thirteenth embodiment. With reference to FIG. 32, the semiconductor device 1M has a mode in which technical ideas of the semiconductor device 1C (refer to FIG. 16 and FIG. 17) according to the third embodiment are combined with the semiconductor device 1K. That is, the semiconductor device 1M includes a plurality of the terminal electrodes 126 arranged on the first polar electrode 124.

The plurality of terminal electrodes 126 and the sealing insulator 71 according to the semiconductor device 1M are formed in the same mode as those of the plurality of source terminal electrodes 55 and the sealing insulator 71 according to the semiconductor device 1C. The plurality of terminal electrodes 126 and the sealing insulator 71 will be described with reference to a description of the plurality of source terminal electrodes 55 and the sealing insulator 71 according to the semiconductor device 1C and, therefore, the description thereof will be omitted. As described above, the same effects as those of the semiconductor device 1K (semiconductor device 1C) are also achieved by the semiconductor device 1M.

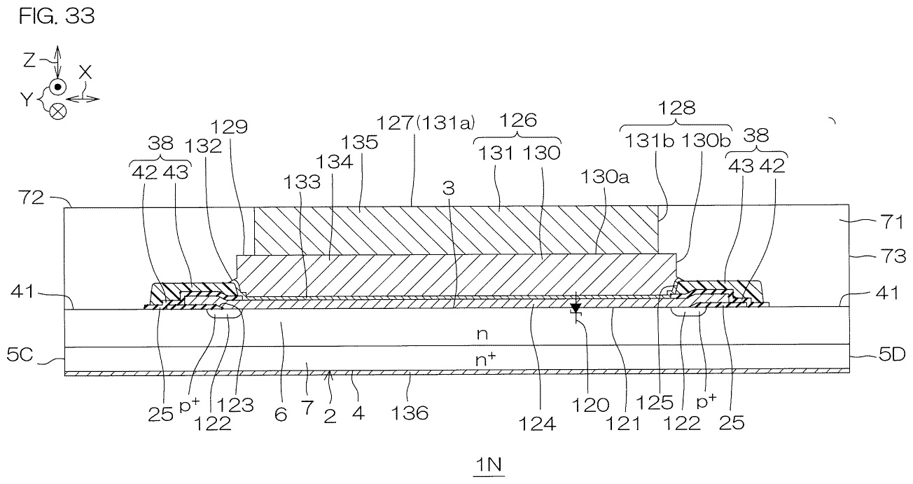

FIG. 33 is a cross sectional view that shows a semiconductor device 1N according to a fourteenth embodiment. With reference to FIG. 33, the semiconductor device 1N has a mode in which technical ideas of the semiconductor device 1D according to the fourth embodiment (refer to FIG. 18) are combined with the semiconductor device 1K. That is, the semiconductor device 1N includes the first terminal layer 130 having the first layer main surface 130a that consists of a flat surface without grinding marks and the sealing insulator 71 that consists of a single layered structure.

The sealing insulator 71 according to the semiconductor device 1N covers the terminal electrode 126 having the recessed portion 129 in the same mode as that of the sealing insulator 71 according to the semiconductor device 1K except that it does not include the first sealing insulator 74 and the second sealing insulator 75. As described above, the same effects as those of the semiconductor device 1K are also achieved by the semiconductor device 1N.

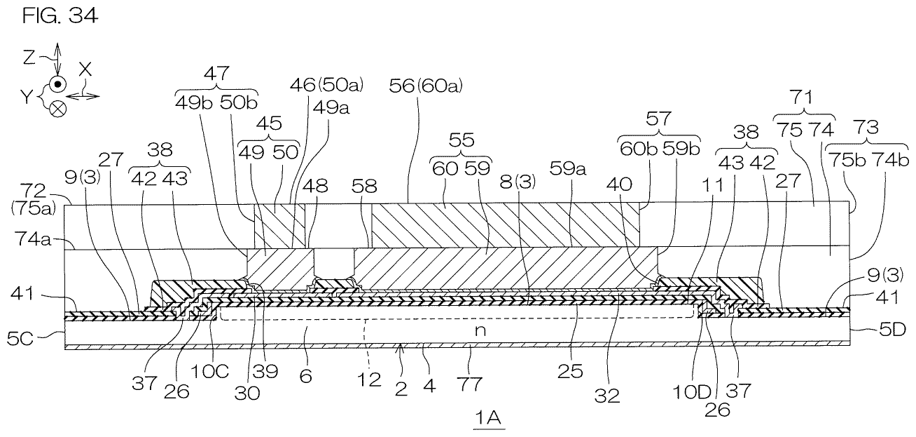

Hereinafter, modified examples to be applied to each embodiment shall be shown. FIG. 34 is a cross sectional view showing a modified example of the chip 2 to be applied to each of the embodiments. In FIG. 34, an example in which the chip 2 according to the modified example is applied to the semiconductor device 1A. However, the chip 2 according to the modified example may be applied to any one of the second to fourteenth embodiments.

With reference to FIG. 34, the semiconductor device 1A does not have the second semiconductor region 7 inside the chip 2 and may only have the first semiconductor region 6 inside the chip 2. In this case, the first semiconductor region 6 is exposed from the first main surface 3, the second main surface 4 and the first to fourth side surfaces 5A to 5D of the chip 2. That is, the chip 2 has a single layered structure that does not have the semiconductor substrate and that consists of the epitaxial layer, in this embodiment. The chip 2 having such a structure is formed by fully removing the second semiconductor region 7 (the semiconductor substrate) in the step shown in FIG. 13M aforementioned.

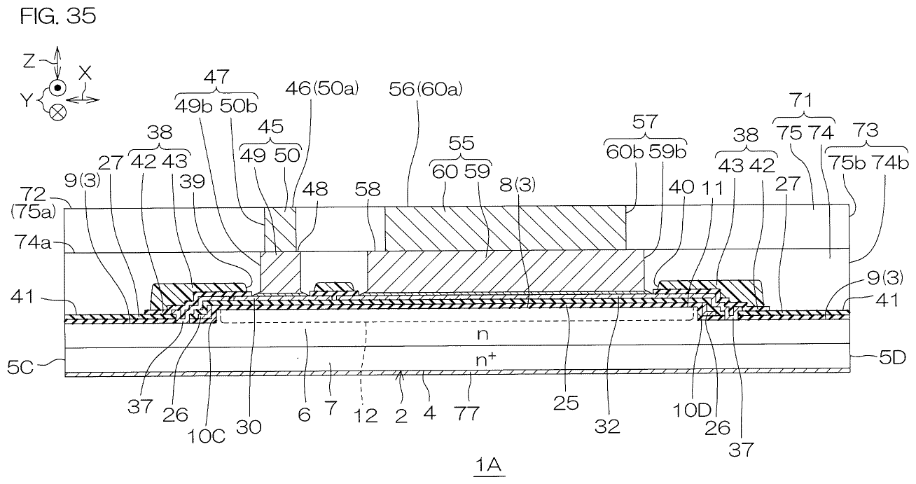

FIG. 35 is a cross sectional view showing a modified example of the sealing insulator 71 to be applied to each of the embodiments. In FIG. 35, an example in which the sealing insulator 71 according to the modified example is applied to the semiconductor device 1A. However, the sealing insulator 71 according to the modified example may be applied to any one of the second to fourteenth embodiments. With reference to FIG. 35, the semiconductor device 1A includes the sealing insulator 71 that covers a whole area of the upper insulating film 38.

In this case, in the first to tenth embodiments, the gate terminal electrode 45 that is not in contact with the upper insulating film 38 and the source terminal electrode 55 that is not in contact with the upper insulating film 38 are formed. In this case, the sealing insulator 71 may have portions that directly cover the gate electrode 30 and the source electrode 32. On the other hand, in the eleventh to fourteenth embodiments, the terminal electrode 126 that is not in contact with the upper insulating film 38 is formed. In this case, the sealing insulator 71 may have a portion that directly covers the first polar electrode 124.

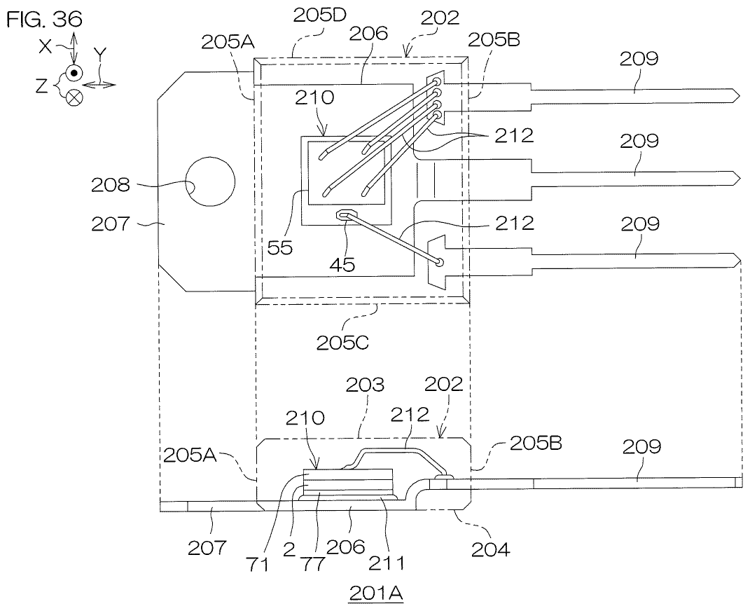

Hereinafter, configuration examples of packages to which any one of or plurality of the semiconductor devices 1A to 1N according to the first to fourteenth embodiments are to be incorporated shall be shown. FIG. 36 is a plan view showing a package 201A to which any one of the semiconductor devices 1A to 1K according to the first to eleventh embodiments is to be incorporated. The package 201A may be referred to as a “semiconductor package” or a “semiconductor module”.

With reference to FIG. 36, the package 201A includes a package body 202 of a rectangular parallelepiped shape. The package body 202 consists of a mold resin, and includes a matrix resin (for example, epoxy resin), a plurality of fillers and a plurality of flexible particles (flexible agent) as with the sealing insulator 71. The package body 202 has a first surface 203 on one side, the second surface 204 on the other side, and first to fourth side walls 205A to 205D connecting the first surface 203 and the second surface 204.

The first surface 203 and the second surface 204 are each formed in a quadrangle shape in plan view as viewed from their normal direction Z. The first side wall 205A and the second side wall 205B extend in the first direction X and oppose in the second direction Y orthogonal to the first direction X. The third side wall 205C and the fourth side wall 205D extend in the second direction Y and oppose in the first direction X.

The package 201A includes a metal plate 206 (conductor plate) that is arranged inside the package body 202. The metal plate 206 may be referred to as a “die pad”. The metal plate 206 is formed in a quadrangle shape (specifically, rectangular shape) in plan view. The metal plate 206 includes a drawer board part 207 that is drawn out from the first side wall 205A to an outside of the package body 202. The drawer board part 207 has a through hole 208 of a circular shape. The metal plate 206 may be exposed from the second surface 204.

The package 201A includes a plurality of (in this embodiment, three) lead terminals 209 that are pulled out from an inside of the package body 202 to the outside of the package body 202. The plurality of lead terminals 209 are arranged on the second side wall 205B side. The plurality of lead terminals 209 are each formed in a band shape extending in an orthogonal direction to the second side wall 205B (that is, the second direction Y). The lead terminals 209 on both sides of the plurality of lead terminals 209 are arranged at intervals from the metal plate 206, and the lead terminals 209 on a center is integrally formed with the metal plate 206. A position of the lead terminal 209 that is to be connected to the metal plate 206 is arbitrary.

The package 201A includes a semiconductor device 210 that is arranged on the metal plate 206 inside the package body 202. The semiconductor device 210 consists of any one of the semiconductor devices 1A to 1K according to the first to eleventh embodiments. The semiconductor device 210 is arranged on the metal plate 206 in a posture with the drain electrode 77 opposing the metal plate 206, and is electrically connected to the metal plate 206.

The package 201A includes a conductive adhesive 211 that is interposed between the drain electrode 77 and the metal plate 206 and that connects the semiconductor device 210 to the metal plate 206. The conductive adhesive 211 may include a solder or a metal paste. The solder may be a lead-free solder. The metal paste may include at least one of Au, Ag and Cu. The Ag paste may consist of an Ag sintered paste. The Ag sintered paste consists of a paste in which Ag particles of nano size or micro size are added into an organic solvent.

The package 201A includes at least one (in this embodiment, a plurality of) conducting wires 212 (conductive connection member) that are electrically connected to the lead terminals 209 and the semiconductor device 210 inside the package body 202. The conducting wires 212 each consists of a metal wire (that is, bonding wire), in this embodiment. The conducting wires 212 may include at least one of a gold wire, a copper wire and an aluminum wire. As a matter of course, the conducting wires 212 may each consist of a metal plate such as a metal clip, instead of the metal wire.

At least one (in this embodiment, one) conducting wire 212 is electrically connected to the gate terminal electrode 45 and the lead terminal 209. At least one (in this embodiment, four) conducting wires 212 are electrically connected to the source terminal electrode 55 and the lead terminal 209. In a case in which the source terminal electrode 55 includes the sense terminal layer 104 (see FIG. 21), the lead terminals 209 corresponding to the sense terminal layer 104, and the conducting wire 212 to be connected to the sense terminal layer 104 and the lead terminals 209 may be provided.

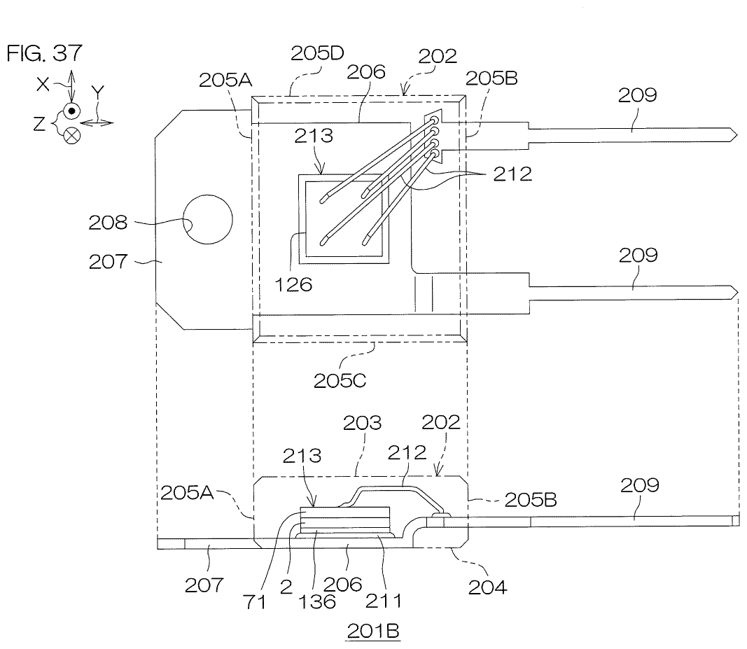

FIG. 37 is a plan view showing a package 201B to which any one of the semiconductor devices 1L to 1N according to the twelfth to fourteenth embodiments is to be incorporated. The package 201B may be referred to as a “semiconductor package” or a “semiconductor module”. With reference to FIG. 37, the package 201B includes the package body 202, the metal plate 206, the plurality (in this embodiment, two) lead terminals 209, a semiconductor device 213, the conductive adhesive 211, and the plurality conducting wires 212. Hereinafter, points different from those of the package 201A shall be described.

One lead terminal 209 of the plurality of lead terminals 209 is arranged at an interval from the metal plate 206, and the other lead terminals 209 is integrally formed with the metal plate 206. The semiconductor device 213 is arranged on the metal plate 206 inside the package body 202. The semiconductor device 213 consists of any one of the semiconductor devices 1L to 1N according to the twelfth to fourteenth embodiments. The semiconductor device 213 is arranged on the metal plate 206 in a posture with the second polar electrode 136 opposing to the metal plate 206, and is electrically connected to the metal plate 206.

The conductive adhesive 211 is interposed between the second polar electrode 136 and the metal plate 206 and connects the semiconductor device 213 to the metal plate 206. At least one (in this embodiment, four) conducting wires 212 are electrically connected to the terminal electrode 126 and the lead terminal 209.

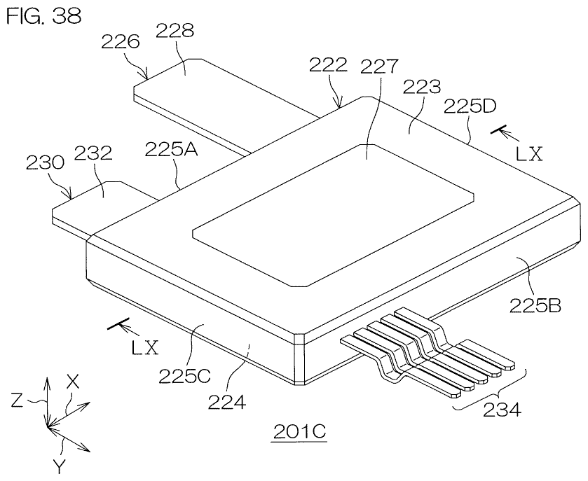

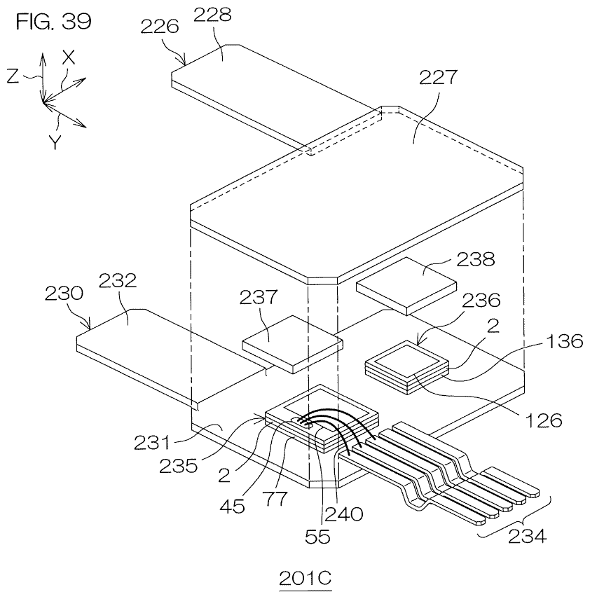

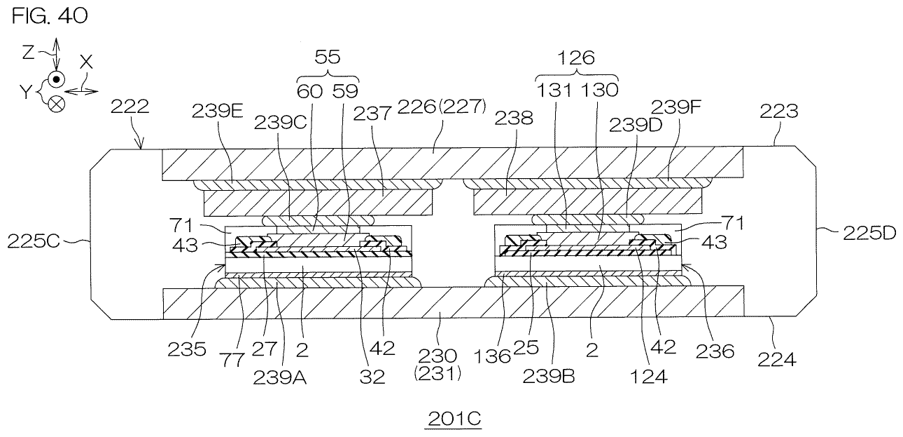

FIG. 38 is a perspective view showing a package to which any one of the semiconductor devices 1A to 1K according to the first to eleventh embodiments and any one of the semiconductor devices 1L to 1N according to the twelfth to fourteenth embodiments are to be incorporated. FIG. 39 is an exploded perspective view of the package 201C shown in FIG. 38. FIG. 40 is a cross sectional view taken along LX-LX line shown in FIG. 38. The package 201C may be referred to as a “semiconductor package” or a “semiconductor module”.

With reference to FIG. 38 to FIG. 40, the package 201C includes a package body 222 of a rectangular parallelepiped shape. The package body 222 consists of a mold resin and includes a matrix resin (for example, epoxy resin), a plurality of fillers and a plurality of flexible particles (flexible agent) as with the sealing insulator 71. The package body 222 has a first surface 223 on one side, the second surface 224 on the other side, and first to fourth side walls 225A to 225D connecting the first surface 223 and the second surface 224.

The first surface 223 and the second surface 224 each formed in a quadrangle shape (in this embodiment, rectangular shape) in plan view as viewed from their normal direction Z. The first side wall 225A and the second side wall 225B extend in the first direction X along the first surface 223 and oppose in the second direction Y. The first side wall 225A and the second side wall 225B each forms a long side of the package body 222. The third side wall 225C and the fourth side wall 225D extend in the second direction Y and oppose in the first direction X. The third side wall 225C and the fourth side wall 225D each forms a short side of the package body 222.

The package 201C includes a first metal plate 226 that is arranged inside and outside the package body 222. The first metal plate 226 is arranged on the first surface 223 side of the first surface 223 and includes a first pad portion 227 and a first lead terminal 228. The first pad portion 227 is formed in a rectangular shape extending in the first direction X inside the package body 222 and exposes the first surface 223.

The first lead terminal 228 is pulled out from the first pad portion 227 toward the first side wall 225A in a band shape extending in the second direction Y, and penetrates the first side wall 225A to be exposed from the package body 222. The first lead terminal 228 is arranged on the fourth side wall 225D side in plan view. The first lead terminal 228 is exposed from the first side wall 225A at a position at intervals from the first surface 223 and the second surface 224.

The package 201C includes a second metal plate 230 that is arranged inside and outside the package body 222. The second metal plate 230 is arranged on the second surface 224 side of the package body 222 at an interval from the first metal plate 226 in the normal direction Z and includes a second pad portion 231 and a second lead terminal 232. The second pad portion 231 is formed in a rectangular shape extending in the first direction X inside the package body 222 and exposes from the second surface 224.

The second lead terminal 232 is pulled out from the second pad portion 231 to the first side wall 225A in a band shape extending in the second direction Y, and penetrates the first side wall 225A to be exposed from the package body 222. The second lead terminal 232 arranged on the third side wall 225C side in plan view. The second lead terminal 232 is exposed from the first side wall 225A at a position at intervals from the first surface 223 and the second surface 224.

The second lead terminal 232 is pulled out at a thickness position different from a thickness position of the first lead terminal 228, in regard to the normal direction Z. The second lead terminal 232 is formed at an interval from the first lead terminal 228 to the second surface 224 side, and does not oppose the first lead terminal 228 in the first direction X, in this embodiment. The second lead terminal 232 has a length different from a length of the first lead terminal 228, in regard to the second direction Y.

The package 201C includes a plurality of (in this embodiment, five) third lead terminals 234 that are pulled out from inside of the package body 222 to outside of the package body 222. The plurality of third lead terminals 234 are arranged in a thickness range between the first pad portion 227 and the second pad portion 231, in this embodiment. The plurality of third lead terminals 234 are each pulled out from inside of the package body 222 toward the second side wall 225B in a band shape extending in the second direction Y, and penetrate the second side wall 225B to be exposed from the package body 222.

An arrangement of the plurality of third lead terminals 234 is arbitrary. The plurality of third lead terminals 234 are arranged on the third side wall 225C side such as to locate on the same straight line with the second lead terminal 232, in plan view, in this embodiment. The plurality of third lead terminals 234 may each have a curved section bent toward the first surface 223 and/or the second surface 224 in a portion located outside the package body 222.

The package 201C includes a first semiconductor device 235 that is arranged inside the package body 222. The first semiconductor device 235 consists of any one of the semiconductor devices 1A to 1K according to the first to eleventh embodiments. The first semiconductor device 235 is arranged between the first pad portion 227 and the second pad portion 231. The first semiconductor device 235 is arranged on the third side wall 225C side in plan view. The first semiconductor device 235 is arranged on the second metal plate 230 in a posture with the drain electrode 77 opposing to the second metal plate 230 (the second pad portion 231), and is electrically connected to the second metal plate 230.

The package 201C includes a second semiconductor device 236 that is arranged inside the package body 222 at an interval from the first semiconductor device 235. The second semiconductor device 236 consists of any one of the semiconductor devices 1L to 1N according to the twelfth to fourteenth embodiments. The second semiconductor device 236 is arranged between the first pad portion 227 and the second pad portion 231. The second semiconductor device 236 is arranged on the fourth side wall 225D side in plan view. The second semiconductor device 236 is arranged on the second metal plate 230 in a posture with the second polar electrode 136 opposing to the second metal plate 230 (the second pad portion 231), and is electrically connected to the second metal plate 230.

The package 201C includes a first conductor spacer 237 (first conductive connection member) and a second conductor spacer 238 (second conductive connection member) that are each arranged inside the package body 222. The first conductor spacer 237 is interposed between the first semiconductor device 235 and the first pad portion 227 and is electrically connected to the first semiconductor device 235 and the first pad portion 227. The second conductor spacer 238 is interposed between the second semiconductor device 236 and the first pad portion 227 and is electrically connected to the second semiconductor device 236 and the first pad portion 227.

The first conductor spacer 237 and the second conductor spacer 238 may each include a metal plate (for example, Cu-based metal plate). The second conductor spacer 238 consists of a separated member from the first conductor spacer 237 in this embodiment, but the second conductor spacer 238 may be integrally formed with the first conductor spacer 237.

The package 201C includes first to sixth conductive adhesives 239A to 239F. The first to sixth conductive adhesives 239A to 239F may each include a solder or a metal past. The solder may be a lead-free solder. The metal paste may include at least one of Au, Ag and Cu. The Ag paste may consist of an Ag sintered paste. The Ag sintered paste consists of a paste in which Ag particles of nano size or micro size are added into an organic solvent.

The first conductive adhesive 239A is interposed between the drain electrode 77 and the second pad portion 231, and connects the first semiconductor device 235 to the second pad portion 231. The second conductive adhesive 239B is interposed between the second polar electrode 136 and the second pad portion 231, and connects the second semiconductor device 236 to the second pad portion 231.

The third conductive adhesive 239C is interposed between the source terminal electrode 55 and the first conductor spacer 237, and connects the first conductor spacer 237 to the source terminal electrode 55. The fourth conductive adhesive 239D is interposed between the terminal electrode 126 and the second conductor spacer 238, and connects the second conductor spacer 238 to the terminal electrode 126.

The fifth conductive adhesive 239E is interposed between the first pad portion 227 and the first conductor spacer 237, and connects the first conductor spacer 237 to the first pad portion 227. The sixth conductive adhesive 239F is interposed between the first pad portion 227 and the second conductor spacer 238, and connects the second conductor spacer 238 to the first pad portion 227.

The package 201C includes at least one (in this embodiment, a plurality of) conducting wires 240 (conductive connection member) that are electrically connected to the gate terminal electrode 45 of the first semiconductor device 235 and at least one (in this embodiment, a plurality of) third lead terminals 234 inside the package body 222. The conducting wires 240 each consists of a metal wire (that is, bonding wire), in this embodiment.

The conducting wires 240 may include at least one of a gold wire, a copper wire and an aluminum wire. As a matter of course, the conducting wires 240 may each consist of a metal plate such as a metal clip, instead of the metal wire. In a case in which the source terminal electrode 55 includes the sense terminal layer 104 (see FIG. 21), a conducting wire 240 to be connected to the sense terminal layer 104 and the third lead terminal 234 may be further provide.

An example in which the source terminal electrode 55 is connected to the first pad portion 227 via the first conductor spacer 237 has been shown, in this embodiment. However, the source terminal electrode 55 may be connected the first pad portion 227 by the third conductive adhesive 239C without using the first conductor spacer 237. Also, an example in which the terminal electrode 126 is connected to the first pad portion 227 via the second conductor spacer 238 has been shown, in this embodiment. However, the terminal electrode 126 may be connected the first pad portion 227 by the fourth conductive adhesive 239D without using the second conductor spacer 238.

Each of the above embodiments can be implemented in yet other embodiments. For example, features disclosed in the first to fourteenth embodiments aforementioned can be appropriately combined therebetween. That is, a configuration that includes at least two features among the features disclosed in the first to fourteenth embodiments aforementioned at the same time may be adopted.

In each of the above embodiments, the gate terminal electrode 45 having the gate recessed portion 48 and the source terminal electrode 55 having the source recessed portion 58 have been shown. However, while the gate terminal electrode 45 that has no gate recessed portion 48 is formed, the source terminal electrode 55 having the source recessed portion 58 may be formed.

Further, while the gate terminal electrode 45 having the gate recessed portion 48 is formed, the source terminal electrode 55 that has no source recessed portion 58 may be formed. However, in a case in which a planar area of the source terminal electrode 55 exceeds a planar area of the gate terminal electrode 45, it is preferable that the source terminal electrode 55 having the source recessed portion 58 is formed.

In each of the above embodiments, the chip 2 having the mesa portion 11 has been shown. However, the chip 2 that does not have the mesa portion 11 and has the first main surface 3 extending in a flat may be adopted. In this case, the side wall structure 26 may be omitted.

In each of the above embodiments, the configurations that has the source wiring 37 have been shown. However, configurations without the source wiring 37 may be adopted. In each of the above embodiments, the gate structure 15 of the trench gate type that controls the channel inside the chip 2 has been shown. However, the gate structure 15 of a planar gate type that controls the channel from on the first main surface 3 may be adopted.

In each of the above embodiments, the configurations in which the MISFET structure 12 and the SBD structure 120 are formed in the different chips 2 have been shown. However, the MISFET structure 12 and the SBD structure 120 may be formed in different regions of the first main surface 3 in the same chip 2. In this case, the SBD structure 120 may be formed as a reflux diode of the MISFET structure 12.

In each of the embodiments, the configuration in which the “first conductive type” is the “n-type” and the “second conductive type” is the “p-type” has been shown. However, in each of the embodiments, a configuration in which the “first conductive type” is the “p-type” and the “second conductive type” is the “n-type” may be adopted. The specific configuration in this case can be obtained by replacing the “n-type” with the “p-type” and at the same time replacing the “p-type” with the “n-type” in the above descriptions and attached drawings.

In each of the embodiments, the second semiconductor region 7 of the “n-type” has been shown. However, the second semiconductor region 7 may be the “p-type”. In this case, an IGBT (Insulated Gate Bipolar Transistor) structure is formed instead of the MISFET structure 12. In this case, in the above descriptions, the “source” of the MISFET structure 12 is replaced with an “emitter” of the IGBT structure, and the “drain” of the MISFET structure 12 is replaced with a “collector” of the IGBT structure. As a matter of course, in a case in which the chip 2 has a single layered structure that consists of the epitaxial layer, the second semiconductor region 7 of the “p-type” may have p-type impurities introduced into a surface layer portion of the second main surface 4 of the chip 2 (the epitaxial layer) by an ion implantation method.

In each of the embodiments, the first direction X and the second direction Y are defined by the extending directions of the first to fourth side surfaces 5A to 5D. However, the first direction X and the second direction Y may be any directions as long as the first direction X and the second direction Y keep a relationship in which the first direction X and the second direction Y intersect (specifically, perpendicularly intersect) each other. For example, the first direction X may be a direction intersecting the first to fourth side surfaces 5A to 5D, and the second direction Y may be a direction intersecting the first to fourth side surfaces 5A to 5D.

Hereinafter, examples of features extracted from the present descriptions and the attached drawings shall be indicated below. Hereinafter, the alphanumeric characters in parentheses represent the corresponding components in the aforementioned embodiments, but are not intended to limit the scope of each clause to the embodiments. The “semiconductor device” in the following clauses may be replaced with a “wide bandgap semiconductor device”, an “SiC semiconductor device”, a “semiconductor switching device” or a “semiconductor rectifier device” as needed.

[A1] A semiconductor device (1A to 1N) comprising: a chip (2) having a main surface (3); a main surface electrode (30, 32, 124) arranged on the main surface (3); a terminal electrode (45, 55, 126) that has a terminal surface (46, 56, 127) and a terminal side wall (47, 57, 128), and that has a recessed portion (48, 58, 129) recessed toward the main surface electrode (30, 32, 124) side in the terminal surface (46, 56, 127); and a sealing insulator (71) that covers a periphery of the terminal electrode (45, 55, 126) on the main surface (3) such as to expose the terminal surface (46, 56, 127) and cover the terminal side wall (47, 57, 128).

[A2] The semiconductor device (1A to 1N) according to A1, wherein the sealing insulator (71) has a portion that covers the recessed portion (48, 58, 129).

[A3] The semiconductor device (1A to 1N) according to A1 or A2, wherein the terminal electrode (45, 55, 126) is thicker than the chip (2).

[A4] The semiconductor device (1A to 1N) according to any one of A1 to A3, wherein the sealing insulator (71) is thicker than the chip (2).

[A5] The semiconductor device (1A to 1N) according to any one of A1 to A4, wherein the recessed portion (48, 58, 129) is formed at a corner portion of the terminal surface (46, 56, 127) such as to define a step portion in the terminal side wall (47, 57, 128).

[A6] The semiconductor device (1A to 1N) according to any one of A1 to A5, wherein the recessed portion (48, 58, 129) is formed in an annular shape that extends along a peripheral edge of the terminal surface (46, 56, 127) such as to surround an inner portion of the terminal surface (46, 56, 127) in plan view.

[A7] The semiconductor device (1A to 1N) according to any one of A1 to A6, wherein the terminal electrode (45, 55, 126) includes a first layer portion (49, 59, 130) that is positioned on the main surface electrode (30, 32, 124) side and a second layer portion (50, 60, 131) that protrudes toward the opposite side with respect to the chip (2) from the first layer portion (49, 59, 130) such as to define the recessed portion (48, 58, 129) with the first layer portion (49, 59, 130) and has the terminal surface (46, 56, 127) that is formed by the second layer portion (50, 60, 131), and the sealing insulator (71) covers the second layer portion (50, 60, 131) and the first layer portion (49, 59, 130) such as to expose the terminal surface (46, 56, 127).

[A8] The semiconductor device (1A to 1N) according to A7, wherein the first layer portion (49, 59, 130) has a first planar area, and the second layer portion (50, 60, 131) has a second planar area that is less than the first planar area.

[A9] The semiconductor device (1A to 1N) according to A7 or A8, wherein the first layer portion (49, 59, 130) has a first thickness, and the second layer portion (50, 60, 131) has a second thickness exceeding the first thickness.

[A10] The semiconductor device (1A to 1N) according to A7 or A8, wherein the first layer portion (49, 59, 130) has a first thickness, and the second layer portion (50, 60, 131) has a second thickness less than the first thickness.

[A11] The semiconductor device (1A to 1N) according to any one of A7 to A10, wherein the sealing insulator (71) has a laminated structure including a first sealing insulator (74) that covers a periphery of the first layer portion (49, 59, 130) on the main surface (3) and a second sealing insulator (75) that covers a periphery of the second layer portion (50, 60, 131) on the first sealing insulator (74).

[A12] The semiconductor device (1A to 1N) according to A11, wherein the first layer portion (49, 59, 130) has a first layer main surface (49a, 59a, 130a) and a first layer side wall (49b, 59b, 130b), the second layer portion (50, 60, 131) has a second layer main surface (50a, 60a, 131a) and a second layer side wall (50b, 60b, 131b), the first sealing insulator (74) covers a periphery of the first layer portion (49, 59, 130) on the main surface (3) such as to expose the first layer main surface (49a, 59a, 130a) and cover the first layer side wall (49b, 59b, 130b), and the second sealing insulator (75) exposes the second layer main surface (50a, 60a, 131a) as the terminal surface (46, 56, 127) and covers a periphery of the second layer portion (50, 60, 131) on the first sealing insulator (74) such as to cover the second layer side wall (50b, 60b, 131b).

[A13] The semiconductor device (1A to 1N) according to A12, wherein the first sealing insulator (74) has a first insulating main surface (74a) that forms a single flat surface with the first layer main surface (49a, 59a, 130a).

[A14] The semiconductor device (1A to 1N) according to A12 or A13, wherein the second sealing insulator (75) has a second insulating main surface (75a) that forms a single flat surface with the second layer main surface (50a, 60a, 131a).

[A15] The semiconductor device (1A to 1N) according to any one of A1 to A14 further comprising: an insulating film (38) that covers the main surface electrode (30, 32, 124), wherein the terminal electrode (45, 55, 126) has a portion that covers the insulating film (38).

[A16] The semiconductor device (1A to 1N) according to A15, wherein the sealing insulator (71) has a portion that covers the insulating film (38).

[A17] The semiconductor device (1A to 1N) according to any one of A1 to A16, wherein the chip (2) has a laminated structure including a substrate (7) and an epitaxial layer (6), and includes the main surface (3) that is formed by the epitaxial layer (6).

[A18] The semiconductor device (1A to 1N) according to A17, wherein the epitaxial layer (6) is thicker than the substrate (7).

[A19] The semiconductor device (1A to 1N) according to any one of A1 to A16, wherein the chip (2) has a single layered structure consisting of an epitaxial layer (6).

[A20] The semiconductor device (1A to 1N) according to any one of A1 to A19, wherein the chip (2) includes a monocrystal of a wide bandgap semiconductor.

[B1] A manufacturing method for a semiconductor device (1A to 1N) comprising: a step of preparing a wafer structure (80) that includes a wafer (81) having a main surface (82) and a main surface electrode (30, 32, 124) that is arranged on the main surface (82); a step of forming a terminal electrode (45, 55, 126) on the main surface electrode (30, 32, 124), the terminal electrode (45, 55, 126) having a terminal surface (46, 56, 127) and a terminal side wall (47, 57, 128) and having a recessed portion (48, 58, 129) recessed toward the main surface electrode (30, 32, 124) side in the terminal surface (46, 56, 127); and a step of forming a sealing insulator (71) that covers a periphery of the terminal electrode (45, 55, 126) such as to expose the terminal surface (46, 56, 127) and cover the terminal side wall (47, 57, 128).

[B2] The manufacturing method for the semiconductor device (1A to 1N) according to B1, wherein the step of forming the sealing insulator (71) includes a step of forming the sealing insulator (71) having a portion that covers the recessed portion (48, 58, 129).

[B3] The manufacturing method for the semiconductor device (1A to 1N) according to B1 or B2 further comprising: a step of thinning the wafer (81) after the step of forming the sealing insulator (71).

[B4] The manufacturing method for the semiconductor device (1A to 1N) according to B3, wherein the step of thinning the wafer (81) includes a step of thinning the wafer (81) until it becomes thinner than the sealing insulator (71).

[B5] The manufacturing method for the semiconductor device (1A to 1N) according to B3 or B4, wherein the step of thinning the wafer (81) includes a step of thinning the wafer (81) until it becomes thinner than the terminal electrode (45, 55, 126).

[B6] The manufacturing method for the semiconductor device (1A to 1N) according to any one of B1 to B5, wherein the step of forming the terminal electrode (45, 55, 126) includes a step of forming the terminal electrode (45, 55, 126) having the recessed portion (48, 58, 129) at a corner portion of the terminal surface (46, 56, 127) such as to define a step portion in the terminal side wall (47, 57, 128).

[B7] The manufacturing method for the semiconductor device (1A to 1N) according to any one of B1 to B6, wherein the step of forming the terminal electrode (45, 55, 126) includes a step of forming the terminal electrode (45, 55, 126) having the recessed portion (48, 58, 129) extending in an annular shape along a peripheral edge of the terminal surface (46, 56, 127) such as to surround an inner portion of the terminal surface (46, 56, 127) in plan view.

[B8] The manufacturing method for the semiconductor device (1A to 1N) according to any one of B1 to B7, wherein the step of forming the terminal electrode (45, 55, 126) includes a step of forming a first layer portion (49, 59, 130) on the main surface electrode (30, 32, 124) and a step of forming a second layer portion (50, 60, 131) on the first layer portion (49, 59, 130) such as to define the recessed portion (48, 58, 129) with the first layer portion (49, 59, 130), and the step of forming the sealing insulator (71) includes a step of forming the sealing insulator (71) that covers the first layer portion (49, 59, 130) and the second layer portion (50, 60, 131) such as to expose a part of the second layer portion (50, 60, 131) as the terminal surface (46, 56, 127).

[B9] The manufacturing method for the semiconductor device (1A to 1N) according to B8, wherein the step of forming the terminal electrode (45, 55, 126) includes a step of forming the first layer portion (49, 59, 130) having a first planar area and a step of forming the second layer portion (50, 60, 131) having a second planar area that is less than the first planar area.

[B10] The manufacturing method for the semiconductor device (1A to 1N) according to B8 or B9, wherein the step of forming the terminal electrode (45, 55, 126) includes a step of forming the first layer portion (49, 59, 130) having a first thickness and a step of forming the second layer portion (50, 60, 131) having a second thickness that exceeds the first thickness.

[B11] The manufacturing method for the semiconductor device (1A to 1N) according to B8 or B9, wherein the step of forming the terminal electrode (45, 55, 126) includes a step of forming the first layer portion (49, 59, 130) having a first thickness and a step of forming the second layer portion (50, 60, 131) having a second thickness less than the first thickness.

[B12] The manufacturing method for the semiconductor device (1A to 1N) according to any one of B8 to B11, wherein the step of forming the sealing insulator (71) includes a step of forming a first sealing insulator (74) that covers a periphery of the first layer portion (49, 59, 130) on the main surface (82) and a step of forming a second sealing insulator (75) that covers a periphery of the second layer portion (50, 60, 131) on the first sealing insulator (74).

[B13] The manufacturing method for the semiconductor device (1A to 1N) according to B12, wherein the step of forming the first layer portion (49, 59, 130) includes a step of forming the first layer portion (49, 59, 130) having a first layer main surface (49a, 59a, 130a) and a first layer side wall (49b, 59b, 130b), the step of forming the second layer portion (50, 60, 131) includes a step of forming the second layer portion (50, 60, 131) having a second layer main surface (50a, 60a, 131a) and a second layer side wall (50b, 60b, 131b), the step of forming the first sealing insulator (74) includes a step of forming the first sealing insulator (74) that covers a periphery of the first layer portion (49, 59, 130) on the main surface (82) such as to expose the first layer main surface (49a, 59a, 130a) and cover the first layer side wall (49b, 59b, 130b), and the step of forming the second sealing insulator (75) includes a step of forming the second sealing insulator (75) that covers a periphery of the second layer portion (50, 60, 131) on the first sealing insulator (74) such as to expose the second layer main surface (50a, 60a, 131a) as the terminal surface (46, 56, 127) and cover the second layer side wall (50b, 60b, 131b).

[B14] The manufacturing method for the semiconductor device (1A to 1N) according to B13, wherein the step of forming the first sealing insulator (74) includes a step of forming the first sealing insulator (74) having a first insulating main surface (74a) that forms a single flat surface with the first layer main surface (49a, 59a, 130a).

[B15] The manufacturing method for the semiconductor device (1A to 1N) according to B13 or B14, wherein the step of forming the second sealing insulator (75) includes a step of forming the second sealing insulator (75) having a second insulating main surface (75a) that forms a single flat surface with the second layer main surface (50a, 60a, 131a).

[B16] The manufacturing method for the semiconductor device (1A to 1N) according to any one of B1 to B15 further comprising: a step of forming an insulating film (38) that covers the main surface electrode (30, 32, 124) before the step of forming the terminal electrode (45, 55, 126), wherein the step of forming the terminal electrode (45, 55, 126) includes a step of forming the terminal electrode (45, 55, 126) having a portion that covers the insulating film (38).

[B17] The manufacturing method for the semiconductor device (1A to 1N) according to B16, wherein the step of forming the sealing insulator (71) includes a step of forming the sealing insulator (71) having a portion that covers the insulating film (38).

[B18] The manufacturing method for the semiconductor device (1A to 1N) according to any one of B1 to B17, wherein the wafer (81) has a laminated structure that includes a substrate (7) and an epitaxial layer (6) and has the main surface (82) that is formed by the epitaxial layer (6).

[B19] The manufacturing method for the semiconductor device (1A to 1N) according to any one of B1 to B18, wherein the wafer (81) includes a monocrystal of a wide bandgap semiconductor.

While embodiments of the present invention have been described in detail above, those are merely specific examples used to clarify the technical contents, and the present invention should not be interpreted as being limited only to those specific examples, and the spirit and scope of the present invention shall be limited only by the appended Claims.

What is claimed is:

1. A semiconductor device comprising:
a chip having a main surface;
a main surface electrode arranged on the main surface;
a terminal electrode that has a terminal surface and a terminal side wall, and that has a recessed portion recessed toward the main surface electrode side in the terminal surface; and
a sealing insulator that covers a periphery of the terminal electrode on the main surface such as to expose the terminal surface and cover the terminal side wall.

2. The semiconductor device according to claim 1,
wherein the sealing insulator has a portion that covers the recessed portion.

3. The semiconductor device according to claim 1,
wherein the terminal electrode is thicker than the chip.

4. The semiconductor device according to claim 1,
wherein the sealing insulator is thicker than the chip.

5. The semiconductor device according to claim 1,
wherein the recessed portion is formed at a corner portion of the terminal surface such as to define a step portion in the terminal side wall.

6. The semiconductor device according to claim 1,
wherein the recessed portion is formed in an annular shape extending along a peripheral edge of the terminal surface such as to surround an inner portion of the terminal surface in plan view.

7. The semiconductor device according to claim 1,
wherein the terminal electrode includes a first layer portion that is positioned on the main surface electrode side and a second layer portion that protrudes toward the opposite side with respect to the chip from the first layer portion such as to define the recessed portion with the first layer portion and has the terminal surface that is formed by the second layer portion, and
the sealing insulator covers the second layer portion and the first layer portion such as to expose the terminal surface.

8. The semiconductor device according to claim 7,
wherein the first layer portion has a first planar area, and
the second layer portion has a second planar area that is less than the first planar area.

9. The semiconductor device according to claim 7,
wherein the first layer portion has a first thickness, and
the second layer portion has a second thickness exceeding the first thickness.

10. The semiconductor device according to claim 7,
wherein the first layer portion has a first thickness, and
the second layer portion has a second thickness less than the first thickness.

11. The semiconductor device according to claim 7,
wherein the sealing insulator has a laminated structure including a first sealing insulator that covers a periphery of the first layer portion on the main surface and a second sealing insulator that covers a periphery of the second layer portion on the first sealing insulator.

12. The semiconductor device according to claim 11,
wherein the first layer portion has a first layer main surface and a first layer side wall,
the second layer portion has a second layer main surface and a second layer side wall,
the first sealing insulator covers a periphery of the first layer portion on the main surface such as to expose the first layer main surface and cover the first layer side wall, and
the second sealing insulator covers a periphery of the second layer portion on the first sealing insulator such as to expose the second layer main surface as the terminal surface and cover the second layer side wall.

13. The semiconductor device according to claim 12,
wherein the first sealing insulator has a first insulating main surface that forms a single flat surface with the first layer main surface.

14. The semiconductor device according to claim 12,
wherein the second sealing insulator has a second insulating main surface that forms a single flat surface with the second layer main surface.

15. The semiconductor device according to claim 1 further comprising:
an insulating film that covers the main surface electrode;
wherein the terminal electrode has a portion that covers the insulating film.

16. The semiconductor device according to claim 15,
wherein the sealing insulator has a portion that covers the insulating film.

17. The semiconductor device according to claim 1,
wherein the chip has a laminated structure including a substrate and an epitaxial layer, and includes the main surface that is formed by the epitaxial layer.

18. The semiconductor device according to claim 17,
wherein the epitaxial layer is thicker than the substrate.

19. The semiconductor device according to claim 1,
wherein the chip has a single layered structure consisting of an epitaxial layer.

20. The semiconductor device according to claim 1,
wherein the chip includes a monocrystal of a wide bandgap semiconductor.
